(19) United States
(12) Patent Application Publication
(10) Pub. No.: US 2022/0299875 A1
(43) Pub. Date: Sep. 22, 2022

(54) RADIATION-SENSITIVE RESIN COMPOSITION, AND METHOD FOR FORMING PATTERN

(71) Applicant: JSR CORPORATION, Tokyo (JP)

(72) Inventor: Ken MARUYAMA, Tokyo (JP)

(73) Assignee: JSR CORPORATION, Tokyo (JP)

(21) Appl. No.: 17/677,173

(22) Filed: Feb. 22, 2022

(30) Foreign Application Priority Data
Mar. 9, 2021 (JP) 2021-037220

(51) Int. Cl. G03F 7/039; G03F 7/004; G03F 7/20; G03F 7/32; G03F 7/11; G03F 7/38; G03F 7/40; G03F 7/16

(52) U.S. Cl. CPC G03F 7/0392; G03F 7/0045; G03F 7/2006; G03F 7/322; G03F 7/11; G03F 7/38; G03F 7/40; G03F 7/162

(57) ABSTRACT

A radiation-sensitive resin composition includes: a resin including a structural unit represented by formula (1); and a solvent containing propylene glycol monomethyl ether and alkyl lactate. The solvent does not contain propylene glycol monomethyl ether acetate or contains propylene glycol monomethyl ether acetate in a content of 5% by mass or less in the solvent. The radiation-sensitive resin composition further includes a radiation-sensitive acid generator, or the resin further includes a structural unit having a radiation-sensitive acid generating structure. In the formula (1), R^{T} is a hydrogen atom, a fluorine atom, a methyl group, or a trifluoromethyl group. R^{X} is a monovalent hydrocarbon group having 1 to 20 carbon atoms. Cy represents an alicyclic structure having 3 to 20 ring members formed together with the carbon atom to which Cy is bonded.

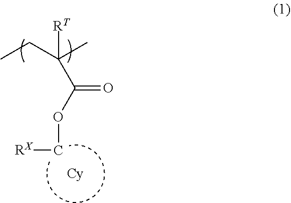

### CROSS-REFERENCE TO RELATED APPLICATIONS

The present application claims priority to Japanese Patent Application No. 2021-037220 filed Mar. 9, 2021, the contents of which are incorporated herein by reference in their entirety.

### BACKGROUND OF THE INVENTION

### Field of the Invention

The present invention relates to a radiation-sensitive resin composition, and a method for forming a pattern.

### Description of the Related Art

A photolithography technology using a resist composition has been used for the fine circuit formation in a semiconductor device. As the representative procedure, for example, a resist pattern is formed on a substrate by generating an acid by irradiating the coating of the resist composition with a radioactive ray through a mask pattern, and then reacting in the presence of the acid as a catalyst to generate the difference of solubility of a resin into a developer between an exposed part and a non-exposed part.

In the above-described photolithography technology, the micronization of the pattern is promoted by using a short wavelength radioactive ray such as an ArF excimer laser or by using such a radioactive ray and an immersion exposure method (liquid immersion lithography) in combination. As a next-generation technology, a shorter wavelength radioactive ray such as an electron beam, an X ray, or EUV (extreme-ultraviolet ray) is tried to be used, and a resist material containing an acid generator having a benzene ring with an enhanced efficiency of absorbing such a radioactive ray is being studied (see, JP-A-2014-2359).

### SUMMARY OF THE INVENTION

According to an aspect of the present invention, a radiation-sensitive resin composition includes: a resin including a structural unit represented by formula (1); and a solvent containing propylene glycol monomethyl ether and alkyl lactate. The solvent does not contain propylene glycol monomethyl ether acetate or contains propylene glycol monomethyl ether acetate in a content of 5% by mass or less in the solvent. The radiation-sensitive resin composition further includes a radiation-sensitive acid generator, or the resin further includes a structural unit having a radiation-sensitive acid generating structure. In the formula (1), R^{T} is a hydrogen atom, a fluorine atom, a methyl group, or a trifluoromethyl group. R^{X} is a monovalent hydrocarbon group having 1 to 20 carbon atoms. Cy represents an alicyclic structure having 3 to 20 ring members formed together with the carbon atom to which Cy is bonded.

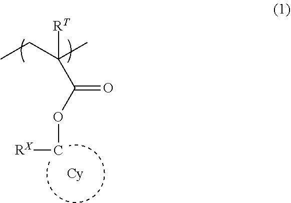

According to another aspect of the present invention, a method for forming a pattern, includes forming a resist film by applying the above-mentioned radiation-sensitive resin composition directly or indirectly onto a substrate. The resist film is exposed. The exposed resist film is developed with a developer.

### DETAILED DESCRIPTION OF THE PREFERRED EMBODIMENTS

Among such efforts for next-generation technologies, various resist performances equal to or higher than those in the related art are required in terms of pattern defect suppression, sensitivity, and critical dimension uniformity (CDU) performance and the like.

The present invention relates to, in an embodiment (hereinafter, also referred to as “first embodiment” for convenience), a radiation-sensitive resin composition containing: a radiation-sensitive acid generator; a resin containing a structural unit (hereinafter, also referred to as “structural unit A”) represented by the following formula (1); and a solvent, wherein the solvent contains at least propylene glycol monomethyl ether and alkyl lactate, and a content of propylene glycol monomethyl ether acetate in the solvent is 5% by mass or less.

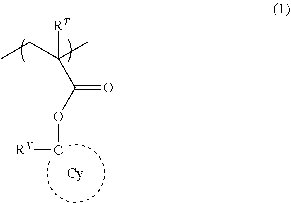

In the formula (1), R^{T} is a hydrogen atom, a fluorine atom, a methyl group, or a trifluoromethyl group.

R^{X} is a monovalent hydrocarbon group having 1 to 20 carbon atoms.

Cy represents an alicyclic structure having 3 to 20 ring members formed together with a carbon atom to which Cy is bonded.

The present invention relates to, in another embodiment (hereinafter, also referred to as “second embodiment” for convenience), a radiation-sensitive resin composition containing:
a radiation-sensitive acid generating resin containing a structural unit having a radiation-sensitive acid generating structure and a structural unit represented by the following formula (1); and
a solvent,
wherein the solvent contains at least propylene glycol monomethyl ether and alkyl lactate, and a content of propylene glycol monomethyl ether acetate in the solvent is 5% by mass or less.

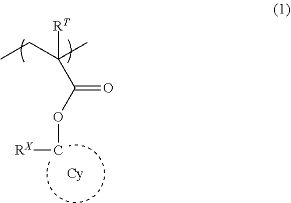

In the formula (1), R^{T} is a hydrogen atom, a fluorine atom, a methyl group, or a trifluoromethyl group.

R^{X} is a monovalent hydrocarbon group having 1 to 20 carbon atoms.

Cy represents an alicyclic structure having 3 to 20 ring members formed together with a carbon atom to which Cy is bonded.

Also in the radiation-sensitive resin composition according to any of the above embodiments, at least the propylene glycol monomethyl ether and the alkyllactate are contained as the solvent, and the content of the propylene glycol monomethyl ether acetate in the solvent is 5% by mass or less, whereby excellent defect-suppression performance can be exhibited. The reason for this is not clear, but is presumed as follows. The present inventors have considered that a pattern defect occurs when a solvent that has permeated into a resist film during solvent removal acts on a surrounding resist film. It is presumed that, increase in hydrophilicity by hydroxy groups of the propylene glycol monomethyl ether and the alkyl lactate of the resist film leads to suppression of the penetration of the solvent into the resist film, and reduction in the content of the propylene glycol monomethyl ether acetate having higher hydrophobicity leads to suppression of the penetration of the solvent into the resist film, whereby the defect-suppression performance is exhibited. The acid dissociable group of the structural unit A in the resin or the radiation-sensitive acid generating resin has high acid dissociation efficiency during exposure, whereby the contrast between an exposed portion and an unexposed portion is increased, which exhibits excellent patternability. It is presumed that the resist performance can be exhibited by these combined actions.

The present invention relates to, in still another embodiment (hereinafter, also referred to as “third embodiment” for convenience), a method for forming a pattern, the method including the steps of: directly or indirectly applying the radiation-sensitive resin composition onto a substrate to form a resist film; exposing the resist film; and developing the exposed resist film with a developer.

In the method for forming a pattern, the radiation-sensitive resin composition having excellent defect-suppression performance, sensitivity, and CDU performance is used, whereby a high-quality resist pattern can be efficiently formed.

Hereinbelow, embodiments of the present invention will be described in detail, but the present invention is not limited to these embodiments.

### First Embodiment

### <<Radiation-Sensitive Resin Composition>>

A radiation-sensitive resin composition according to the first embodiment (hereinafter, also simply referred to as a “composition”) contains a radiation-sensitive acid generator, a resin, and a solvent. The resin according to the first embodiment and the radiation-sensitive acid generating resin according to the second embodiment described later as the main components of the radiation-sensitive resin composition are also referred to as a base resin. The composition may contain another optional component as long as the effects of the present invention are not impaired. By containing a predetermined solvent and a base resin, the radiation-sensitive resin composition can impart a high level of defect-suppression performance, sensitivity and CDU performance to the obtained resist film.

### <Radiation-Sensitive Acid Generator>

The radiation-sensitive acid generator is a component that generates an acid during exposure. The acid generated during exposure is considered to have two functions in the radiation-sensitive resin composition depending on the strength of the acid. Examples of the first function include a function that causes the acid generated during exposure to dissociate an acid dissociable group of a structural unit A of the resin, to generate a carboxy group or the like. The radiation-sensitive acid generator having the first function is referred to as a radiation-sensitive acid generator (I). Examples of the second function include a function that suppresses the diffusion of the acid generated from the radiation-sensitive acid generator (I) in the non-exposed part without substantially dissociating the acid dissociable group or the like of the structural unit A of the resin or the like under a pattern formation condition using the radiation-sensitive resin composition. The radiation-sensitive acid generator having the second function is referred to as a radiation-sensitive acid generator (II). The acid generated from the radiation-sensitive acid generator (II) can be said to be relatively weaker (acid having a larger pKa) than the acid generated from the radiation-sensitive acid generator (I). Whether the radiation-sensitive acid generator functions as the radiation-sensitive acid generator (I) or the radiation-sensitive acid generator (II) depends on energy required for the dissociation of the acid-dissociable group of the structural unit A or the like of the resin, and acidity of an acid generated from the radiation-sensitive acid generator, and the like. The containing mode of the radiation-sensitive acid generator in the radiation-sensitive resin composition may be a mode in which the radiation-sensitive acid generator is present alone as a compound (released from a polymer), a mode in which the radiation-sensitive acid generator is incorporated as a part of a polymer, or both of these forms. The mode in which the radiation-sensitive acid generator is incorporated as a part of a polymer will be described later as a radiation-sensitive acid generating resin.

When the radiation-sensitive resin composition contains the radiation-sensitive acid generator (I), the polarity of the resin in the exposed part increases, whereby the resin in the exposed part is soluble in the developer in the case of alkaline aqueous solution development, and is poorly soluble in the developer in the case of organic solvent development.

The radiation-sensitive resin composition contains the radiation-sensitive acid generator (II), whereby a resist pattern having more excellent pattern developability, LWR performance, and CDU performance can be formed from the radiation-sensitive resin composition.

Examples of the radiation-sensitive acid generator include an onium salt, a sulfonimide compound, a halogen-containing compound, and a diazoketone compound. Examples of the onium salt include a sulfonium salt, a tetrahydrothiophenium salt, an iodonium salt, a phosphonium salt, a diazonium salt, and a pyridinium salt. Among them, a sulfonium salt and an iodonium salt are preferable.

Examples of the acid generated during exposure include acids that generate sulfonic acid, carboxylic acid, and sulfonimide during exposure. Examples of such an acid include
(1) a compound in which the carbon atom adjacent to the sulfo group is substituted with one or more fluorine atoms or fluorinated hydrocarbon groups, and
(2) a compound in which the carbon atom adjacent to the sulfo group is not substituted with a fluorine atom or a fluorinated hydrocarbon group.

Examples of the carboxylic acid generated during exposure include
(3) a compound in which the carbon atom adjacent to the carboxy group is substituted with one or more fluorine atoms or fluorinated hydrocarbon groups, and
(4) a compound in which the carbon atom adjacent to the carboxy group is not substituted with a fluorine atom or a fluorinated hydrocarbon group.

Among them, as the radiation-sensitive acid generator (I), a radiation-sensitive acid generator corresponding to the above (1) is preferable, and a radiation-sensitive acid generator having a cyclic structure is particularly preferable. As the radiation-sensitive acid generator (II), a radiation-sensitive acid generator corresponding to the above (2), (3), or (4) is preferable, and a radiation-sensitive acid generator corresponding to the above (2) or (4) is particularly preferable.

The radiation-sensitive acid generator preferably contains one or two or more onium salts containing an organic acid anion moiety and an onium cation moiety.

The organic acid anion moiety preferably has at least one selected from the group consisting of a sulfonate anion, a carboxylate anion, and a sulfonimide anion so as to correspond to the acid generated during the exposure.

The onium cation moiety is preferably at least one selected from the group consisting of a sulfonium cation and an iodonium cation so as to correspond to the sulfonium salt and the iodonium salt.

The onium salt is preferably at least one selected from the group consisting of:
a radiation-sensitive strong acid generator containing the organic acid anion moiety and the onium cation moiety; and
an acid diffusion controlling agent containing the organic acid anion moiety and the onium cation moiety and generating an acid having a pKa higher than that of an acid generated from the radiation-sensitive strong acid generator by irradiation with radiation.

The radiation-sensitive acid generator (I) corresponds to the radiation-sensitive strong acid generator, and the radiation-sensitive acid generator (II) corresponds to the acid diffusion controlling agent. The structures of the organic acid anion moiety and the onium cation moiety are appropriately designed, whereby the radiation-sensitive acid generator can function as both the radiation-sensitive strong acid generator and the acid diffusion controlling agent.

### (Radiation-Sensitive Strong Acid Generator)

The onium salt as the radiation-sensitive strong acid generator is preferably represented by the following formula (pd-1) or the following formula (pd-2).

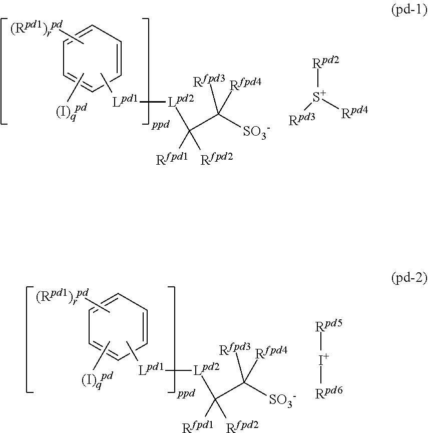

In the formulae (pd-1) and (pd-2), L^{pd1} is an alkylene group having 1 to 6 carbon atoms which may contain a single bond, an ether bond or an ester bond, or an ether bond or an ester bond. The alkylene group may be linear, branched, or cyclic.

R^{pd1} is a hydroxy group, a carboxy group, a fluorine atom, a chlorine atom, a bromine atom, an amino group, an alkyl group having 1 to 20 carbon atoms, an alkoxy group having 1 to 20 carbon atoms, an alkoxycarbonyl group having 2 to 10 carbon atoms, an acyloxy group having 2 to 20 carbon atoms, an alkylsulfonyloxy group having 1 to 20 carbon atoms, —NR^{pd6}—C(═O)—R^{pd7}, or —NR^{pd6}—C(═O)—O—R^{pd7}. The alkyl group having 1 to 20 carbon atoms, the alkoxy group having 1 to 20 carbon atoms, or the fluorine atom may be substituted with a chlorine atom, a bromine atom, a hydroxy group, an amino group, or an alkoxy group having 1 to 10 carbon atoms. R^{pd6} is a hydrogen atom or an alkyl group having 1 to 6 carbon atoms which may contain a halogen atom, a hydroxy group, an alkoxy group having 1 to 6 carbon atoms, an acyl group having 2 to 6 carbon atoms or an acyloxy group having 2 to 6 carbon atoms. R^{pd7} is an alkyl group having 1 to 16 carbon atoms, an alkenyl group having 2 to 16 carbon atoms, or an aryl group having 6 to 12 carbon atoms, and these groups may contain a halogen atom, a hydroxy group, an alkoxy group having 1 to 6 carbon atoms, an acyl group having 2 to 6 carbon atoms, or an acyloxy group having 2 to 6 carbon atoms. The alkyl group, the alkoxy group, the alkoxycarbonyl group, the acyloxy group, the acyl group, and the alkenyl group may be linear, branched, or cyclic.

Among them, R^{pd1} is preferably a hydroxy group, —NR^{pd6}—C(═O)—R^{pd7}, a fluorine atom, a chlorine atom, a bromine atom, a methyl group, or a methoxy group, or the like.

p^{pd} is an integer satisfying 0≤p^{pd}≤3. L^{pd2} is a hydrogen atom or a monovalent organic group having 1 to 20 carbon atoms when p^{pd} is 0. L^{pd2} is a single bond or a divalent linking group having 1 to 20 carbon atoms when p^{pd} is 1. L^{pd2} is a trivalent or tetravalent linking group having 1 to 20 carbon atoms when p^{pd} is 2 or 3. The linking group may contain an oxygen atom, a sulfur atom, or a nitrogen atom. Examples of the monovalent organic group when p is 0 include the same as those exemplified as the hydrocarbon group constituting the fluorinated hydrocarbon group, and monovalent groups in which some of methylene groups constituting the hydrocarbon group are substituted with an ether group or an ester group.

R^{fpd1} to R^{fpd4} are each independently a hydrogen atom, a fluorine atom, or a trifluoromethyl group, and at least one of them is a fluorine atom or a trifluoromethyl group. In particular, both R^{fpd3} and R^{fpd4} are preferably fluorine atoms.

R^{pd2}, R^{pd3}, R^{pd4}, R^{pd5}, and R^{pd6} are each independently a monovalent hydrocarbon group having 1 to 20 carbon atoms which may contain a hetero atom. R^{pd2}, R^{pd3}, and R^{pd4} may include one or more fluorine atoms, and R^{pd5} and R^{pd6} may include one or more fluorine atoms. Any two of R^{pd2}, R^{pd3}, and R^{pd4} may be bonded to each other to form a ring together with a sulfur atom to which they are bonded. The monovalent hydrocarbon group may be linear, branched, or cyclic, and specific examples thereof include the same as those exemplified as the hydrocarbon group constituting the fluorinated hydrocarbon group. Some or all of the hydrogen atoms of these groups may be substituted with a hydroxy group, a carboxy group, a halogen atom, a cyano group, an amide group, a nitro group, a mercapto group, a sultone group, a sulfone group, or a sulfonium salt-containing group.

q^{pd} and r^{pd} are integers satisfying 0≤q^{pd}≤5, 0≤r^{pd}≤3, and 0≤q^{pd}+r^{pd}≤5. q^{pd} is preferably an integer satisfying 1 q^{pd}≤3, and more preferably 2 or 3. r^{pd} is preferably an integer satisfying 0≤r^{pd}≤2.

Examples of the organic acid anion moiety of the radiation-sensitive strong acid generator represented by the formulae (pd-1) and (pd-2) include, but are not limited to, those shown below. The organic acid anion moiety preferably contains an iodine-substituted aromatic ring structure. All of those shown below are organic acid anion moieties having an iodine-substituted aromatic ring structure, but as the organic acid anion moieties having no iodine-substituted aromatic ring structure, a structure in which an iodine atom in the following formula is substituted with an atom or group other than an iodine atom such as a hydrogen atom or another substituent can be suitably employed.

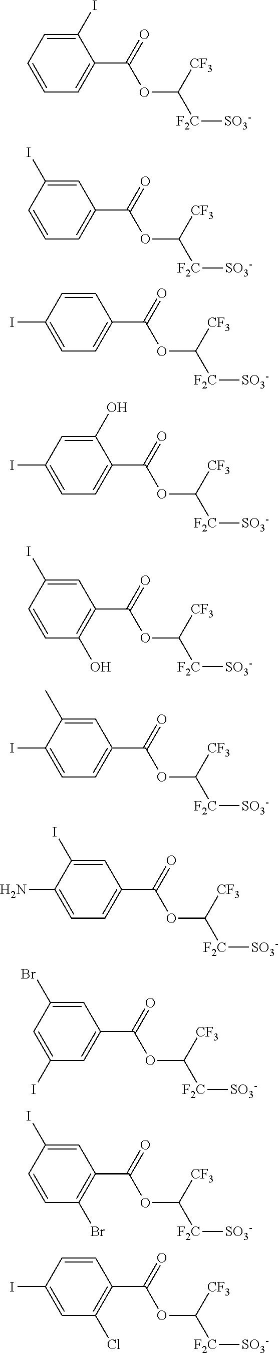

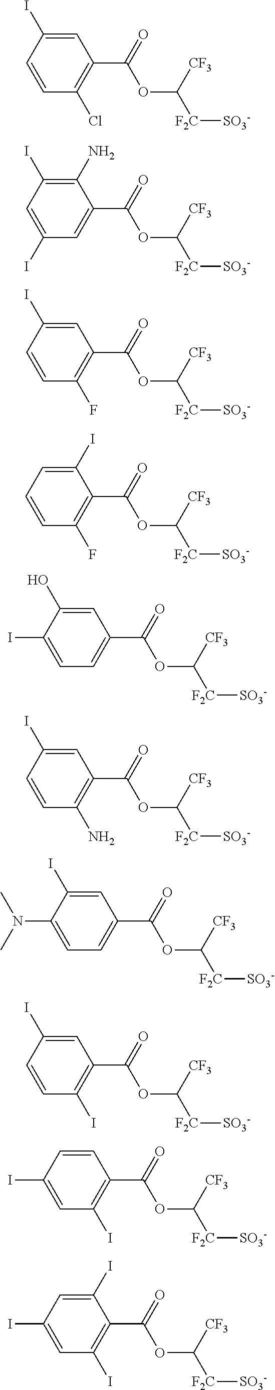

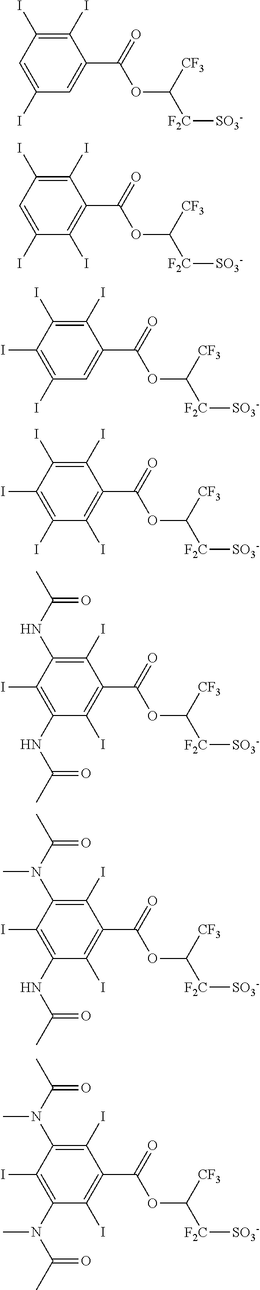

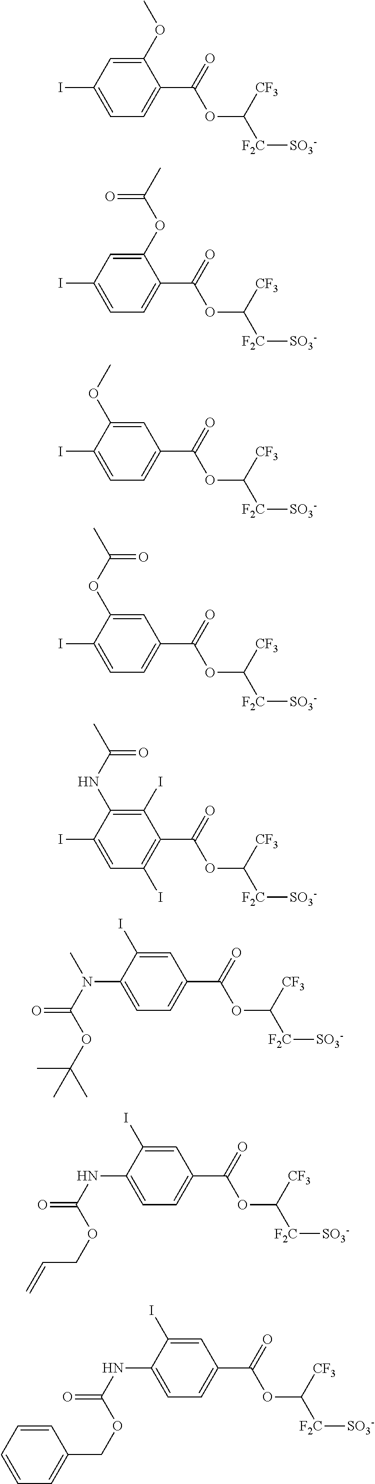

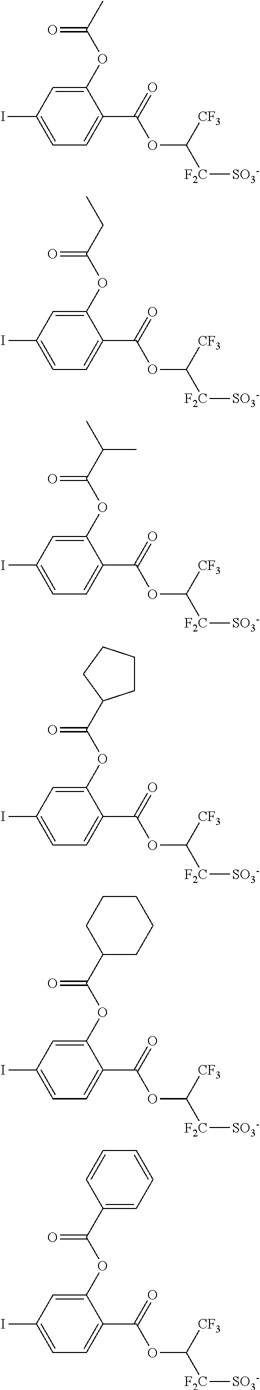

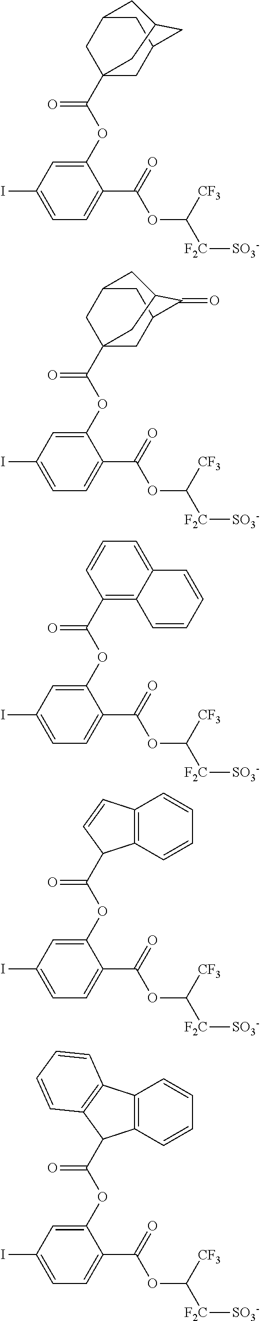

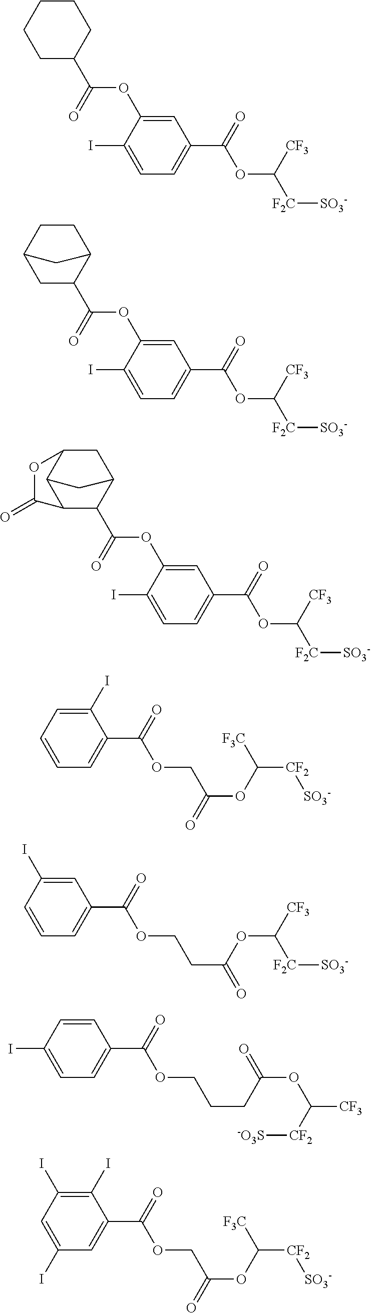

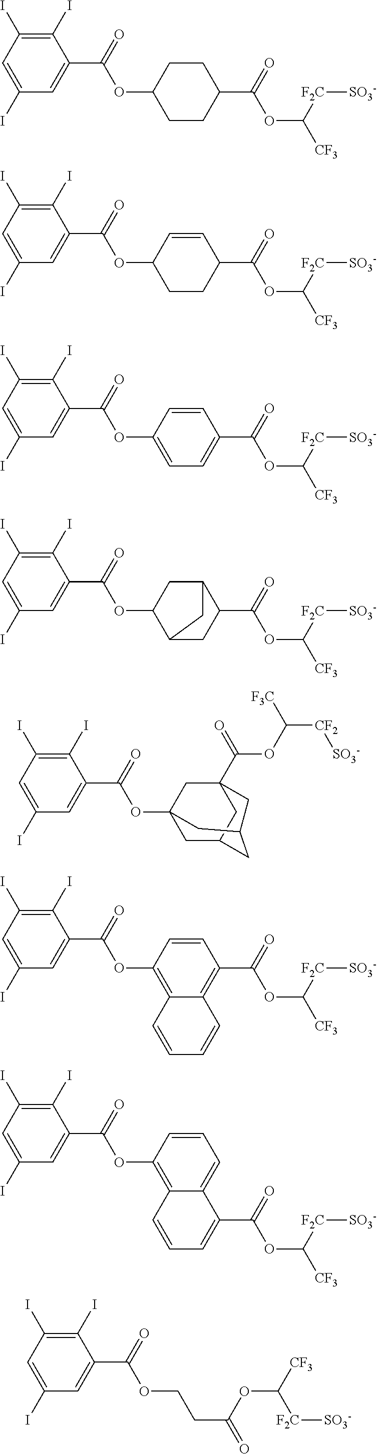

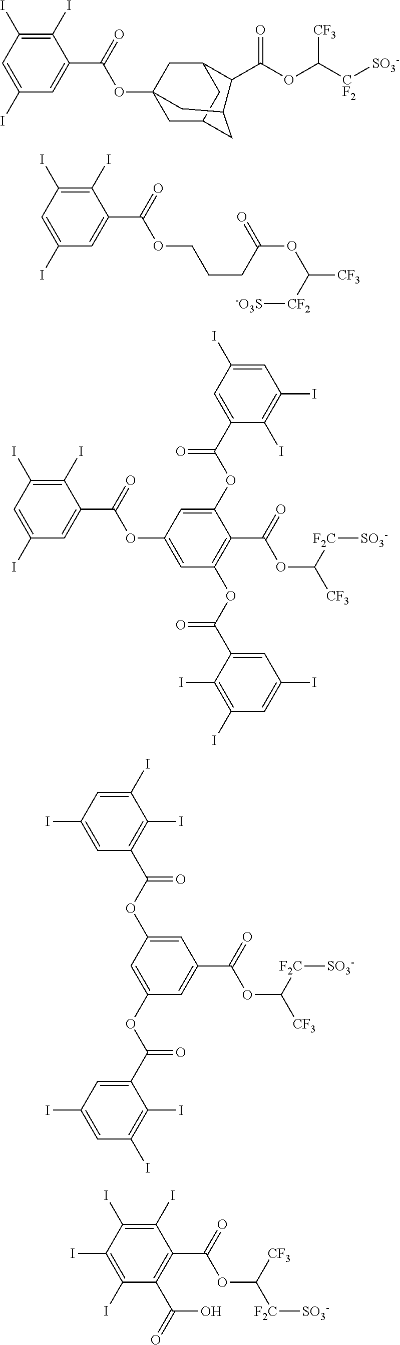

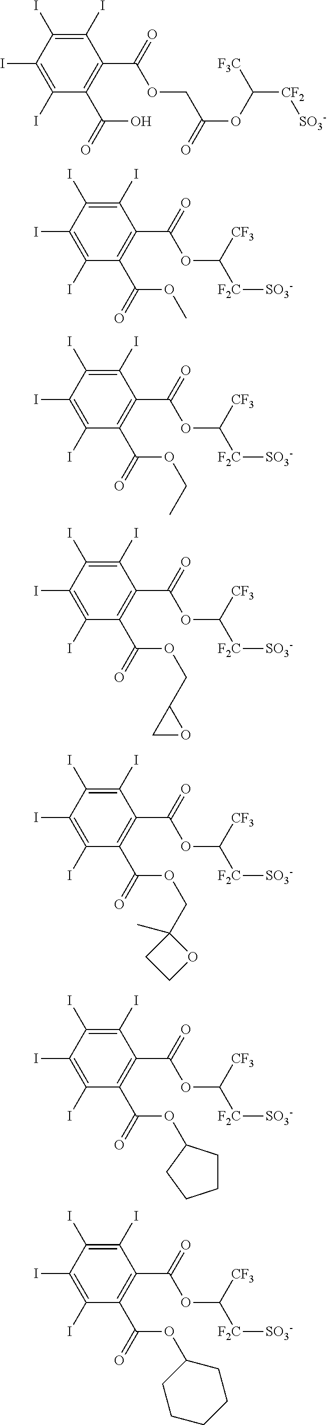

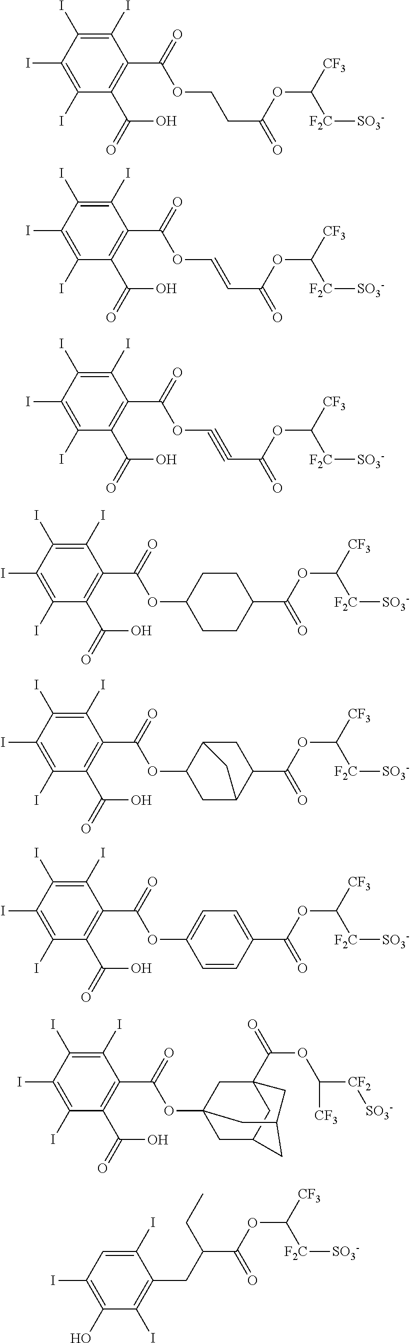

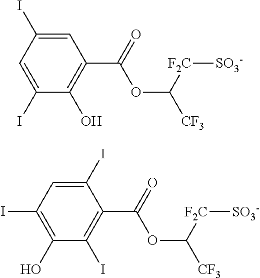

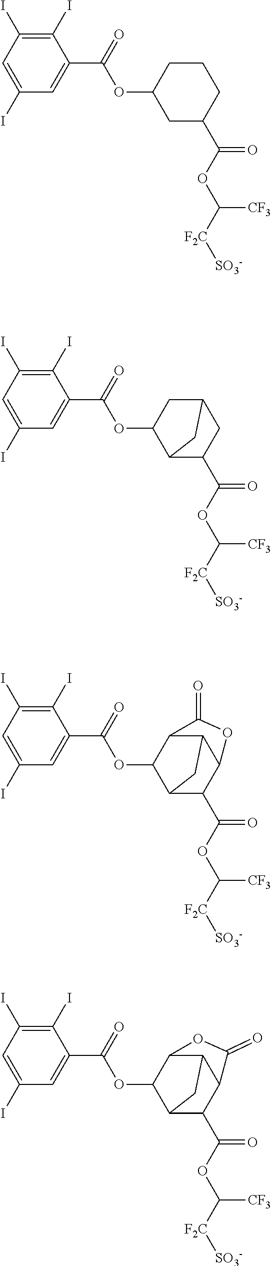

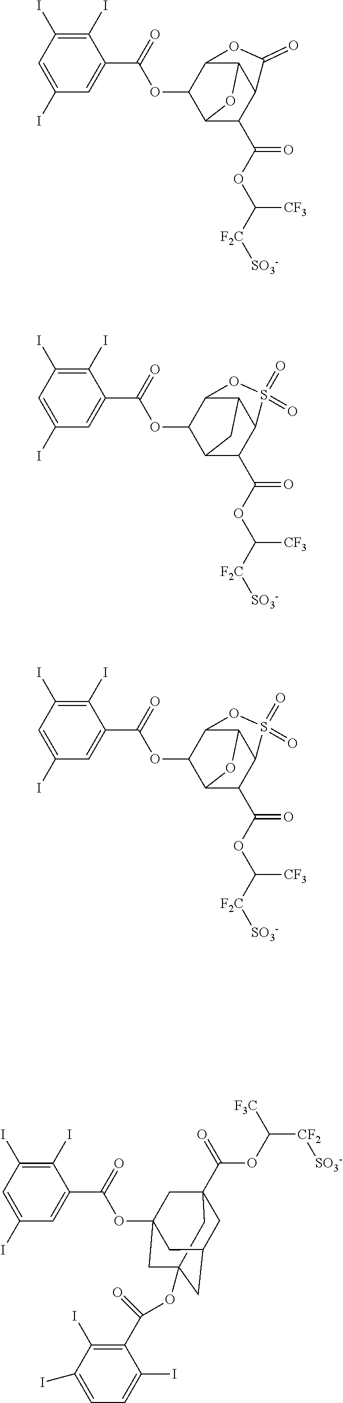

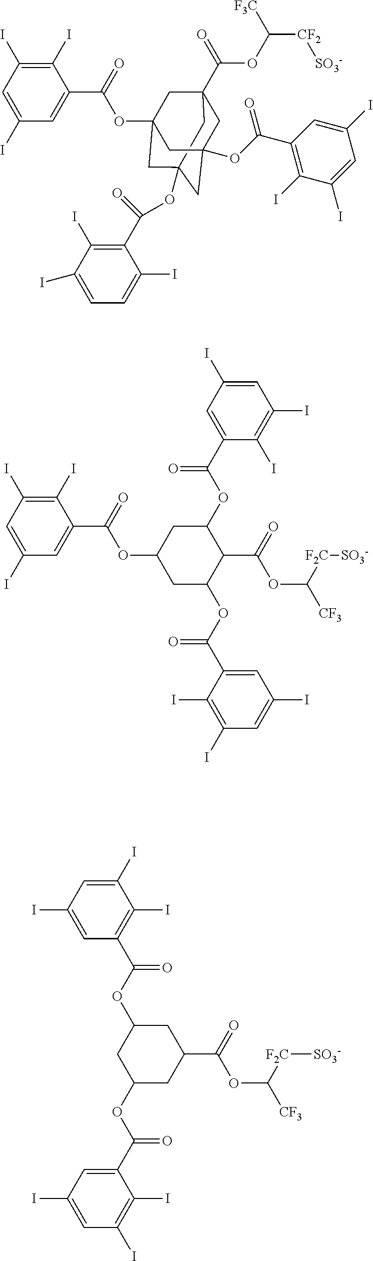

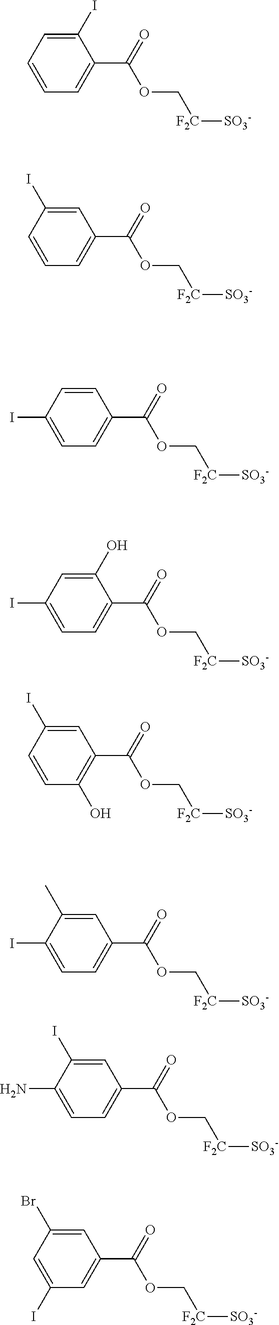

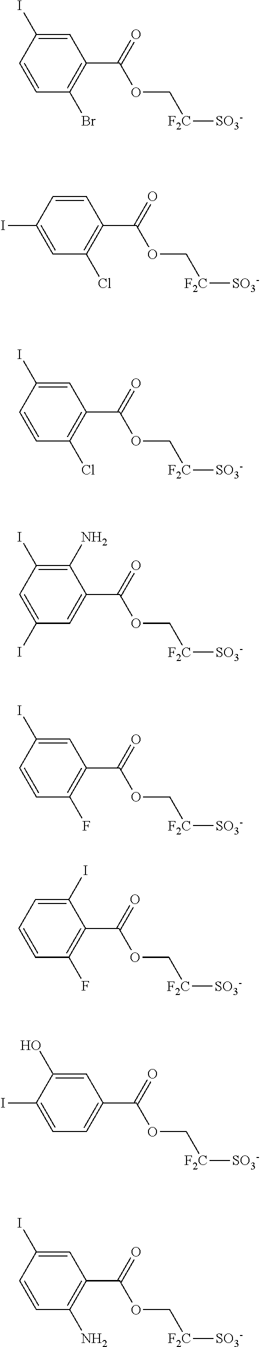

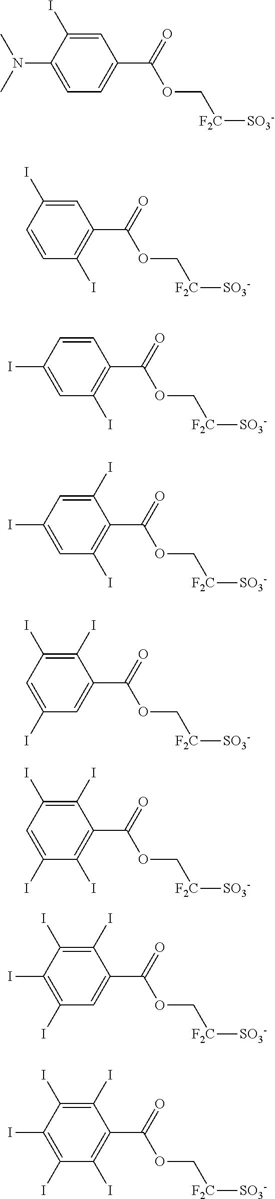

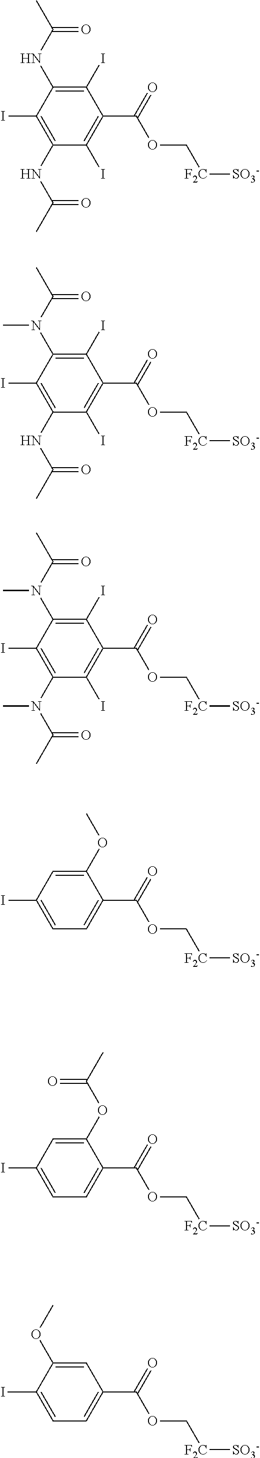

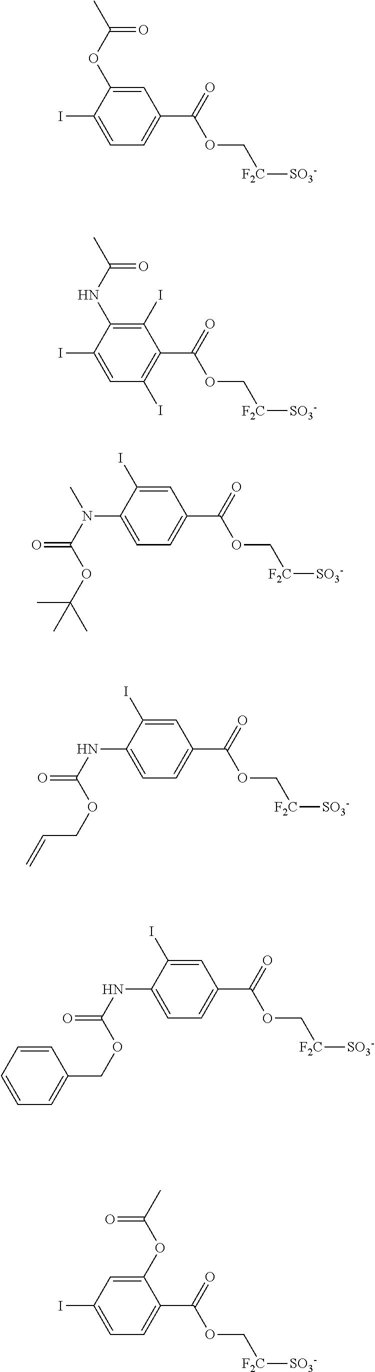

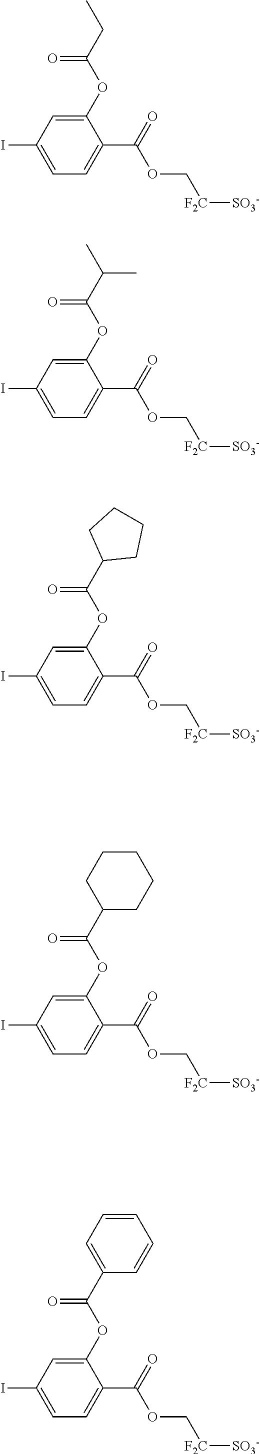

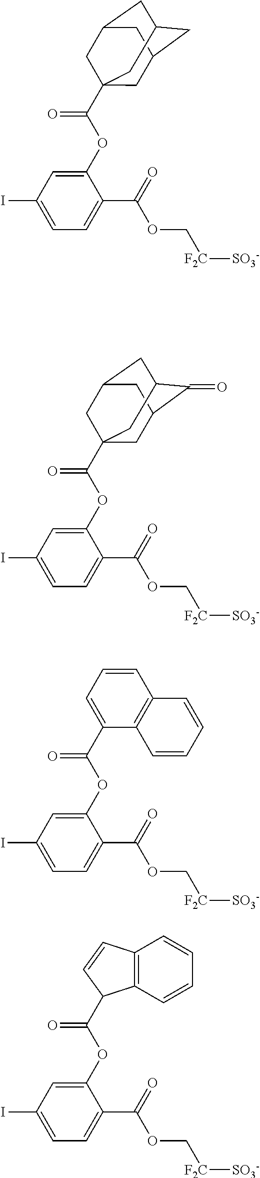

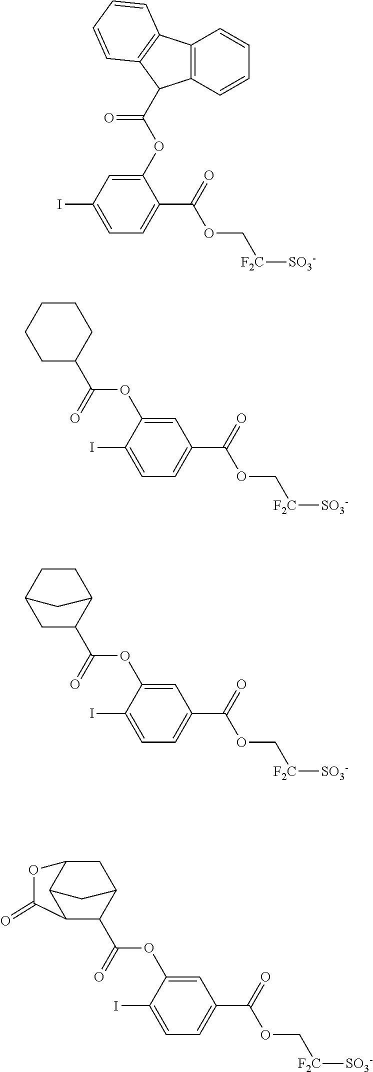

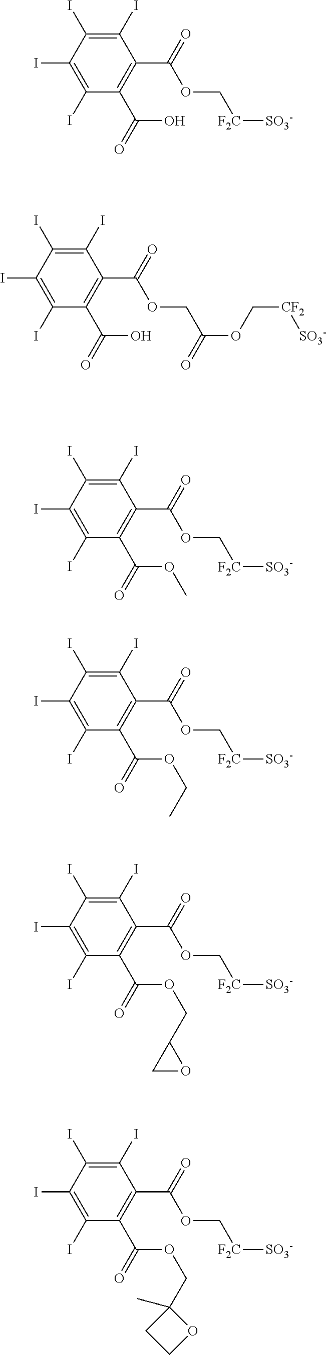

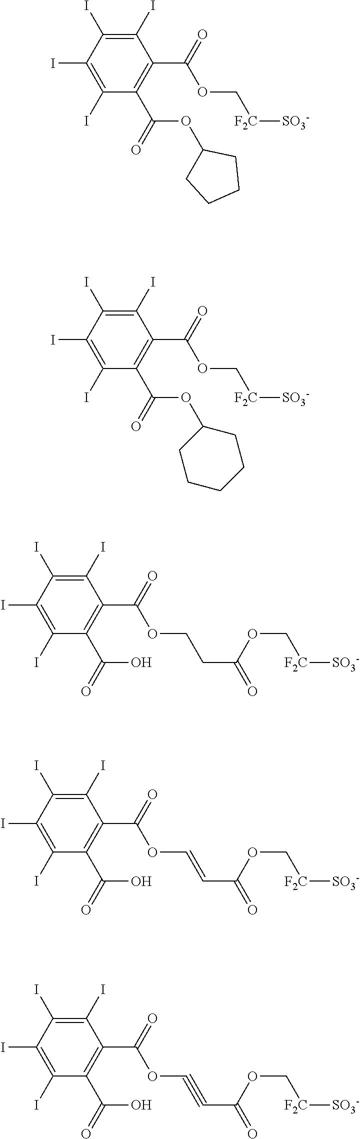

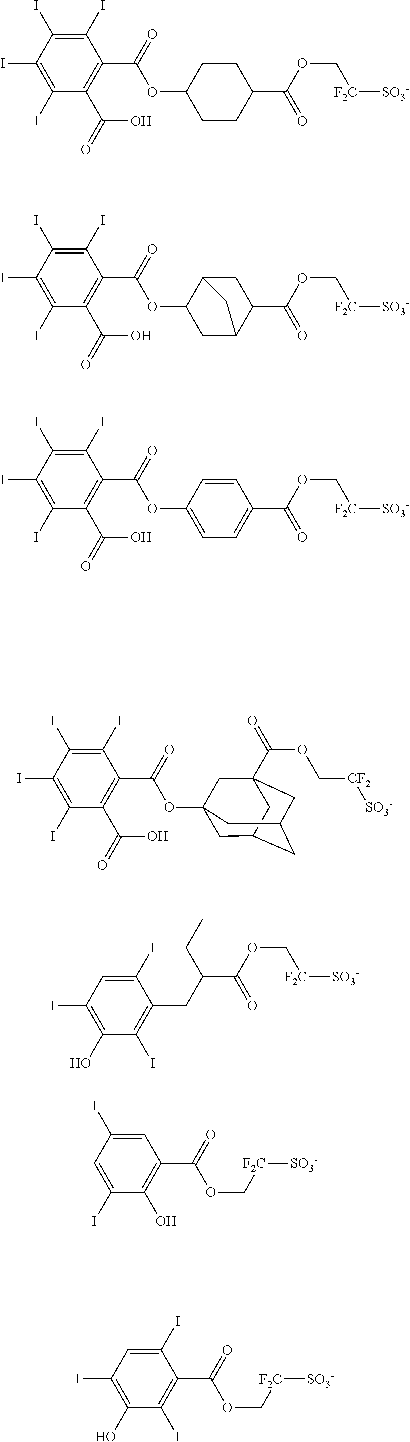

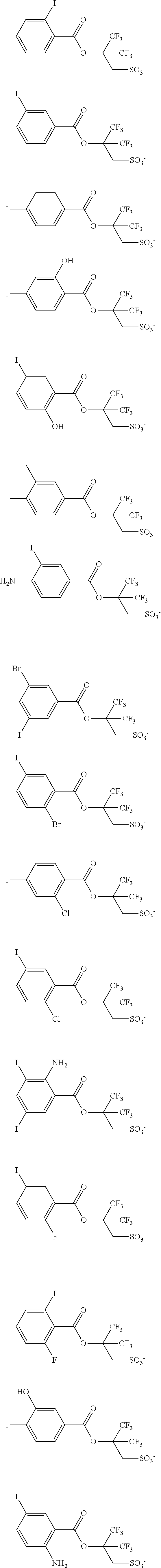

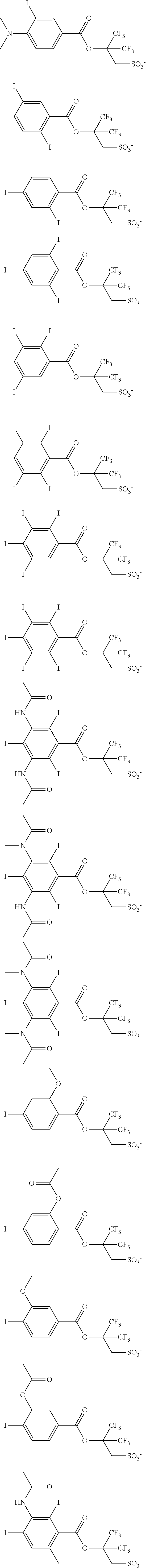

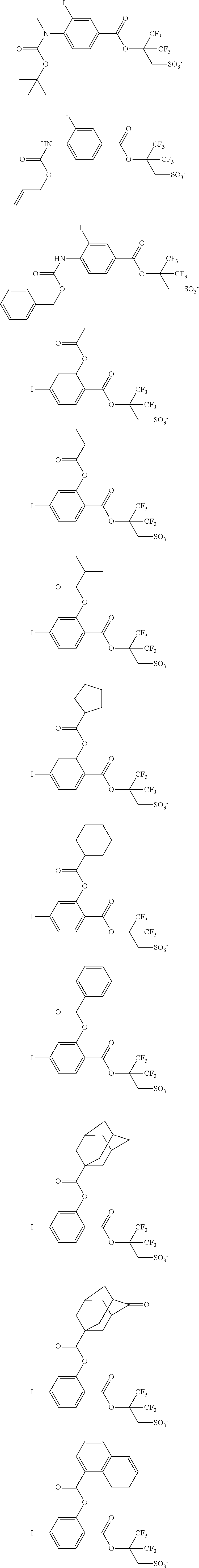

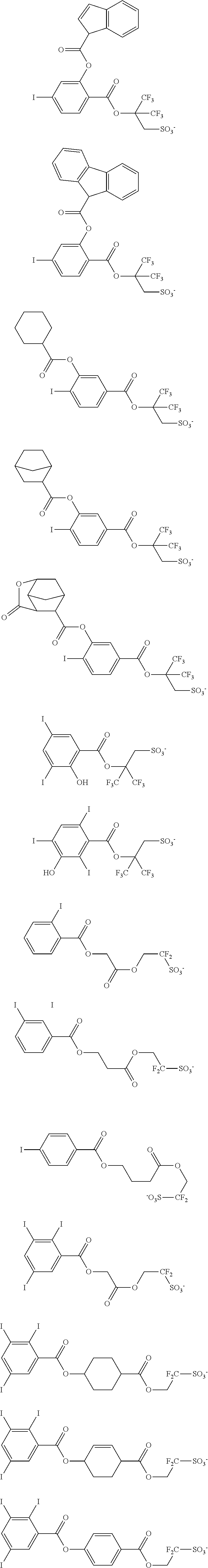

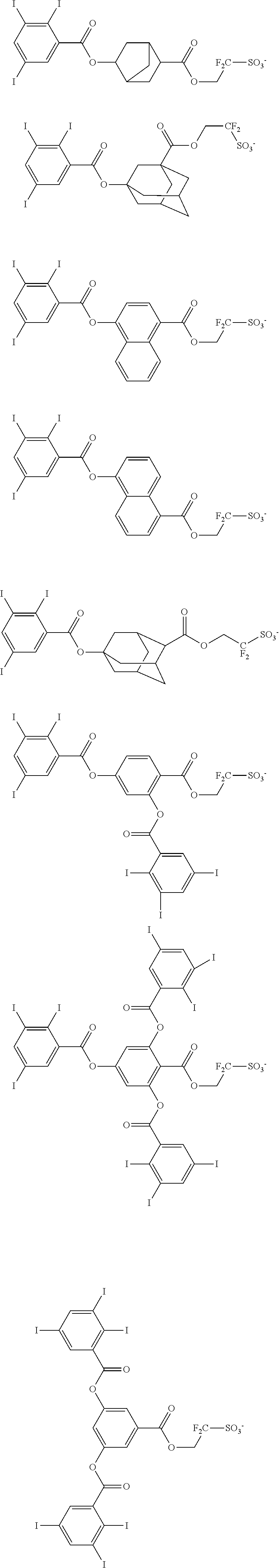

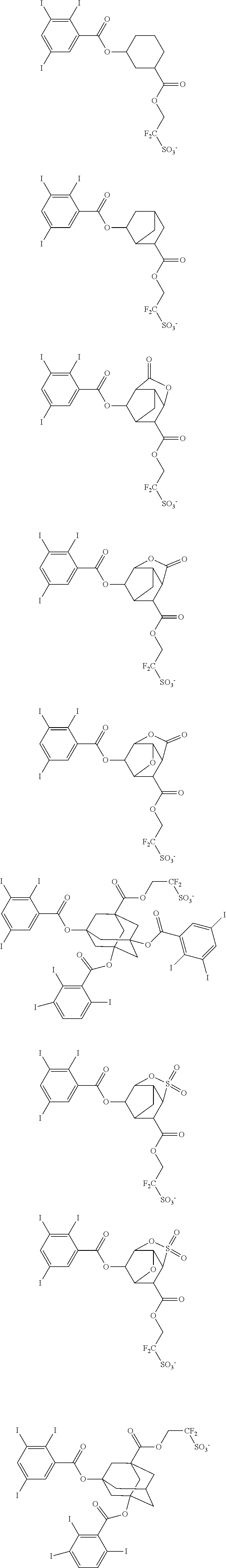

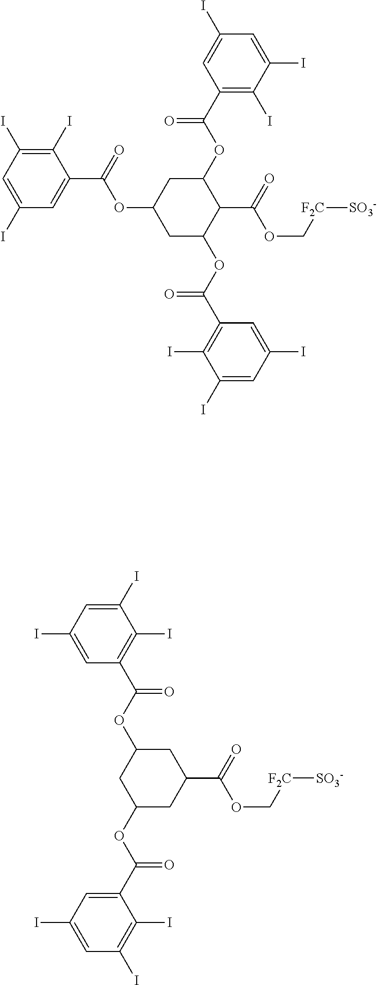

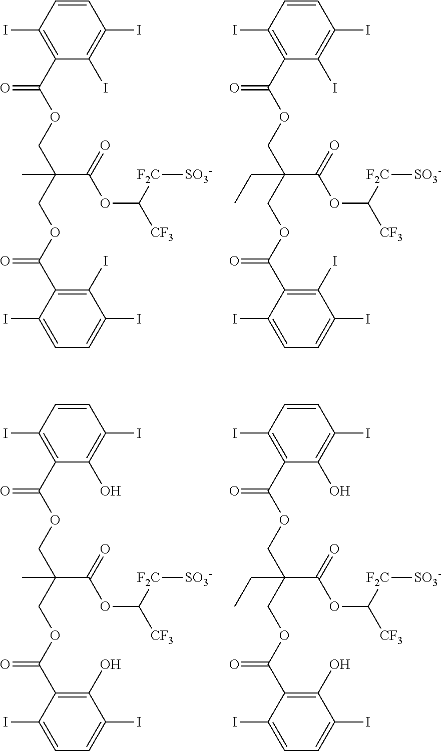

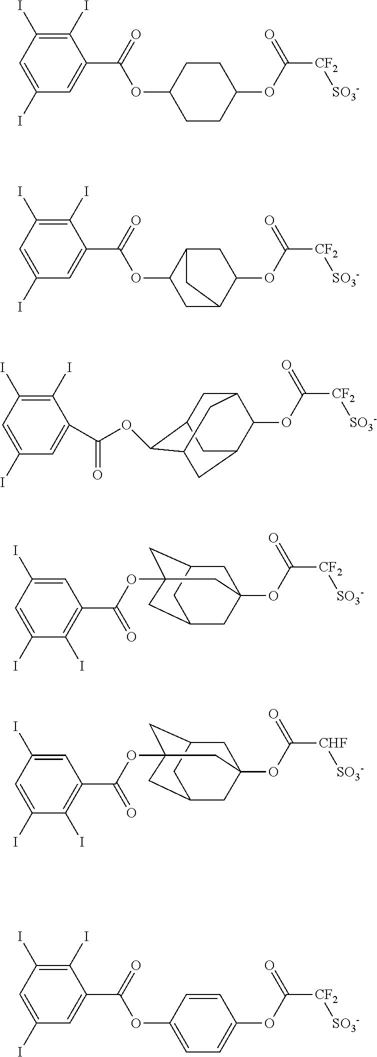

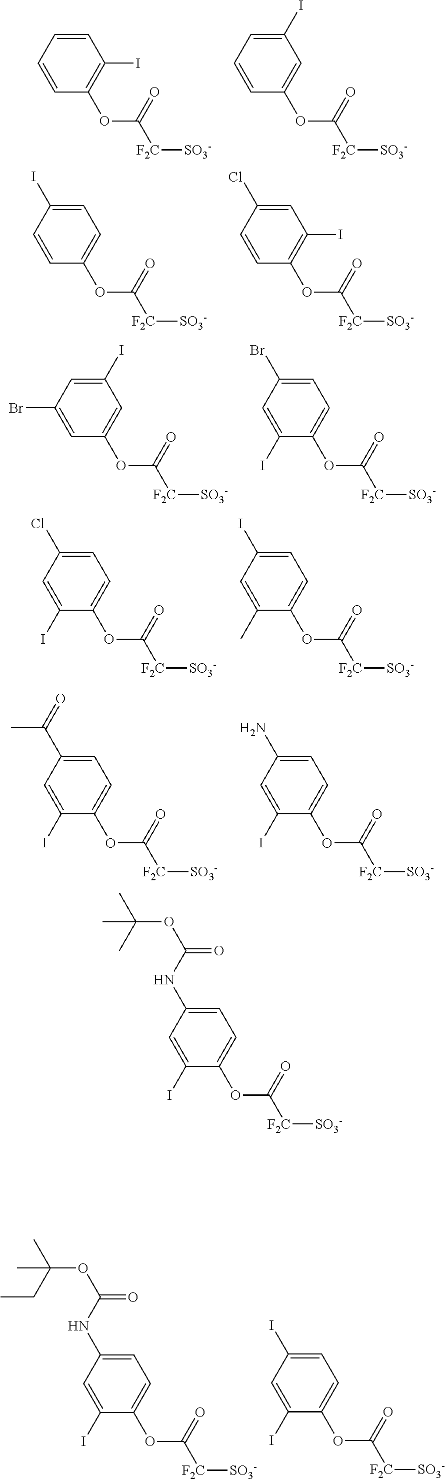

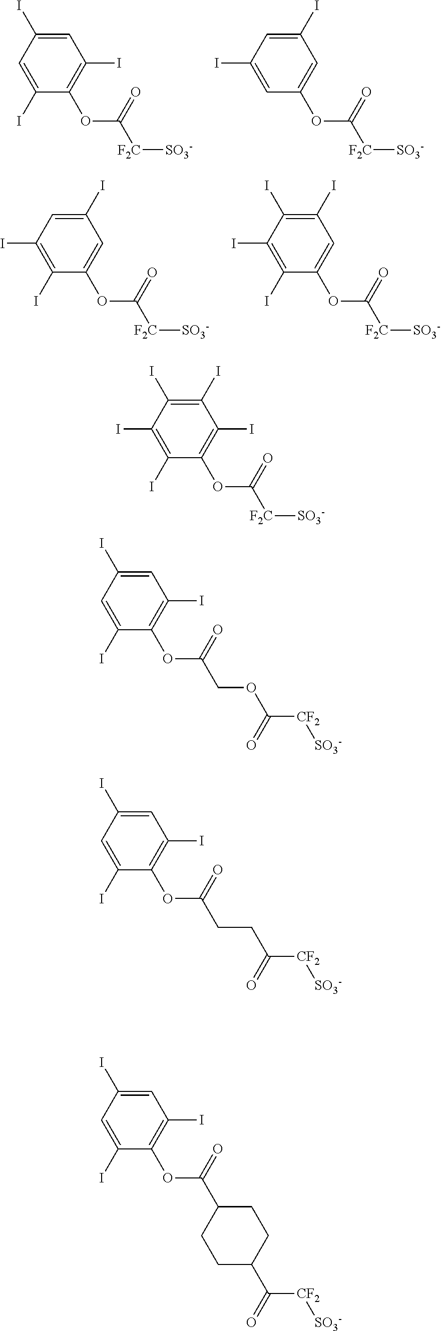

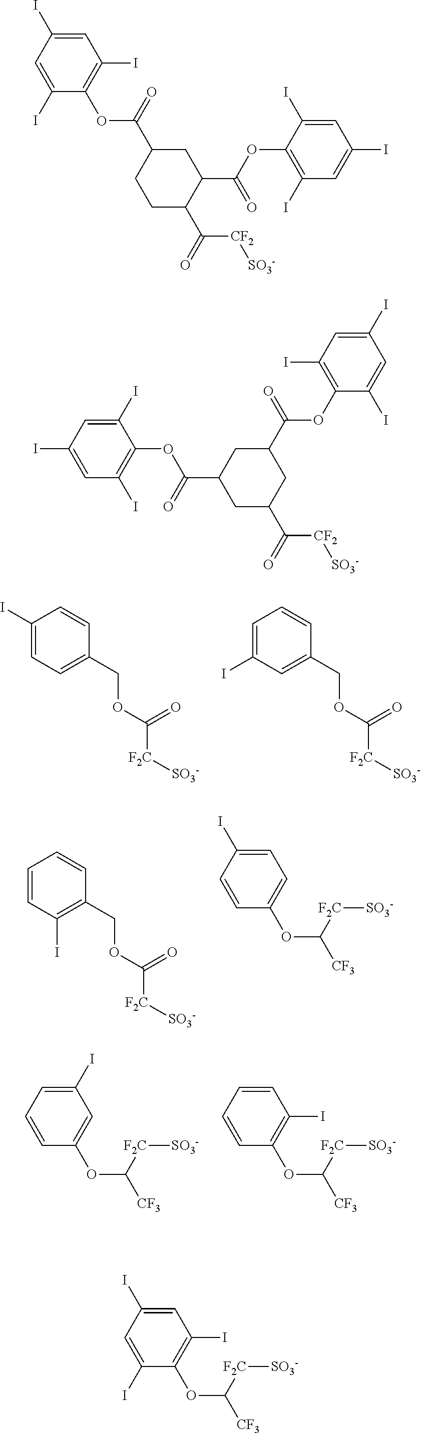

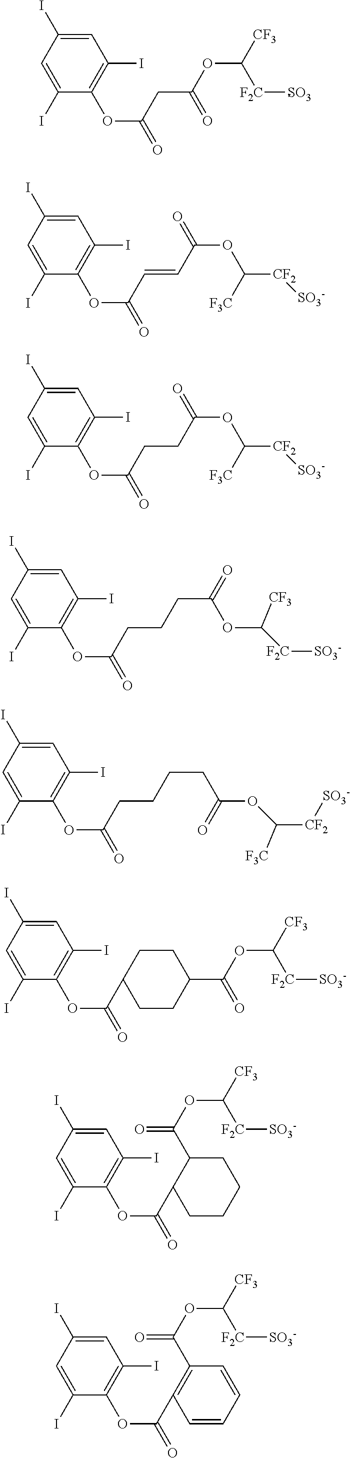

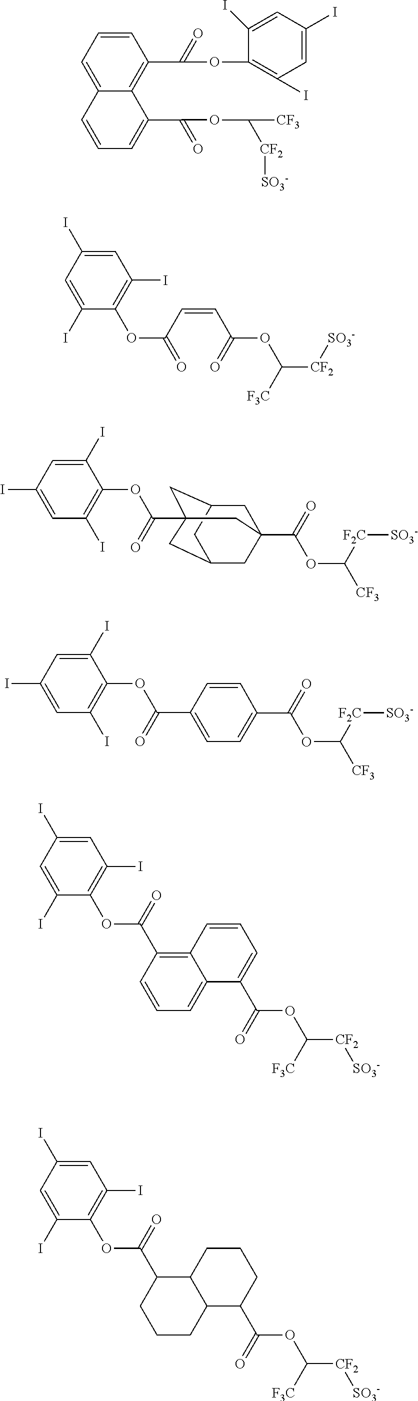

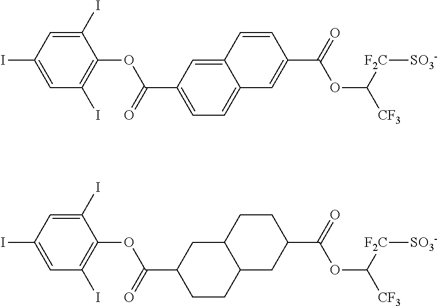

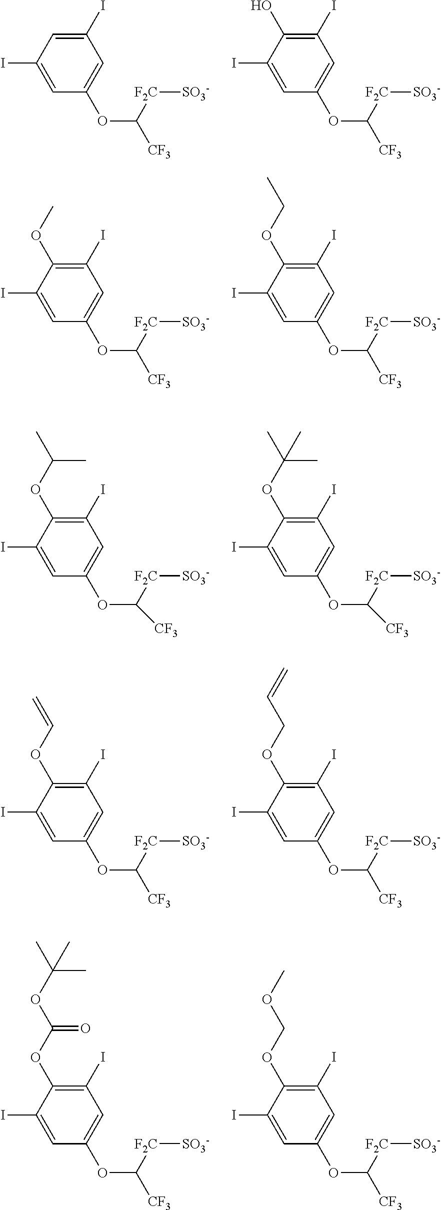

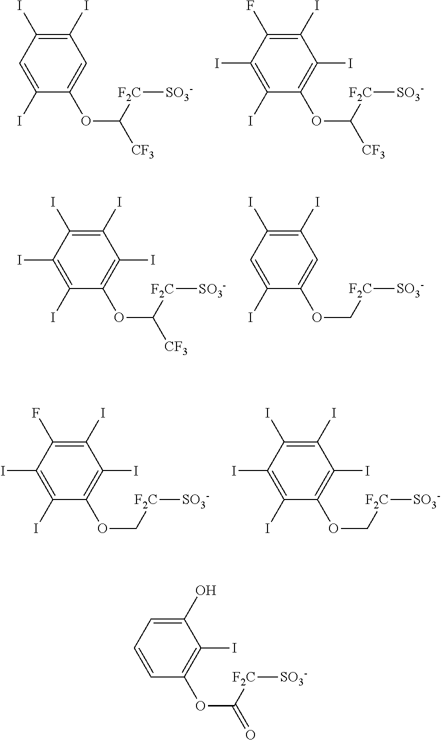

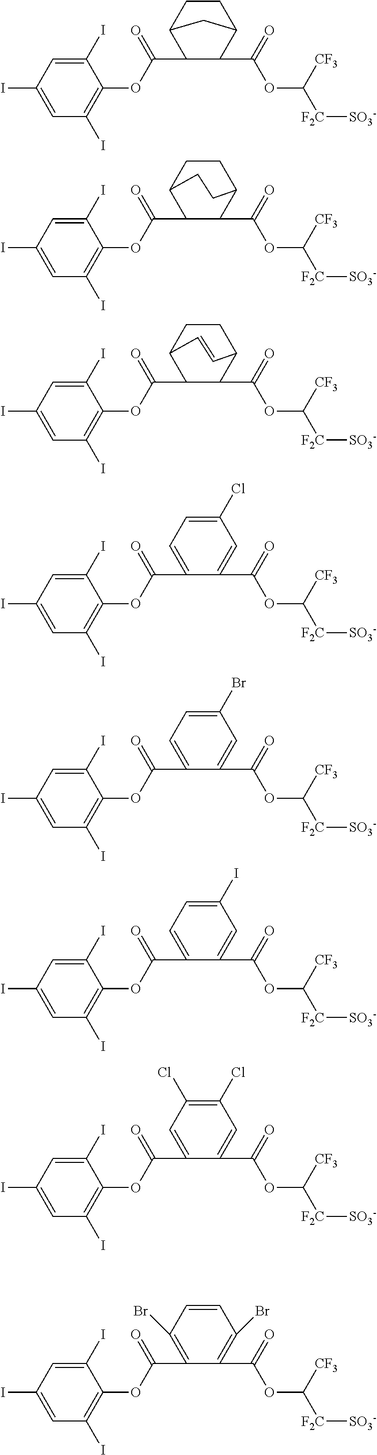

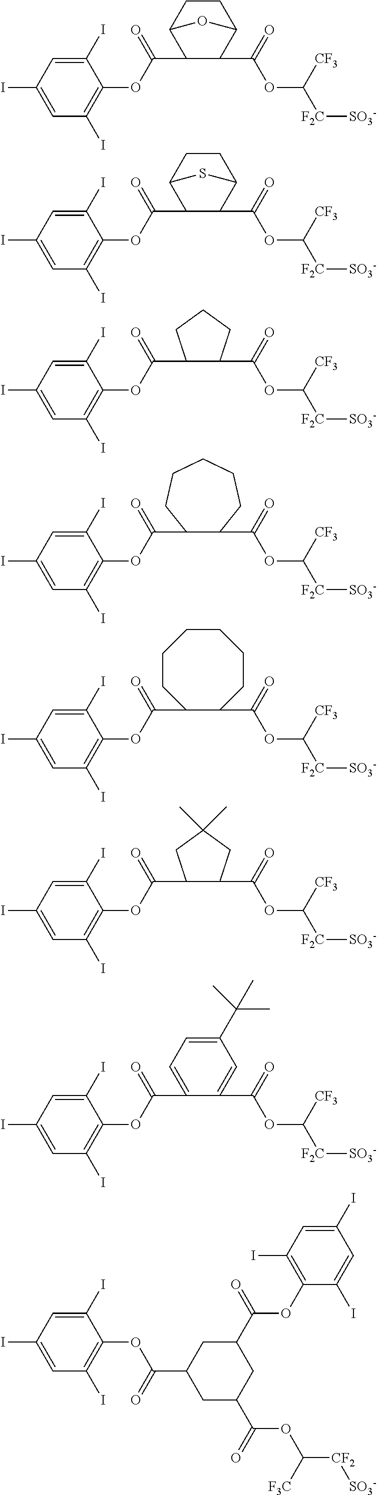

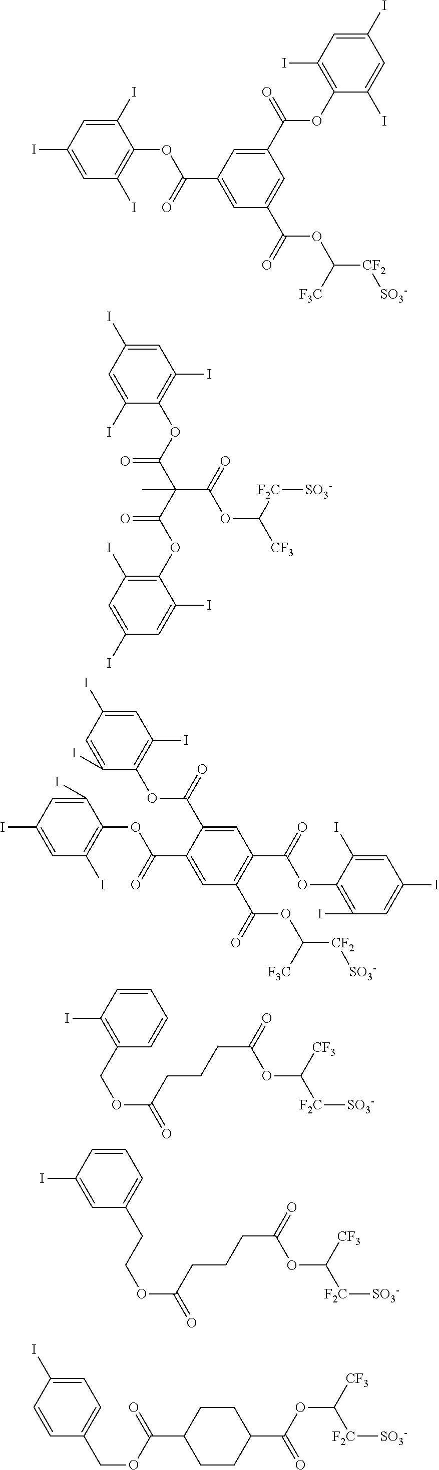

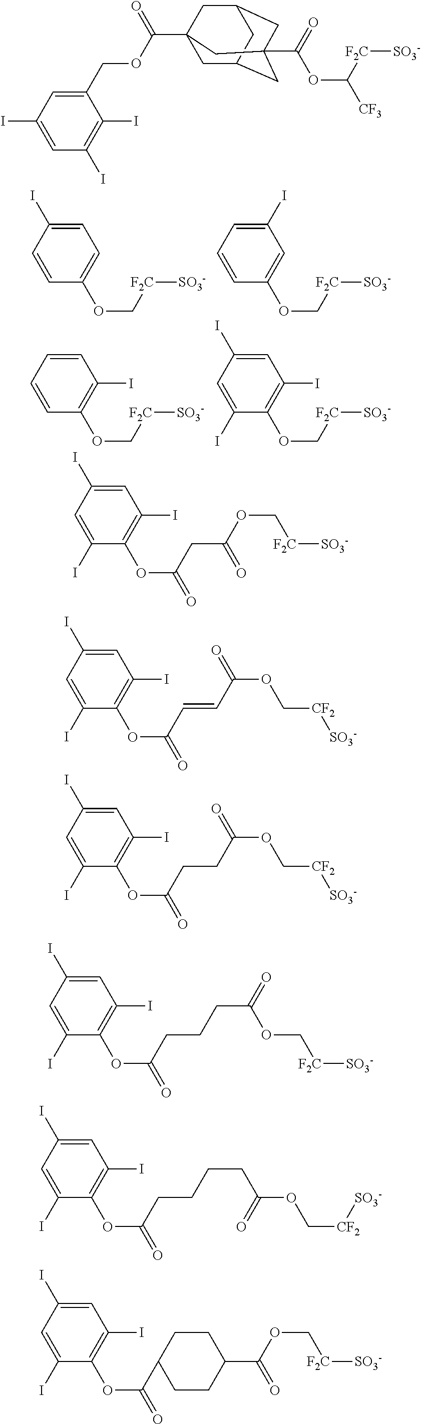

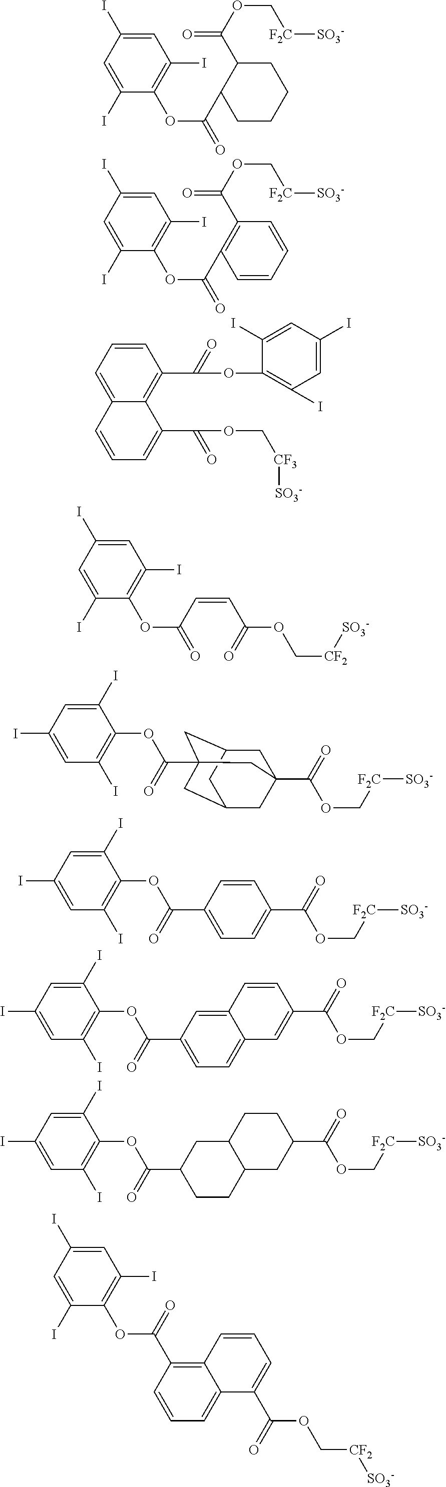

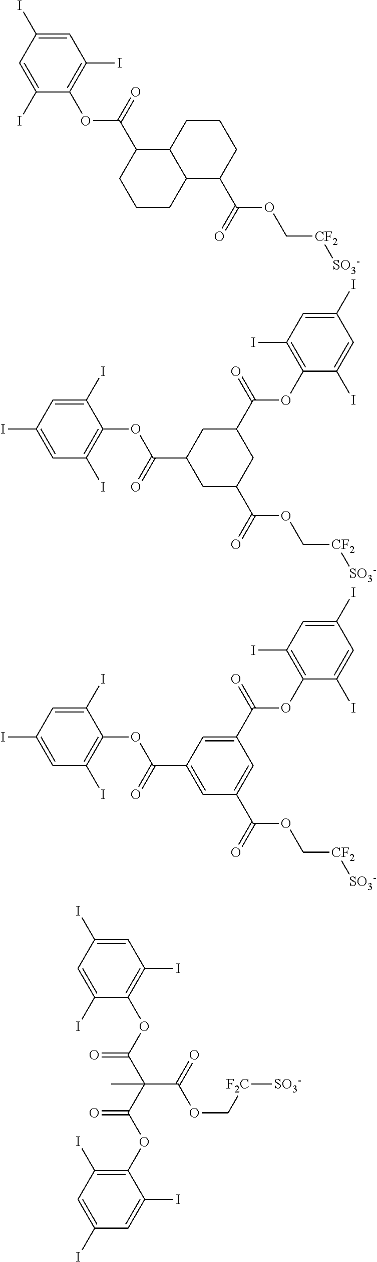

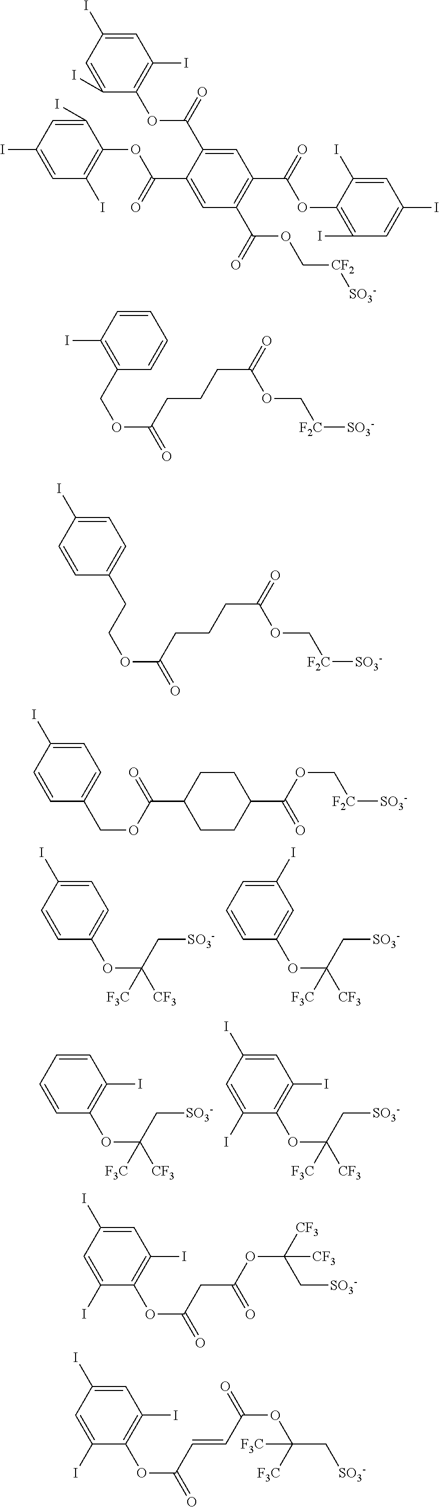

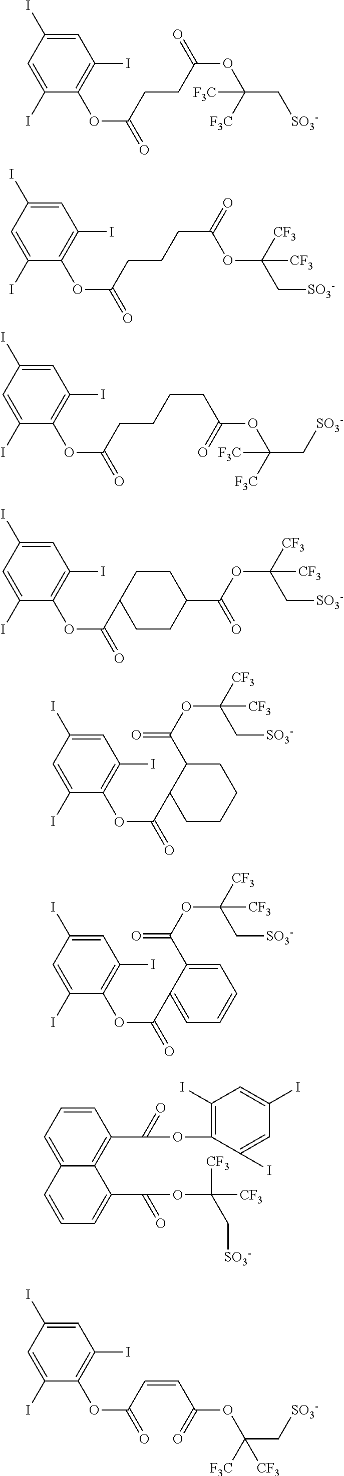

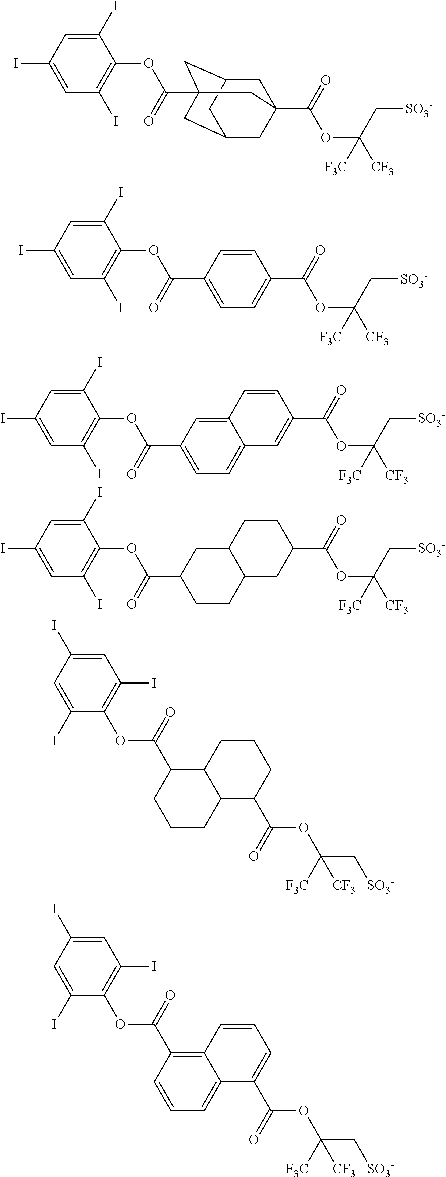

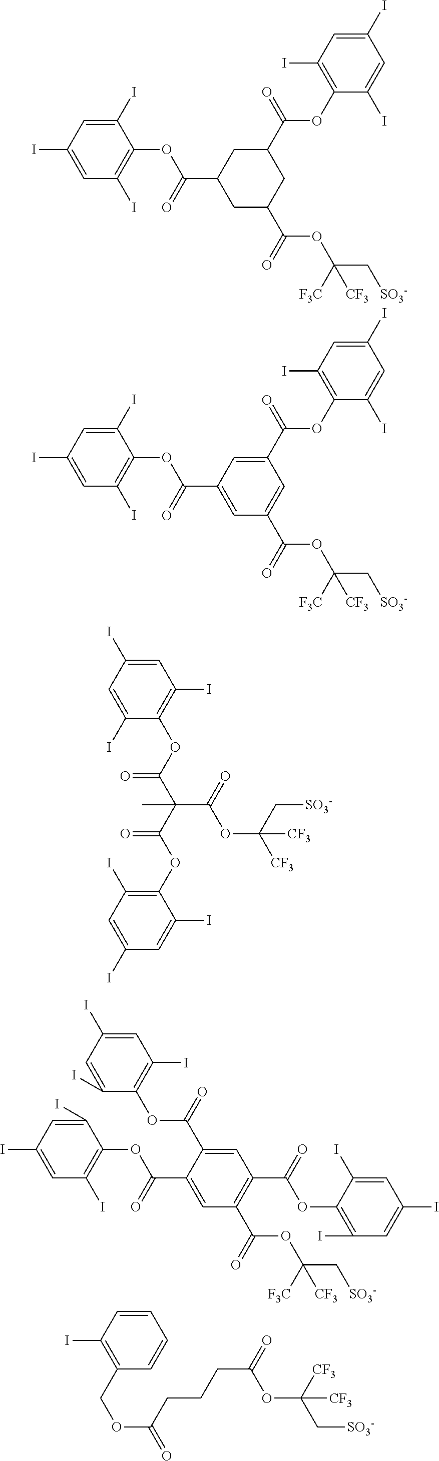

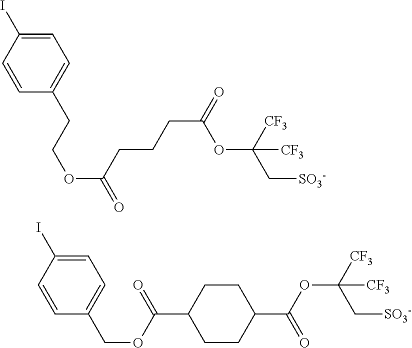

Specific examples of the onium cation moiety in the radiation-sensitive strong acid generator represented by the formula (pd-1) include the following. The onium cation moiety preferably contains a fluorine-substituted aromatic ring structure. All of those shown below are sulfonium cations containing a fluorine-substituted aromatic ring structure, but as an onium cation moiety not containing an aromatic ring structure having a fluorine atom, a structure in which a fluorine atom or CF₃ in the following formula is substituted with an atom or group other than a fluorine atom such as a hydrogen atom or another substituent can be suitably employed.

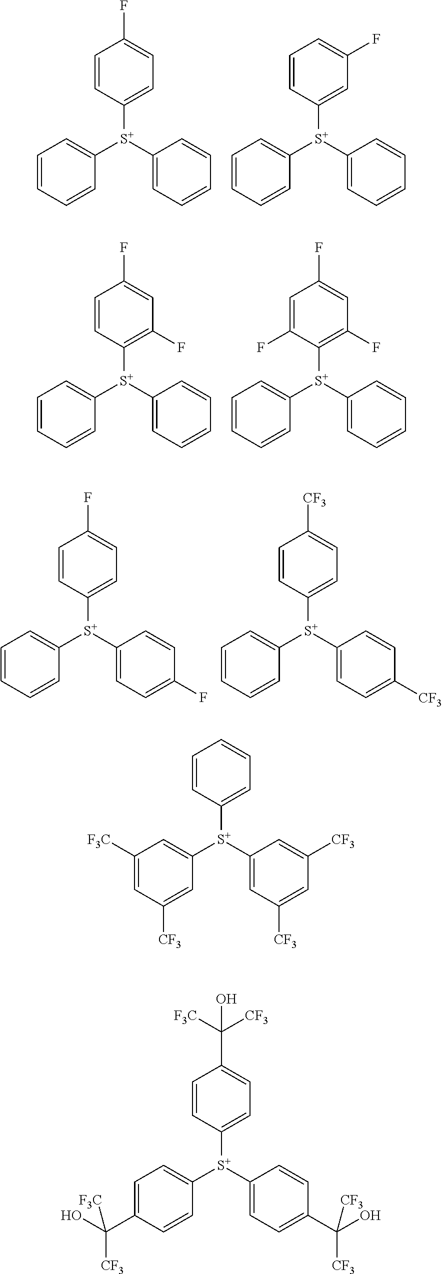

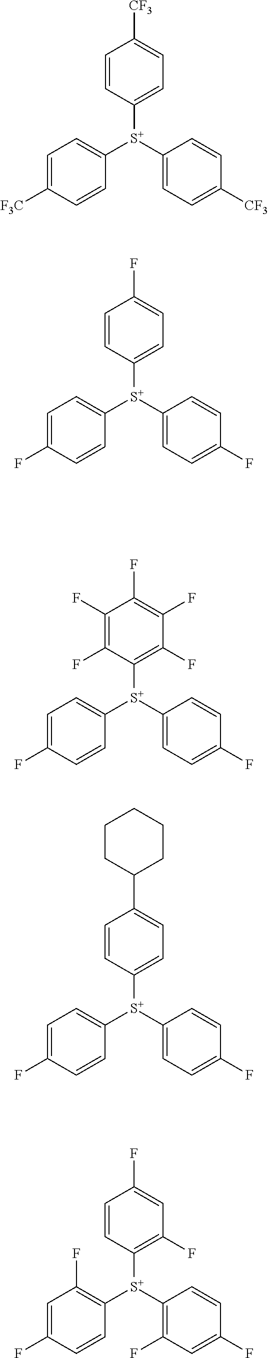 [SMILES: FC(F)(F)c1ccc([S+](c2ccc(C(F)(F)F)cc2)c2ccc(C(F)(F)F)cc2)cc1 ; Fc1ccc([S+](c2ccc(F)cc2)c2ccc(F)cc2)cc1 ; Fc1ccc([S+](c2ccc(F)cc2)c2c(F)c(F)c(F)c(F)c2F)cc1 ; Fc1ccc([S+](c2ccc(F)cc2)c2ccc(C3CCCCC3)cc2)cc1 ; Fc1ccc([S+](c2ccc(F)cc2F)c2ccc(F)cc2F)c(F)c1]

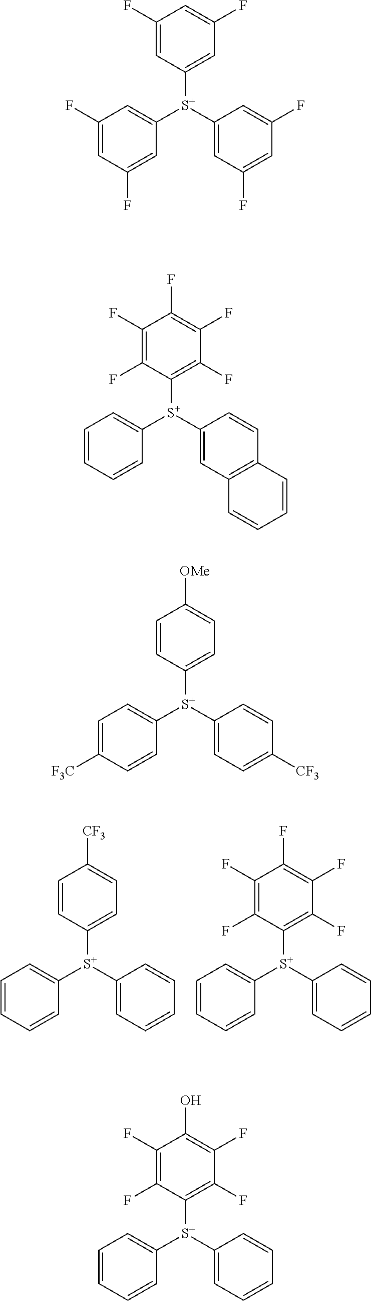 [SMILES: Fc1cc(F)cc([S+](c2cc(F)cc(F)c2)c2cc(F)cc(F)c2)c1 ; Fc1c(F)c(F)c([S+](c2ccccc2)c2ccc3ccccc3c2)c(F)c1F ; COc1ccc([S+](c2ccc(C(F)(F)F)cc2)c2ccc(C(F)(F)F)cc2)cc1 ; FC(F)(F)c1ccc([S+](c2ccccc2)c2ccccc2)cc1 ; Fc1c(F)c(F)c([S+](c2ccccc2)c2ccccc2)c(F)c1F ; Oc1c(F)c(F)c([S+](c2ccccc2)c2ccccc2)c(F)c1F]

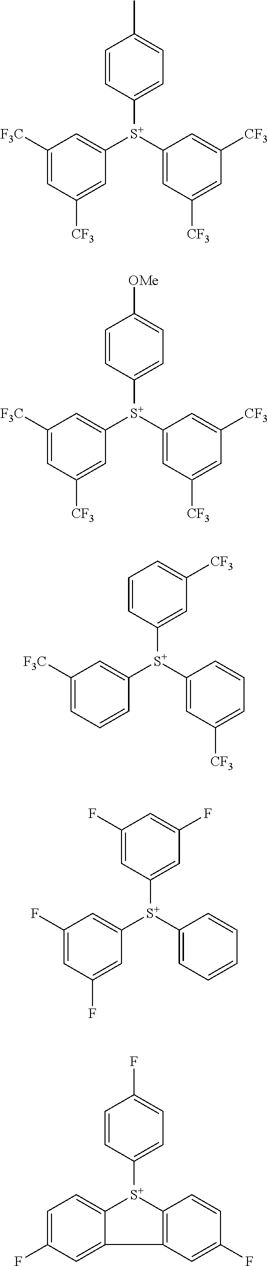 [SMILES: Cc1ccc([S+](c2cc(C(F)(F)F)cc(C(F)(F)F)c2)c2cc(C(F)(F)F)cc(C(F)(F)F)c2)cc1 ; COc1ccc([S+](c2cc(C(F)(F)F)cc(C(F)(F)F)c2)c2cc(C(F)(F)F)cc(C(F)(F)F)c2)cc1 ; FC(F)(F)c1cccc([S+](c2cccc(C(F)(F)F)c2)c2cccc(C(F)(F)F)c2)c1 ; Fc1cc(F)cc([S+](c2ccccc2)c2cc(F)cc(F)c2)c1 ; Fc1ccc(-[s+]2c3ccc(F)cc3c3cc(F)ccc32)cc1]

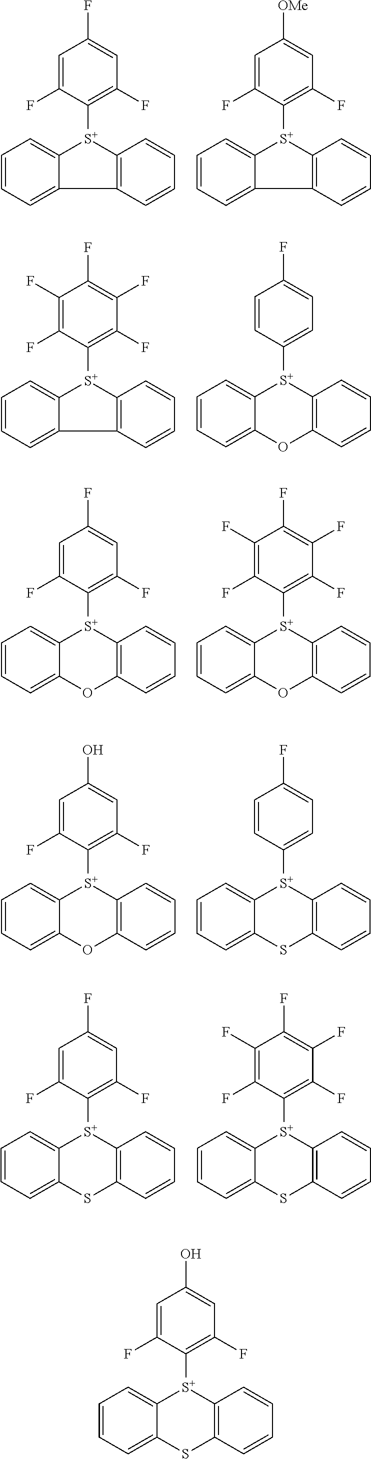

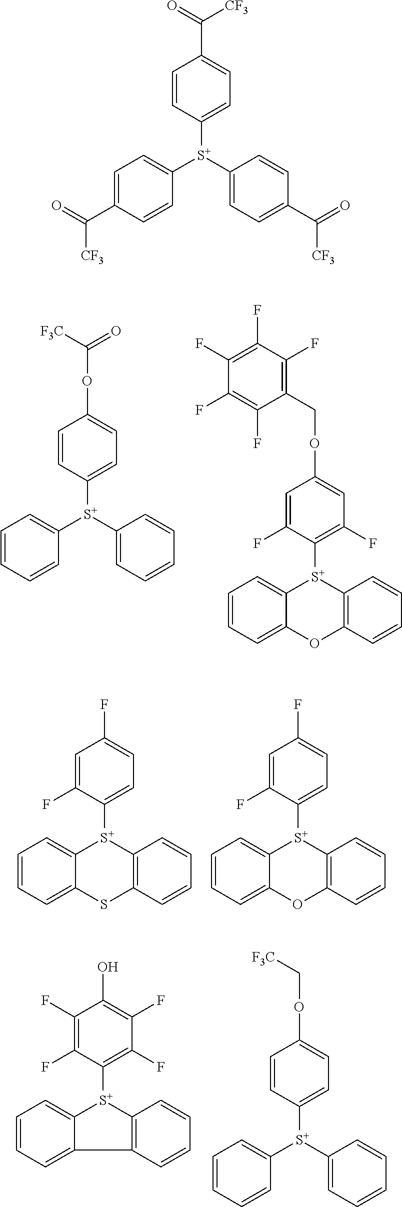

Specific examples of the onium cation moiety in the radiation-sensitive strong acid generator represented by the formula (pd-2) include the following. The onium cation moiety preferably contains a fluorine-substituted aromatic ring structure. All of those shown below are iodonium cations containing a fluorine-substituted aromatic ring structure, but as an onium cation moiety not containing an aromatic ring structure having a fluorine atom, a structure in which a fluorine atom or CF₃ in the following formula is substituted with an atom or group other than a fluorine atom such as a hydrogen atom or another substituent can be suitably employed.

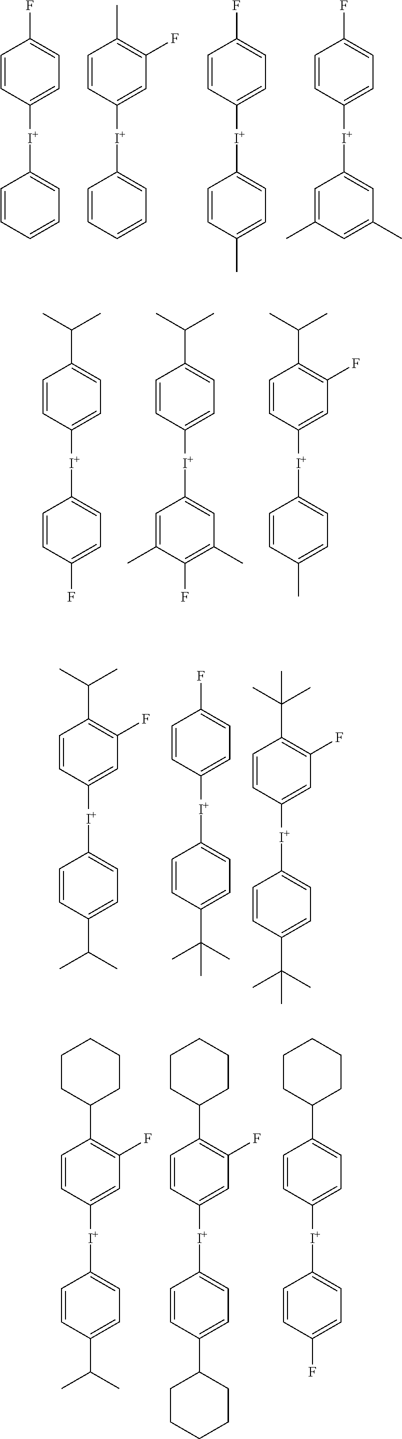

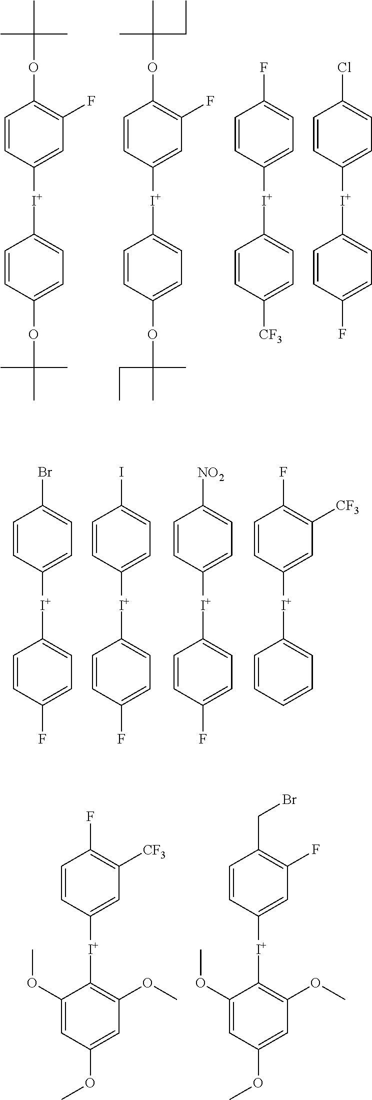

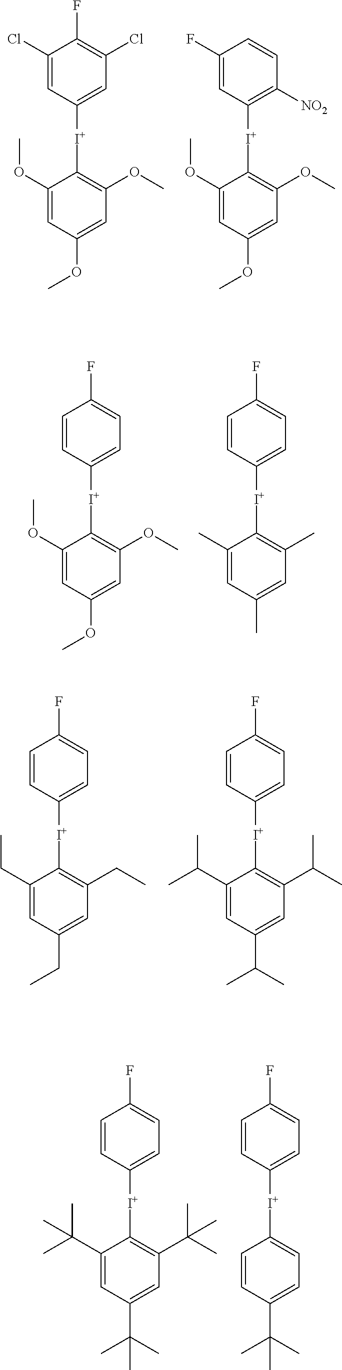

The radiation-sensitive acid generators represented by the above formulae (pd-1) and (pd-2) can also be synthesized by a known method, particularly by a salt exchange reaction.

These radiation-sensitive acid generators may be used alone or in combination of two or more thereof. The lower limit of the content of the radiation-sensitive acid generator is preferably 5 parts by mass, more preferably 10 parts by mass, and still more preferably 15 parts by mass, based on 100 parts by mass of a base resin (the total amount when at least one of a resin and a radiation-sensitive acid generating resin described later is contained in combination). The upper limit of the content is preferably 50 parts by mass, more preferably 40 parts by mass, and still more preferably 30 parts by mass. This makes it possible to exhibit excellent sensitivity and CDU performance when forming a resist pattern.

### (Acid Diffusion Controlling Agent)

The onium salt as the acid diffusion controlling agent is preferably represented by the following formula (ps-1) or the following formula (ps-2).

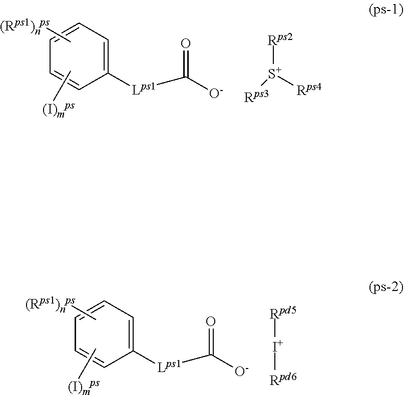

In the formulae (ps-1) and (ps-2), R^{ps1} represents a hydrogen atom, a hydroxy group, a fluorine atom, a chlorine atom, an amino group, a nitro group, a cyano group, an alkyl group having 1 to 6 carbon atoms, an alkoxy group having 1 to 6 carbon atoms, an acyloxy group having 2 to 6 carbon atoms, an alkylsulfonyloxy group having 1 to 4 carbon atoms, —NR^{ps1A}—C(═O)—R^{ps1B}, or —NR^{ps1A}—C(═O)—O—R^{ps1B}. The alkyl group having 1 to 6 carbon atoms, the alkoxy group having 1 to 6 carbon atoms, the acyloxy group having 2 to 6 carbon atoms, and the alkylsulfonyloxy group having 1 to 4 carbon atoms may be substituted with a halogen atom. R^{ps1A} is a hydrogen atom or an alkyl group having 1 to 6 carbon atoms, and R^{ps1B} is an alkyl group having 1 to 6 carbon atoms or an alkenyl group having 2 to 8 carbon atoms.

The alkyl group having 1 to 6 carbon atoms may be linear, branched, or cyclic, and specific examples thereof include a methyl group, an ethyl group, an n-propyl group, an isopropyl group, a cyclopropyl group, an n-butyl group, an isobutyl group, a sec-butyl group, a tert-butyl group, a cyclobutyl group, an n-pentyl group, a cyclopentyl group, an n-hexyl group, and a cyclohexyl group. Examples of the alkyl moiety of the alkoxy group having 1 to 6 carbon atoms, the acyloxy group having 2 to 7 carbon atoms, and the alkoxycarbonyl group having 2 to 7 carbon atoms include the same as the above-described specific examples of the alkyl group, and examples of the alkyl moiety of the alkylsulfonyloxy group having 1 to 4 carbon atoms include those having 1 to 4 carbon atoms among the above-described specific examples of the alkyl group. The alkenyl group having 2 to 8 carbon atoms may be linear, branched, or cyclic, and specific examples thereof include a vinyl group, a 1-propenyl group, and a 2-propenyl group. Among them, R^{ps1} is preferably a hydrogen atom, a fluorine atom, a chlorine atom, a hydroxy group, an amino group, an alkyl group having 1 to 3 carbon atoms, an alkoxy group having 1 to 3 carbon atoms, an acyloxy group having 2 to 4 carbon atoms, —NR^{ps1A}—C(═O)—R^{ps1B}, or —NR^{ps1A}—C(═O)—O—R^{ps1B}.

R^{ps2}, R^{ps3}, R^{ps4}, R^{ps5}, and R^{ps6} are each independently a monovalent hydrocarbon group having 1 to 20 carbon atoms which may contain a hetero atom. R^{ps2}, R^{ps3}, and R^{ps4} include one or more fluorine atoms, and R^{ps5} and R^{ps6} include one or more fluorine atoms. Any two of R^{ps2}, R^{ps3}, and R^{ps4} may be bonded to each other to form a ring together with a sulfur atom to which they are bonded. The monovalent hydrocarbon group may be linear, branched, or cyclic, and specific examples thereof include an alkyl group having 1 to 12 carbon atoms, an alkenyl group having 2 to 12 carbon atoms, an alkynyl group having 2 to 12 carbon atoms, an aryl group having 6 to 20 carbon atoms, and an aralkyl group having 7 to 12 carbon atoms. Some or all of the hydrogen atoms of these groups may be substituted with a hydroxy group, a carboxy group, a halogen atom, a cyano group, an amide group, a nitro group, a mercapto group, a sultone group, a sulfone group, or a sulfonium salt-containing group, and some of the carbon atoms of these groups may be substituted with an ether bond, an ester bond, a carbonyl group, a carbonate group, or a sulfonic acid ester bond.

L^{ps1} is a single bond or a divalent linking group having 1 to 20 carbon atoms. Examples of the divalent linking group include groups formed by combining an ether bond, a carbonyl group, an ester bond, an amide bond, a sultone ring, a lactam ring, a carbonate bond, a carboxy group, and a divalent hydrocarbon group, and the divalent hydrocarbon group may be substituted with a halogen atom, a hydroxy group, or a carboxy group. Examples of the divalent hydrocarbon group include an alkylene group having 1 to 12 carbon atoms, a cycloalkylene group having 3 to 12 carbon atoms, or an arylene group having 6 to 10 carbon atoms.

m^{ps} and n^{ps} are integers satisfying 0≤m^{ps}≤5, 0≤n^{ps}≤3, and 0≤m^{ps}+n^{ps}≤5, and preferably integers satisfying 1≤m^{ps}≤3 and 0≤n^{ps}≤2.

Examples of the organic acid anion moiety of the acid diffusion controlling agent represented by the above formula (ps-1) or (ps-2) include, but are not limited to, those shown below. All of those shown below are organic acid anion moieties having an iodine-substituted aromatic ring structure, but as the organic acid anion moieties having no iodine-substituted aromatic ring structure, a structure in which an iodine atom in the following formula is substituted with an atom or group other than an iodine atom such as a hydrogen atom or another substituent can be suitably employed.

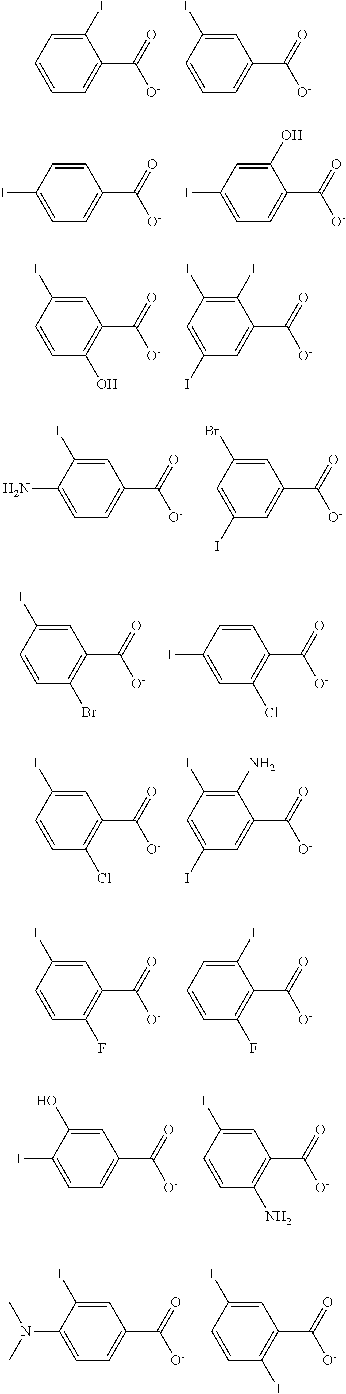

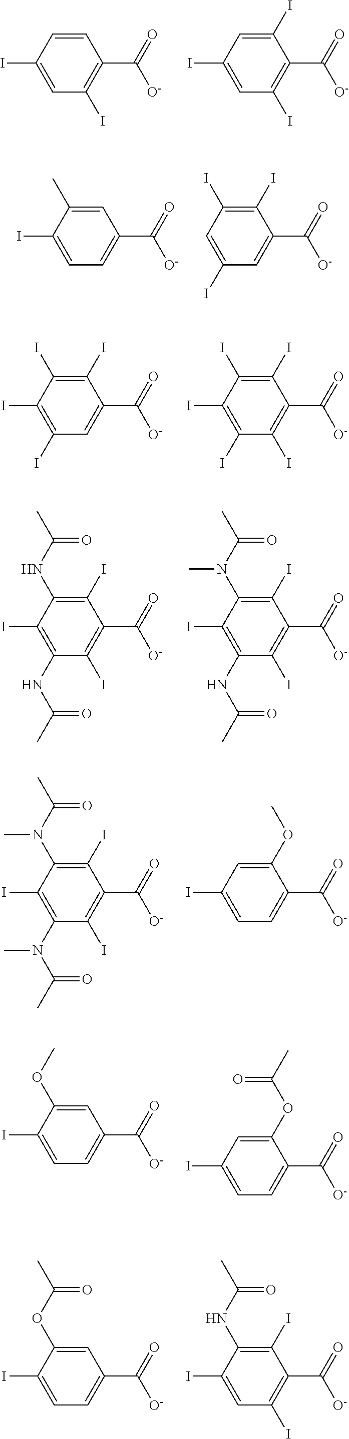

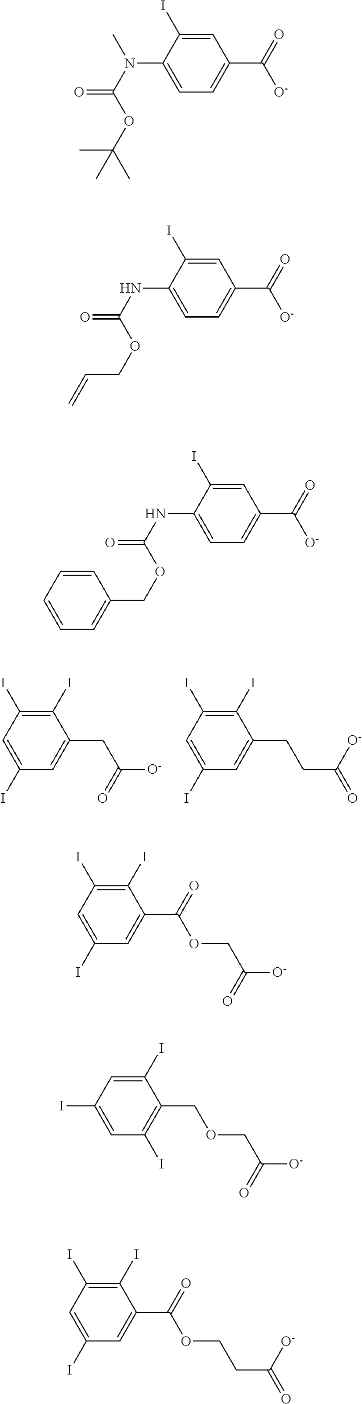

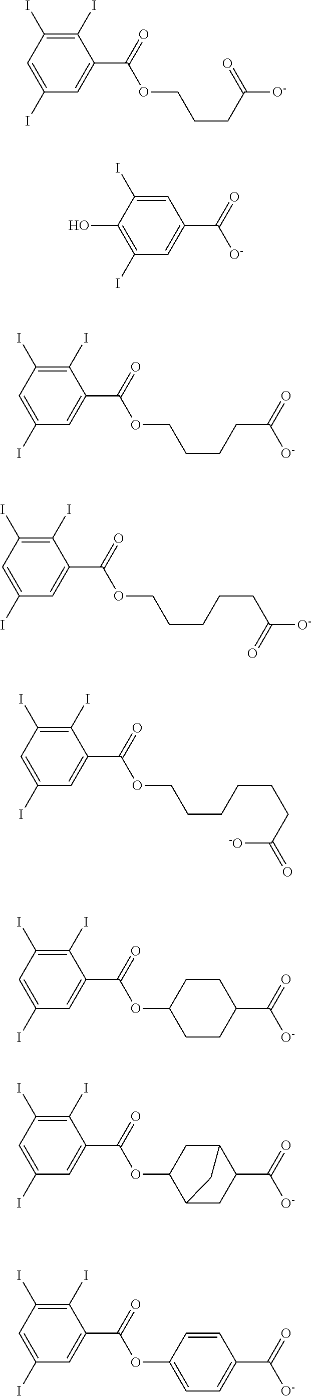

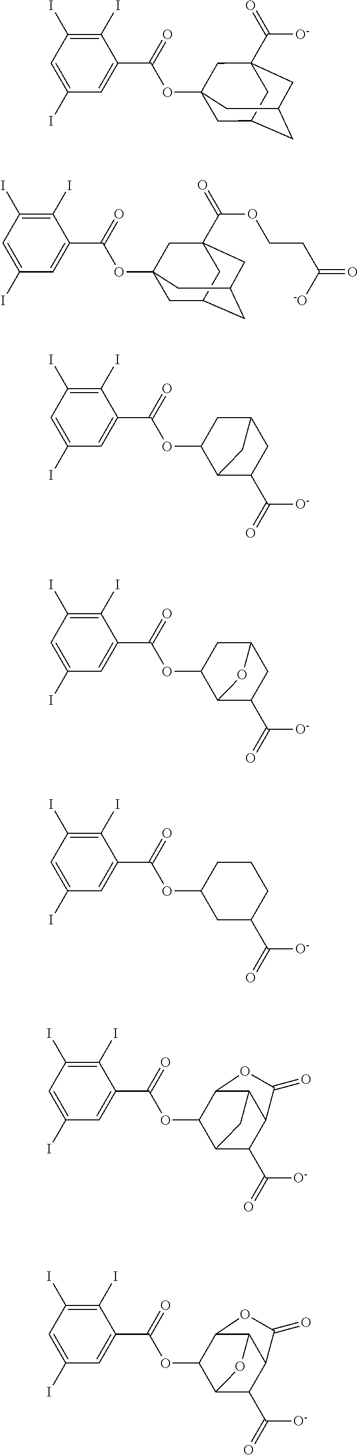

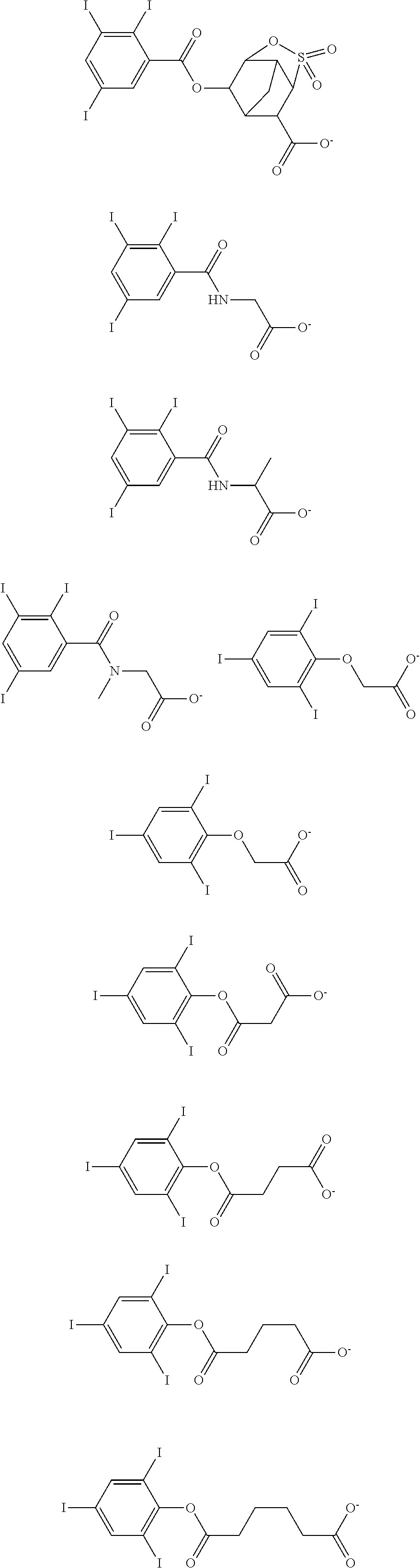

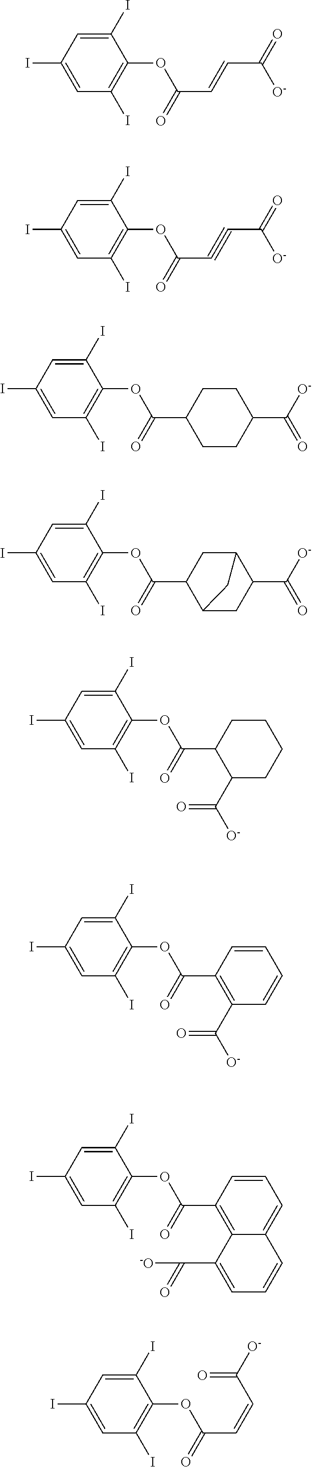

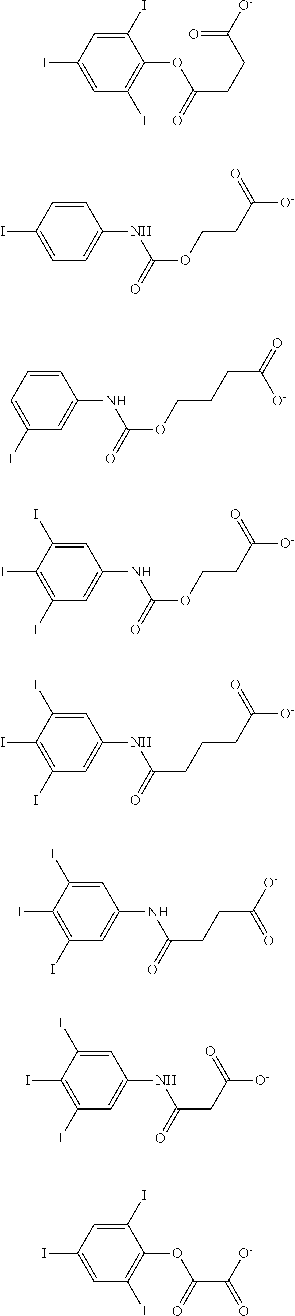

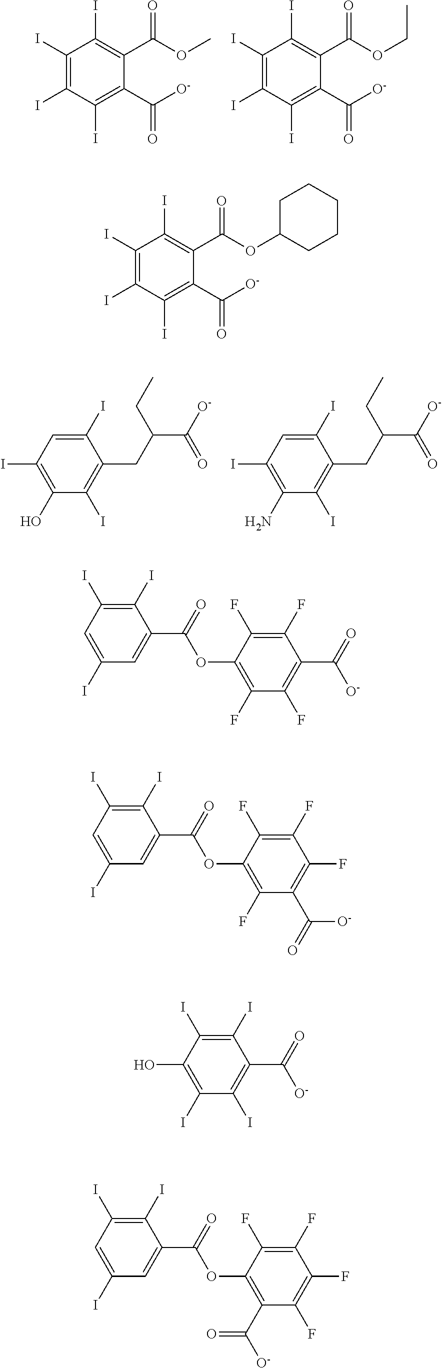

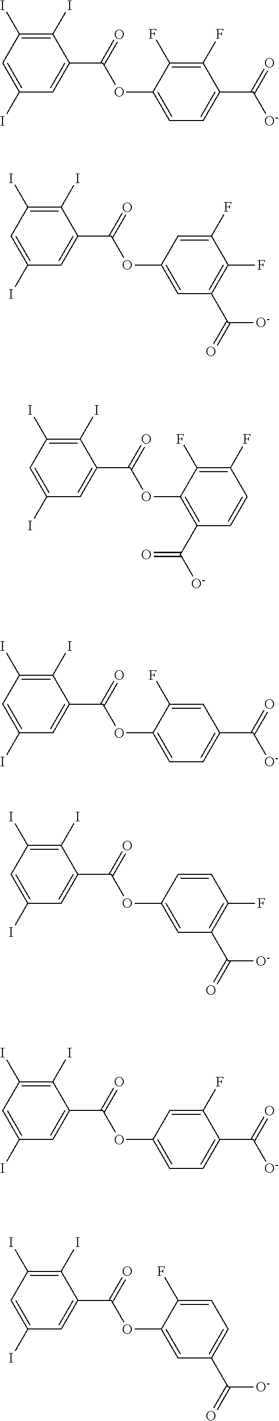

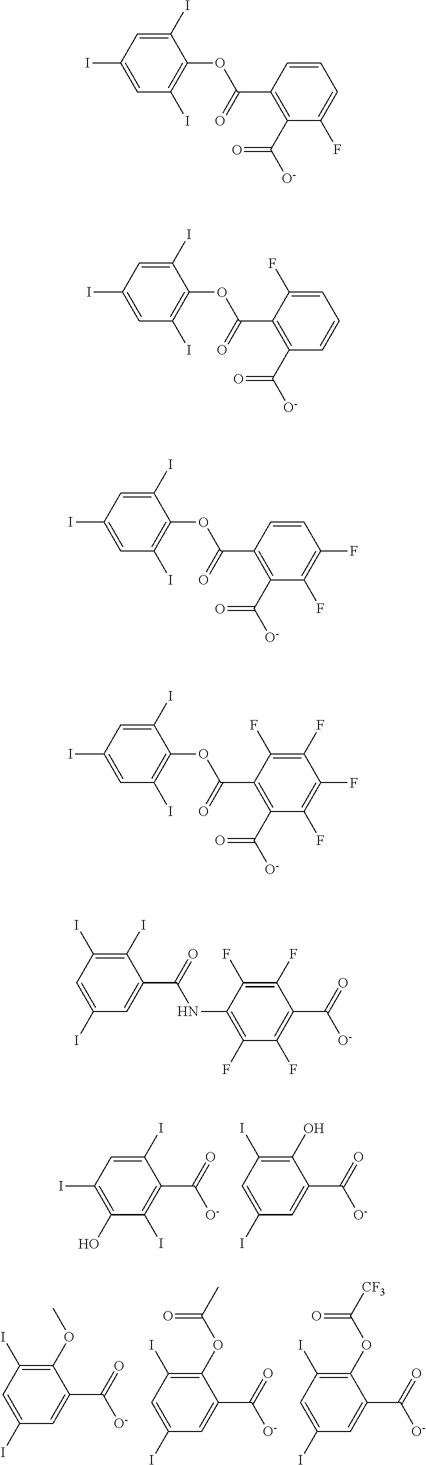

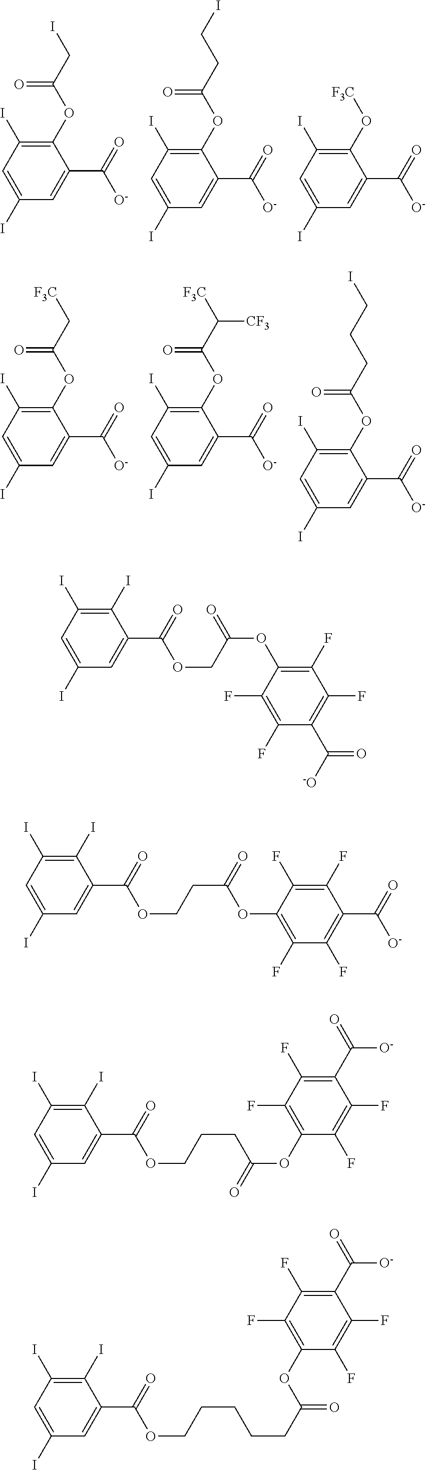

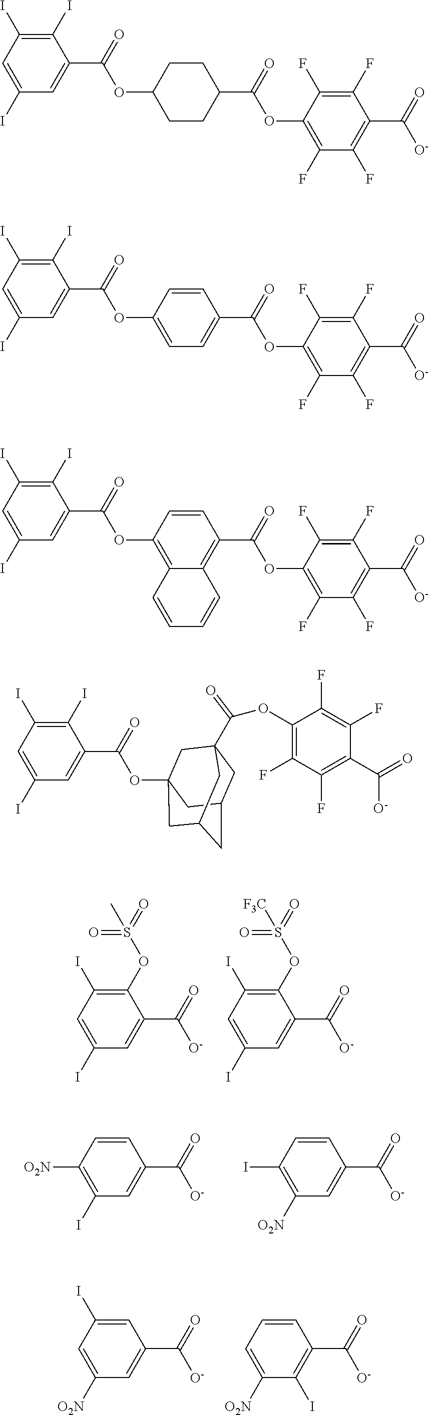

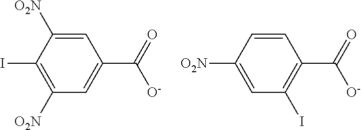 [SMILES: O=C([O-])c1cc([N+](=O)[O-])c(I)c([N+](=O)[O-])c1 ; O=C([O-])c1ccc([N+](=O)[O-])cc1I]

As the onium cation moiety in the acid diffusion controlling agent represented by the above formulae (ps-1) and (ps-2), the onium cation moiety in the radiation-sensitive strong acid generator can be suitably employed.

The acid diffusion controlling agents represented by the above formulae (ps-1) and (ps-2) can also be synthesized by a known method, particularly by a salt exchange reaction.

These acid diffusion controlling agents may be used alone or in combination of two or more thereof. The lower limit of the content ratio of the acid diffusion controlling agent is preferably 5% by mass, more preferably 10% by mass, and still more preferably 15% by mass, with respect to 100 parts by mass of the content of the radiation-sensitive acid generator (the total of the contents of the acid diffusion controlling agent and the structural unit in 100 parts by mass of the radiation-sensitive acid generating resin when the radiation-sensitive acid generating resin is contained). The upper limit of the content ratio is preferably 100% by mass, more preferably 80% by mass, and still more preferably 60% by mass. This makes it possible to exhibit excellent sensitivity and CDU performance when forming a resist pattern.

### (Structure of Other Organic Acid Anion Moiety)

The radiation-sensitive acid generator (including both the radiation-sensitive strong acid generator and the acid diffusion controlling agent) may include, as the organic acid anion moiety, a structure represented by the following formula (bd1) together with or in place of the organic acid anion moiety of the radiation-sensitive strong acid generator represented by the above formulae (pd-1) and (pd-2) or the organic acid anion moiety of the acid diffusion controlling agent represented by the above formula (ps-1) or (ps-2).

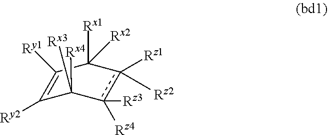

In the formula (bd1), R^{x1} to R^{x4} each independently represent a hydrogen atom, a substituted or unsubstituted hydrocarbon group, or a ring structure formed by combining two or more of these groups with each other.

R^{y1} to R^{y2} each independently represent a hydrogen atom, a substituted or unsubstituted hydrocarbon group, or a ring structure formed by combining the groups with each other.

[symbol]

is a double bond or a single bond.

R^{z1} to R^{z4} each independently represent a hydrogen atom, a substituted or unsubstituted hydrocarbon group, or a ring structure formed by combining two or more of these groups with each other. However, at least one of R^{x1} to R^{x4}, R^{y1} to R^{y2}, and R^{z1} to R^{z4} has an acid anion structure.

Each of the hydrocarbon groups in R^{x1} to R^{x4}, R^{y1} to R^{y2}, and R^{z1} to R^{z4} may be an aliphatic hydrocarbon group, an aromatic hydrocarbon group, a cyclic hydrocarbon group, or a chain hydrocarbon group.

Examples of the hydrocarbon group which may have a substituent in R^{x1} to R^{x4}, R^{y1} to R^{y2}, and R^{z1} to R^{z4} include a cyclic group which may have a substituent, a chain alkyl group which may have a substituent, or a chain alkenyl group which may have a substituent.

The cyclic group which may have a substituent is preferably a cyclic hydrocarbon group, and the cyclic hydrocarbon group may be an aromatic hydrocarbon group or an aliphatic hydrocarbon group. The aliphatic hydrocarbon group means a hydrocarbon group having no aromaticity. The aliphatic hydrocarbon group may be saturated or unsaturated, and is usually preferably saturated. The cyclic hydrocarbon group in R^{x1} to R^{x4}, R^{y1} to R^{y2}, and R^{z1} to R^{z4} may contain a hetero atom such as a heterocyclic ring.

In the formula (bd1), at least one of R^{x1} to R^{x4}, R^{y1} to R^{y2}, and R^{z1} to R^{z4} has an acid anion structure, and the entire organic acid anion moiety is an n-valent anion. n is an integer of 1 or more. The organic acid anion moiety represented by the above formula (bd1) acts as a radiation-sensitive strong acid generator that generates an acid acting on the acid-dissociable group in the base resin in the composition by selecting the acid anion structure in the molecule, or as an acid diffusion controlling agent that traps an acid generated from the radiation-sensitive strong acid generator upon exposure (controls the diffusion of the acid).

Examples of the acid anion structure of R^{x1} to R^{x4}, R^{y1} to R^{y2}, and R^{z1} to R^{z4} include those having a sulfonate anion structure, a carboanion structure, an imide anion structure, a methide anion structure, a carbonate anion structure, a borate anion structure, a halogen anion structure, a phosphate anion structure, an antimonate anion structure, and an arsenate anion structure and the like. Among them, those having a sulfonate anion structure and those having a carboxylate anion structure are preferable.

In the organic anion moiety represented by the formula (bd1), R^{x1} to R^{x4}, R^{y1} to R^{y2}, and R^{z1} to R^{z4} may be each the acid anion structure. When two or more of R^{x1} to R^{x4} are bonded to each other to form a ring structure, a carbon atom forming the ring structure or a hydrogen atom bonded to the carbon atom may be substituted with the acid anion structure. When two or more of R^{y1} to R^{y2} are bonded to each other to form a ring structure, a carbon atom forming the ring structure or a hydrogen atom bonded to the carbon atom may be substituted with the acid anion structure. When two or more of R^{z1} to R^{z4} are bonded to each other to form a ring structure, a carbon atom forming the ring structure or a hydrogen atom bonded to the carbon atom may be substituted with the acid anion structure.

The organic acid anion moiety preferably contains a partial structure represented by the following formula (b1) or (b2).

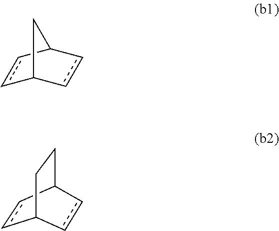

(In the above formula,

[symbol]

represents a single bond or a double bond.)

Specific examples of the organic anion moiety represented by the formula (bd1) include, but are not limited to, those shown below.

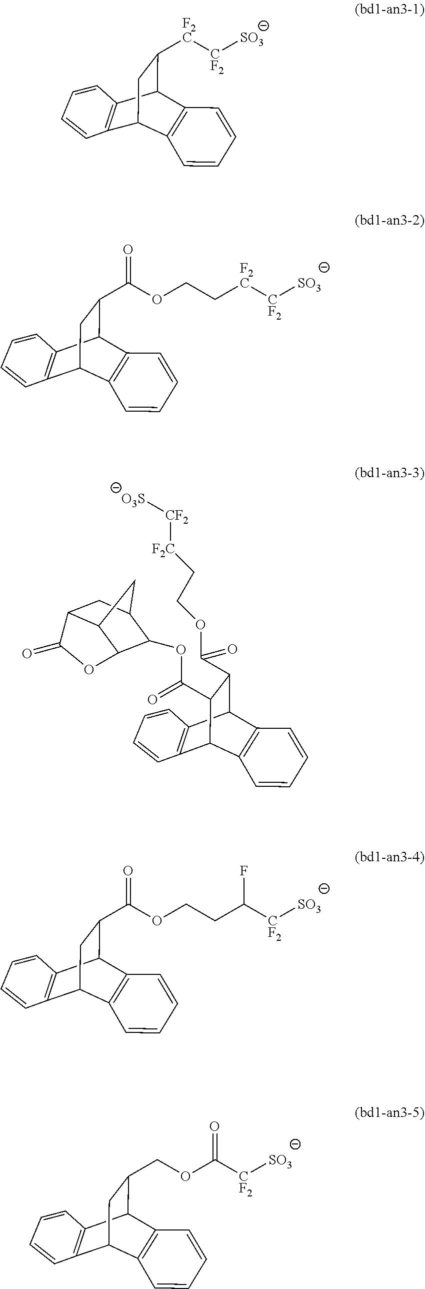

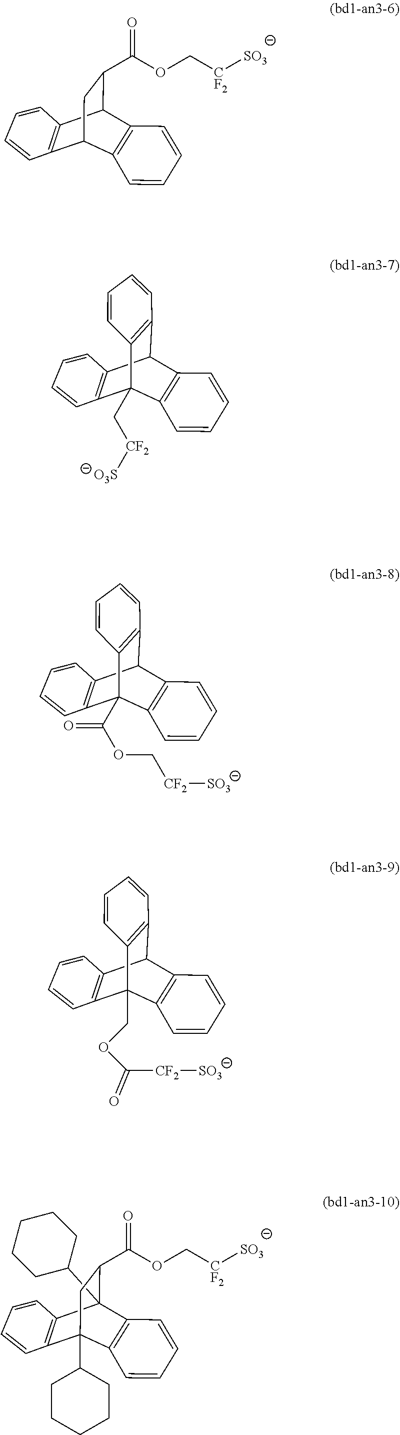

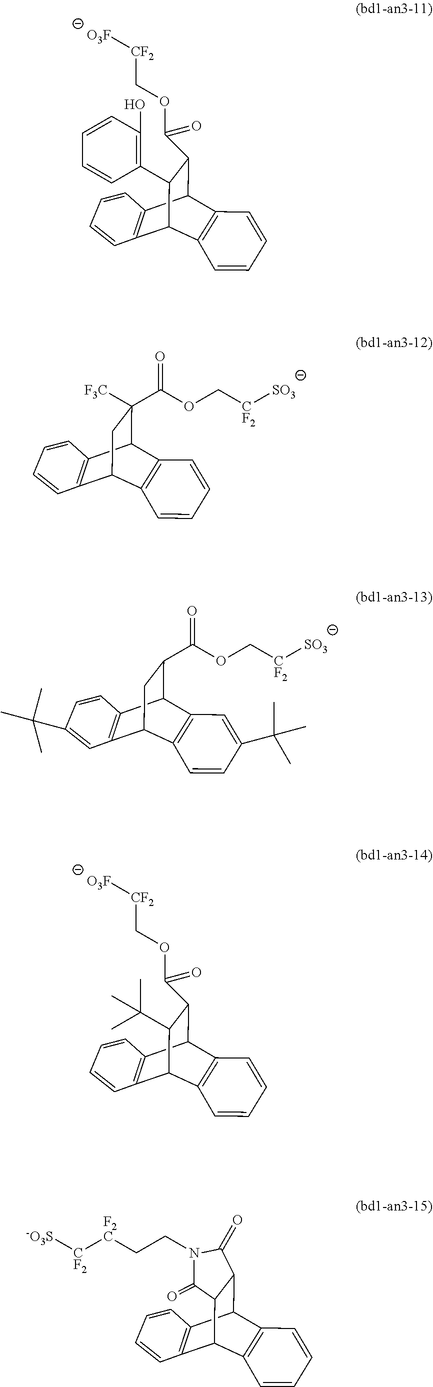

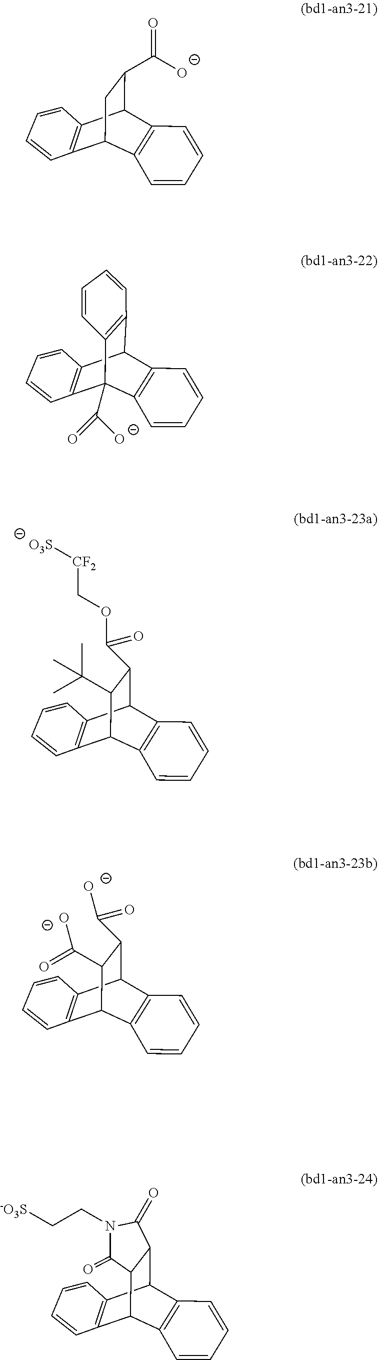

### <Resin>

The resin contains a structural unit A having an acid-dissociable group. In addition to the structural unit A, the resin may contain a structural unit B having a phenolic hydroxyl group, and a structural unit C containing a lactone structure or the like, and the like. Each structural unit will be described below.

### (Structural Unit A)

The structural unit A is represented by the following formula (1).

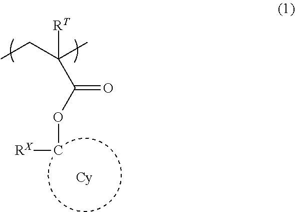

In the formula (1), R^{T} is a hydrogen atom, a fluorine atom, a methyl group, or a trifluoromethyl group.

R^{X} is a monovalent hydrocarbon group having 1 to 20 carbon atoms.

Cy represents an alicyclic structure having 3 to 20 ring members formed together with a carbon atom to which Cy is bonded.

Examples of the monovalent hydrocarbon group having 1 to 20 carbon atoms represented by R^{X} include a chain hydrocarbon group having 1 to 10 carbon atoms, a monovalent alicyclic hydrocarbon group having 3 to 20 carbon atoms, and a monovalent aromatic hydrocarbon group having 6 to 20 carbon atoms.

Examples of the chain hydrocarbon group having 1 to 10 carbon atoms include a linear or branched saturated hydrocarbon group having 1 to 10 carbon atoms, or a linear or branched unsaturated hydrocarbon group having 1 to 10 carbon atoms.

Examples of the alicyclic hydrocarbon group having 3 to 20 carbon atoms include a monocyclic or polycyclic saturated hydrocarbon group or a monocyclic or polycyclic unsaturated hydrocarbon group. The monocyclic saturated hydrocarbon group is preferably a cyclopentyl group, a cyclohexyl group, a cycloheptyl group, or a cyclooctyl group. The polycyclic cycloalkyl group is preferably a bridged alicyclic hydrocarbon group such as a norbornyl group, an adamantyl group, a tricyclodecyl group, or a tetracyclododecyl group. The bridged alicyclic hydrocarbon group refers to a polycyclic alicyclic hydrocarbon group in which two carbon atoms not adjacent to each other among carbon atoms constituting an alicyclic ring are bonded by a bond chain containing one or more carbon atoms.

Examples of the monovalent aromatic hydrocarbon group having 6 to 20 carbon atoms include aryl groups such as a phenyl group, a tolyl group, a xylyl group, a naphthyl group, and an anthryl group; and aralkyl groups such as a benzyl group, a phenethyl group, and a naphthylmethyl group.

R^{X} is preferably a linear or branched saturated hydrocarbon group having 1 to 5 carbon atoms and an alicyclic hydrocarbon group having 3 to 12 carbon atoms.

The alicyclic structure having 3 to 20 ring members in Cy is not particularly limited as long as the alicyclic structure is included. The alicyclic structure may have a monocyclic, bicyclic, tricyclic, tetracyclic, or more polycyclic structure, and may be any of a bridged cyclic structure, a spiro cyclic structure, a ring assembly structure in which a plurality of rings are directly bonded by a single bond or a double bond, or a combination thereof. Among them, it is preferable to have a monocyclic, bicyclic, tricyclic, or tetracyclic bridged cyclic structure, and a ring structure of any one of cyclopentane, cyclohexane, norbornane, adamantane, tricyclo[5.2.1.0^{2,6}]decane, tetracyclo[4.4.0.1^{2,5}.1^{7,10}]dodecane, perhydronaphthalene or perhydroanthracene, or a derivative thereof is more preferable.

The structural unit A is preferably represented by, for example, the following formulae (A-1) to (A-8).

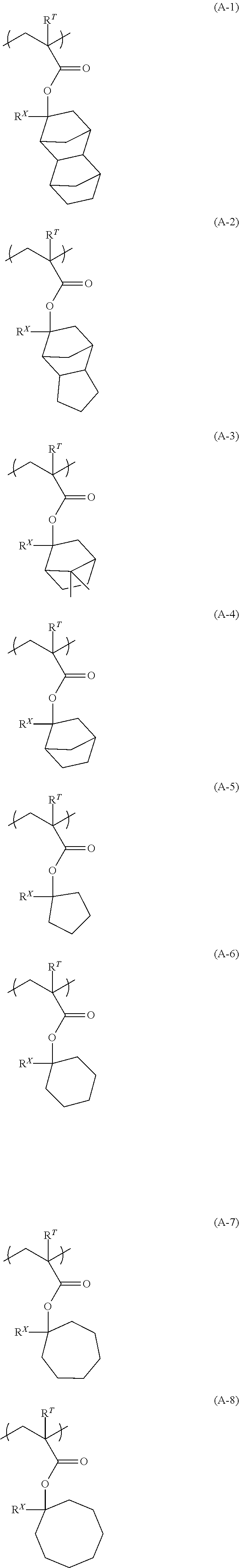

In the above formulae (A-1) to (A-8), R^{T} and R^{X} have the same meanings as those in the above formula (1). Among them, the structural unit A is preferably represented by, for example, the above formulae (A-1), (A-4), (A-5), (A-6), and (A-8).

The lower limit of the content ratio of the structural unit A in the resin (the total when there are a plurality of structural units A) is preferably 20 mol %, more preferably 30 mol %, and still more preferably 40 mol % with respect to the total structural units constituting the resin. The upper limit of the content ratio is preferably 80 mol %, more preferably 75 mol %, and still more preferably 65 mol %. The content ratio of the structural unit A is set within the above range, whereby the radiation-sensitive resin composition can have further improved sensitivity and CDU performance.

(Structural Unit B)

The structural unit B is a structural unit that contains a phenolic hydroxyl group or gives a phenolic hydroxyl group by the action of an acid. The embodiment of the present invention also includes, as a phenolic hydroxyl group of structural unit B, a phenolic hydroxyl group generated through deprotection by the action of an acid generated by exposure. The resin containing the structural unit B can adjust its solubility in a developer more appropriately, which as a result makes it possible to further improve the sensitivity etc. of the radiation-sensitive resin composition. Further, when KrF excimer laser light, EUV, an electron beam, or the like is used as a radioactive ray for irradiation in an exposure step in a method for forming a resist pattern, the structural unit B contributes to improved etching resistance and improved difference in solubility in a developer between an exposed part and a non-exposed part (dissolution contrast). Particularly, the structural unit C is suitably used when a pattern is formed by exposure using a radioactive ray having a wavelength of 50 nm or less such as an electron beam or EUV. The structural unit B is preferably represented by the following formula (B)

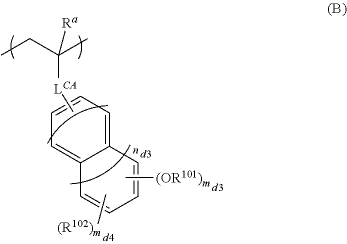

(wherein
R^{α} is a hydrogen atom, a fluorine atom, a methyl group, or a trifluoromethyl group,
L^{CA} is a single bond, —COO—*, or —O—*, wherein * represents a hand bonding to an aromatic ring,
R¹⁰¹ is a hydrogen atom or a protective group to be deprotected by action of an acid, and when two or more R⁴¹s are present, the two or more R⁴¹s are the same or different from each other,
R¹⁰² is a cyano group, a nitro group, an alkyl group, a fluorinated alkyl group, an alkoxycarbonyloxy group, an acyl group, or an acyloxy group, and when two or more R¹⁰²s are present, the two or more R¹⁰²s are the same or different from each other, and
n_{d3} is an integer of 0 to 2, m_{d3} is an integer of 1 to 8, and m_{d4} is an integer of 0 to 8, provided that n_{d3}, m_{d3}, and m_{d4} satisfy 1≤m_{d3}+m_{d4}≤2n_{d3}+5)

The R^{α} is preferably a hydrogen atom or a methyl group from the viewpoint of copolymerizability of the monomer giving the structural unit B.

L^{CA} is preferably a single bond or —COO—.

Examples of the protective group represented by R¹⁰¹ to be deprotected by the action of an acid include groups represented by the following formulas (Al-1) to (AL-3).

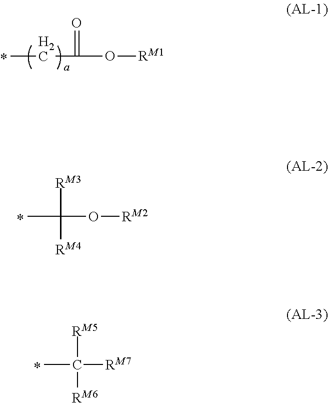

In the above formulas (AL-1) and (AL-2), R^{M1} and R^{M2} are each a monovalent hydrocarbon group, and may contain a hetero atom such as an oxygen atom, a sulfur atom, a nitrogen atom, or a fluorine atom. The monovalent hydrocarbon group may be linear, branched, or cyclic, and is preferably an alkyl group having 1 to 40 carbon atoms, more preferably an alkyl group having 1 to 20 carbon atoms. In the formula (AL-1), a is an integer of 0 to 10, preferably an integer of 1 to 5. In the above formulas (AL-1) to (AL-3), * represents a hand bonding to another moiety.

In the above formula (AL-2), R^{M3} and R^{M4} are each independently a monovalent hydrocarbon group, and may contain a hetero atom such as an oxygen atom, a sulfur atom, a nitrogen atom, or a fluorine atom. The monovalent hydrocarbon group may be linear, branched, or cyclic, and is preferably an alkyl group having 1 to 20 carbon atoms. Any two of R^{M2}, R^{M3}, and R^{M4} may be bonded together to form a ring having 3 to 20 carbon atoms together with a carbon atom or a carbon atom and an oxygen atom to which they are bonded. The ring is preferably a ring having 4 to 16 carbon atoms, particularly preferably an alicyclic ring.

In the above formula (AL-3), R^{M5}, R^{M6}, and R^{M7} are each independently a monovalent hydrocarbon group, and may contain a hetero atom such as an oxygen atom, a sulfur atom, a nitrogen atom, or a fluorine atom. The monovalent hydrocarbon group may be linear, branched, or cyclic, and is preferably an alkyl group having 1 to 20 carbon atoms. Any two of R^{M5}, R^{M6}, and R^{M7} may be bonded together to form a ring having 3 to 20 carbon atoms together with a carbon atom to which they are bonded. The ring is preferably a ring having 5 to 16 carbon atoms, particularly preferably an alicyclic ring.

Among them, the protective group to be deprotected by the action of an acid is preferably a group represented by the above formula (AL-3).

Examples of the alkyl group in R¹⁰² include linear or branched alkyl groups having 1 to 8 carbon atoms such as a methyl group, an ethyl group, and a propyl group. Examples of the fluorinated alkyl group include linear or branched fluorinated alkyl groups having 1 to 8 carbon atoms such as a trifluoromethyl group and a pentafluoroethyl group. Examples of the alkoxycarbonyloxy group include chain or alicyclic alkoxycarbonyloxy groups having 2 to 16 carbon atoms such as a methoxycarbonyloxy group, a butoxycarbonyloxy group, and an adamantylmethyloxycarbonyloxy group. Examples of the acyl group include aliphatic or aromatic acyl groups having 2 to 12 carbon atoms such as an acetyl group, apropionyl group, a benzoyl group, and an acryloyl group. Examples of the acyloxy group include aliphatic or aromatic acyloxy groups having 2 to 12 carbon atoms such as an acetyloxy group, a propionyloxy group, a benzoyloxy group, and an acryloyloxy group.

n_{d3} is preferably 0 or 1, more preferably 0.

m_{d3} is preferably an integer of 1 to 3, more preferably 1 or 2.

m_{d4} is an integer of 0 to 3, more preferably an integer of 0 to 2.

Preferred examples of the structural unit B include structural units represented by the following formulas (B-1) to (B-10) (hereinafter, also referred to as “structural unit (B-1) to structural units (B-10)”).

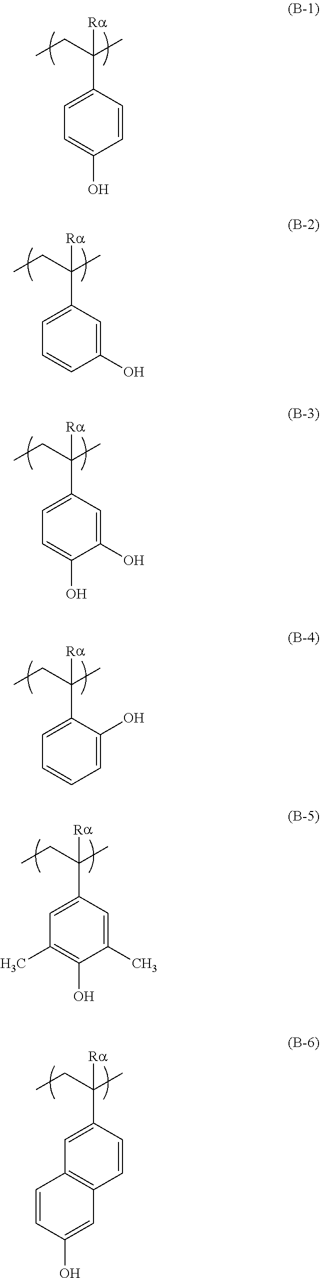

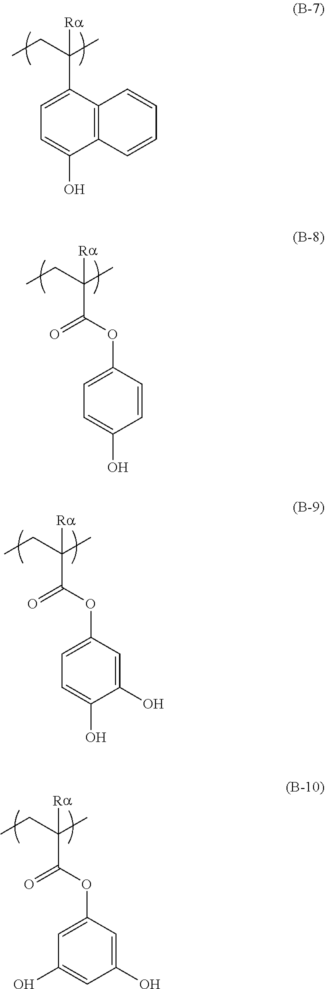

In the above formulas (B-1) to (B-10), R^{α} has the same meaning as in the above formula (B).

Among them, the structural units (B-1) to (B-4), (B-6), and (B-8) are preferred.

When the base resin contains the structural unit B, the lower limit of the content of the structural unit B (when two or more kinds of structural units B are present, the content of the structural unit B is the total content of the structural units B) is preferably 10 mol %, more preferably 15 mol %, even more preferably 20 mol %, particularly preferably 25 mol % with respect to the total amount of all the structural units constituting the resin. The upper limit of the content is preferably 80 mol %, more preferably 70 mol %, even more preferably 60 mol %, particularly preferably 55 mol %. When the content of the structural unit B is set to fall within the above range, the sensitivity, CDU performance, and resolution of the radiation-sensitive resin composition can further be improved.

When the structural unit B is obtained by polymerizing a monomer having a phenolic hydroxyl group such as a hydroxystyrene, it is preferred that the monomer is polymerized in a state where its phenolic hydroxyl group is protected by a protective group such as an alkali-dissociable group, and then hydrolysis is performed for deprotection to obtain the structural unit B.

(Structural Unit C)

The structural unit C is a structural unit including at least one selected from the group consisting of a lactone structure, a cyclic carbonate structure and a sultone structure. The solubility of the base resin into a developer can be adjusted by further introducing the structural unit C. As a result, the radiation-sensitive resin composition can provide improved lithography properties such as the resolution. The adhesion between a resist pattern formed from the base resin and a substrate can also be improved.

Among them, the structural unit C is preferably a group having a lactone structure, more preferably a group having a norbornane lactone structure, and further preferably a group derived from a norbornane lactone-yl (meth)acrylate.

When the base resin contains the structural unit C, the lower limit of the content by percent of the structural unit C is preferably 3 mol %, more preferably 8 mol %, and further preferably 20 mol % based on the total structural units as the component of the base resin. The upper limit of the content by percent is preferably 40 mol %, more preferably 30 mol %, and further preferably 20 mol %. By adjusting the content by percent of the structural unit (II) within the ranges, the radiation-sensitive resin composition can provide improved lithography properties such as the resolution. The adhesion between the formed resist pattern and the substrate can also be improved.

(Structural Unit D)

The base resin optionally contains another structural unit other than the above-described structural units A to C. Another structural unit includes a structural unit D having a polar group (excluding those corresponding to the structural units B and C). By further having the structural unit D, the base resin can adjust the solubility to the developing solution, and as a result, the lithography performance such as the resolution of the radiation-sensitive resin composition can be improved. Examples of the polar group include a hydroxyl group, a carboxyl group, a cyano group, a nitro group, and a sulfonamide group. Among these, a hydroxyl group or a carboxyl group is preferable, and a hydroxyl group is more preferable.

Examples of the structural unit D include structural units represented by the following formulas.

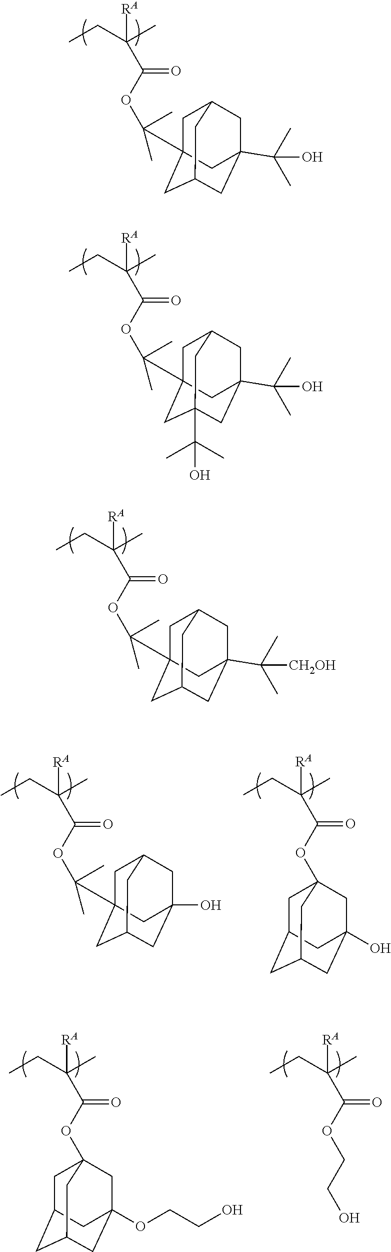

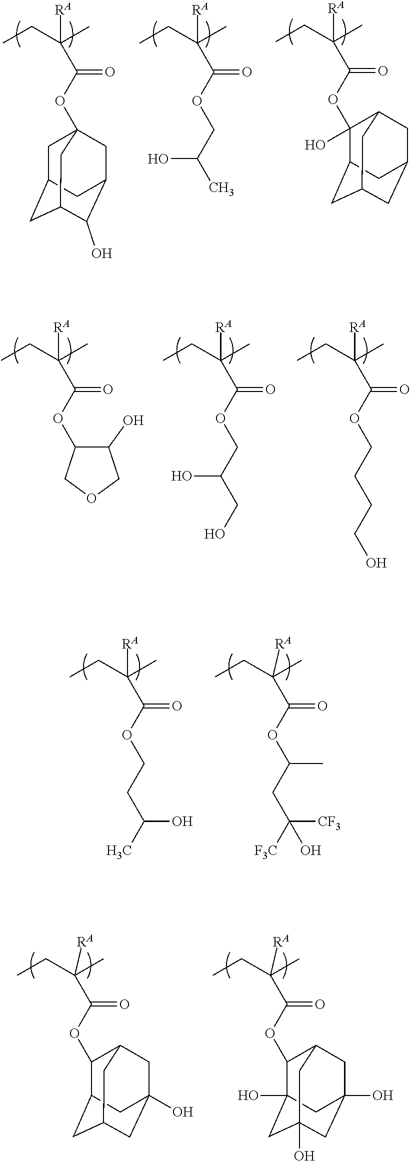

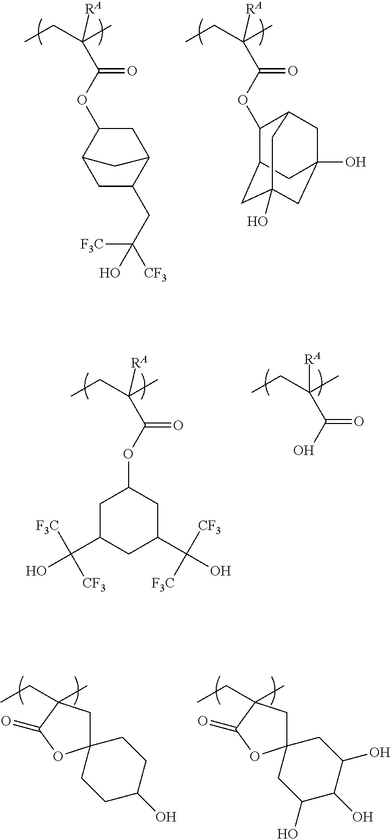

In the above formulas, R^{A} is a hydrogen atom, a fluorine atom, a methyl group, or a trifluoromethyl group.

When the resin has the structural unit D, the lower limit of the content of the structural unit D is preferably 1 mol %, more preferably 2 mol %, even more preferably 3 mol % with respect to the total amount of all the structural units constituting the resin. On the other hand, the upper limit of the content is preferably 30 mol %, more preferably 20 mol %, even more preferably 15 mol %. When the content of the structural unit D is set to fall within the above range, it is possible to further improve the lithography performance such as the resolution of the radiation-sensitive resin composition.

(Method for Synthesizing Resin)

The base resin can be synthesized, for example, by subjecting a monomer giving each structural unit to a polymerization reaction in an appropriate solvent using a known radical polymerization initiator or the like.

The molecular weight of the resin as the base resin is not particularly limited, but the weight average molecular weight (Mw) in terms of polystyrene by gel permeation chromatography (GPC) is preferably 1,000 or more, more preferably 2,000 or more, still more preferably 3,000 or more, and particularly preferably 4,000 or more. The weight average molecular weight is preferably 50,000 or less, more preferably 30,000 or less, still more preferably 15,000 or less, and particularly preferably 12,000 or less. When the Mw of the resin is within the above range, the heat resistance and developability of the resist film are further improved.

For the base resin as a base resin, the ratio of Mw to the number average molecular weight (Mn) as determined by GPC relative to standard polystyrene (Mw/Mn) is typically not less than 1 and not more than 5, preferably not less than 1 and not more than 3, and more preferably not less than 1 and not more than 2.

The Mw and Mn of the resin in the specification are amounts measured by using Gel Permeation Chromatography (GPC) with the condition as described below.

GPC column: two G2000HXL, one G3000HXL, and one G4000HXL (all manufactured from Tosoh Corporation)

Column temperature: 40° C.

Eluting solvent: tetrahydrofuran

Flow rate: 1.0 mL/min

Sample concentration: 1.0% by mass

Sample injection amount: 100 μL

Detector: Differential Refractometer

Reference material: monodisperse polystyrene

The content of the resin is preferably not less than 70% by mass, more preferably not less than 80% by mass, and further preferably not less than 85% by mass based on the total solid content of the radiation-sensitive resin composition.

<Another Resin>

The radiation-sensitive resin composition according to the present embodiment may contain, as another resin, a resin having higher content by mass of fluorine atoms than the above-described base resin (hereinafter, also referred to as a “high fluorine-containing resin). When the radiation-sensitive resin composition contains the high fluorine-containing resin, the high fluorine-containing resin can be localized in the surface layer of a resist film compared to the base resin, which as a result makes it possible to control the resist film so that the resist film can have a desired surface condition or a desired component distribution.

The high fluorine-containing resin preferably has, for example, any one of the structural units A to D contained in the base resin and a structural unit represented by the following formula (E) (hereinafter, also referred to as a “structural unit E”), if necessary.

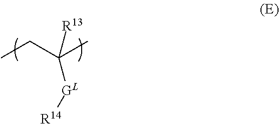

In the above formula (E), R¹³ is a hydrogen atom, a methyl group, or a trifluoromethyl group; G is a single bond, an oxygen atom, a sulfur atom, —COO—, —SO₂ONH—, —CONH—, or —OCONH—; R¹⁴ is a monovalent fluorinated chain hydrocarbon group having a carbon number of 1 to 20, or a monovalent fluorinated alicyclic hydrocarbon group having a carbon number of 3 to 20.

As R¹³ as described above, in terms of the copolymerizability of monomers resulting in the structural unit E, a hydrogen atom or a methyl group is preferred, and a methyl group is more preferred.

As G^{L} as described above, in terms of the copolymerizability of monomers resulting in the structural unit E, a single bond or —COO— is preferred, and —COO— is more preferred.

Example of the monovalent fluorinated chain hydrocarbon group having a carbon number of 1 to 20 represented by R¹⁴ as described above includes a group in which a part of or all of hydrogen atoms in the straight or branched chain alkyl group having a carbon number of 1 to 20 is/are substituted with a fluorine atom.

Example of the monovalent fluorinated alicyclic hydrocarbon group having a carbon number of 3 to 20 represented by R¹⁴ as described above includes a group in which apart of or all of hydrogen atoms in the monocyclic or polycyclic hydrocarbon group having a carbon number of 3 to 20 is/are substituted with a fluorine atom.

The R¹⁴ as described above is preferably a fluorinated chain hydrocarbon group, more preferably a fluorinated alkyl group, and further preferably 2,2,2-trifluoroethyl group, 1,1,1,3,3,3-hexafluoropropyl group, 5,5,5-trifluoro-1,1-diethylpentyl group, and 1,1,1,2,2,3,3-heptafluoro-6-methylheptane-4-yl group.

When the high fluorine-containing resin has the structural unit E, the lower limit of the content of the structural unit E is preferably 5 mol %, more preferably 10 mol %, even more preferably 15 mol % with respect to the total amount of all the structural units constituting the high fluorine-containing resin. The upper limit of the content is preferably 100 mol %, more preferably 95 mol %, even more preferably 90 mol %. When the content of the structural unit E is set to fall within the above range, the content by mass of fluorine atoms of the high fluorine-containing resin can more appropriately be adjusted to further promote the localization of the high fluorine-containing resin in the surface layer of a resist film.

The high fluorine-containing resin may have a fluorine atom-containing structural unit represented by the following formula (f-1) (hereinafter, also referred to as a “structural unit F”) other than the structural unit E. When the high fluorine-containing resin has the structural unit F, solubility in an alkaline developing solution is improved, and therefore generation of development defects can be prevented.

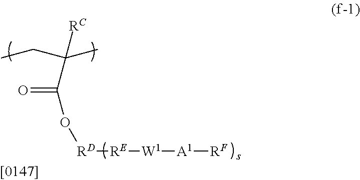

The structural unit F is classified into two groups: a unit having an alkali soluble group (x); and a unit having a group (y) in which the solubility into the alkaline developing solution is increased by the dissociation by alkali (hereinafter, simply referred as an “alkali-dissociable group”). In both cases of (x) and (y), R^{C} in the above formula (f-1) is a hydrogen atom, a fluorine atom, a methyl group, or a trifluoromethyl group; R^{D} is a single bond, a hydrocarbon group having a carbon number of 1 to 20 with the valency of (s+1), a structure in which an oxygen atom, a sulfur atom, —NR^{dd}—, a carbonyl group, —COO— or —CONH— is connected to the terminal on R^{E} side of the hydrocarbon group, or a structure in which a part of hydrogen atoms in the hydrocarbon group is substituted with an organic group having a hetero atom; R^{dd} is a hydrogen atom, or a monovalent hydrocarbon group having a carbon number of 1 to 10; and s is an integer of 1 to 3.

When the structural unit F has the alkali soluble group (x), R^{F} is a hydrogen atom; A¹ is an oxygen atom, —COO—* or —SO₂O—*; * refers to a bond to R^{F}; W¹ is a single bond, a hydrocarbon group having a carbon number of 1 to 20, or a divalent fluorinated hydrocarbon group. When A¹ is an oxygen atom, W¹ is a fluorinated hydrocarbon group having a fluorine atom or a fluoroalkyl group on the carbon atom connecting to A¹. R^{E} is a single bond, or a divalent organic group having a carbon number of 1 to 20. When s is 2 or 3, a plurality of R^{E}, W¹, A¹ and R^{F} may be each identical or different. The affinity of the high fluorine-containing resin into the alkaline developing solution can be improved by including the structural unit F having the alkali soluble group (x), and thereby prevent from generating the development defect. As the structural unit F having the alkali soluble group (x), particularly preferred is a structural unit in which A¹ is an oxygen atom and W¹ is a 1,1,1,3,3,3-hexafluoro-2,2-methanediyl group.

When the structural unit F has the alkali-dissociable group (y), R^{F} is a monovalent organic group having carbon number of 1 to 30; A¹ is an oxygen atom, —NR^{aa}—, —COO—*, or —SO₂O—*; R^{aa} is a hydrogen atom, or a monovalent hydrocarbon group having a carbon number of 1 to 10; * refers to a bond to R^{F}; W¹ is a single bond, or a divalent fluorinated hydrocarbon group having a carbon number of 1 to 20; R^{E} is a single bond, or a divalent organic group having a carbon number of 1 to 20. When A¹ is —COO—* or —SO₂O—*, W¹ or R^{F} has a fluorine atom on the carbon atom connecting to A¹ or on the carbon atom adjacent to the carbon atom. When A¹ is an oxygen atom, W¹ and R^{E} are a single bond; R^{D} is a structure in which a carbonyl group is connected at the terminal on R^{E} side of the hydrocarbon group having a carbon number of 1 to 20; and R^{F} is an organic group having a fluorine atom. When s is 2 or 3, a plurality of R^{E}, W¹, A¹ and R^{F} may be each identical or different. The surface of the resist film is changed from hydrophobic to hydrophilic in the alkaline developing step by including the structural unit F having the alkali-dissociable group (y). As a result, the affinity of the high fluorine-containing resin into the alkaline developing solution can be significantly improved, and thereby prevent from generating the development defect more efficiently. As the structural unit F having the alkali-dissociable group (y), particularly preferred is a structural unit in which A¹ is —COO—*, and R^{F} or W¹, or both is/are a fluorine atom.

In terms of the copolymerizability of monomers resulting in the structural unit F, R^{C} is preferably a hydrogen atom or a methyl group, and more preferably a methyl group.

When R^{E} is a divalent organic group, R^{E} is preferably a group having a lactone structure, more preferably a group having a polycycliclactone structure, and further preferably a group having a norbornane lactone structure.

When the high fluorine-containing resin has the structural unit F, the lower limit of the content of the structural unit F is preferably 5 mol %, more preferably 10 mol %, even more preferably 15 mol % with respect to the total amount of all the structural units constituting the high fluorine-containing resin. The upper limit of the content is preferably 90 mol %, more preferably 80 mol %, even more preferably 70 mol %. When the content of the structural unit F is set to fall within the above range, water repellency of a resist film during immersion exposure can further be improved.

The lower limit of Mw of the high fluorine-containing resin is preferably 1,000, more preferably 2,000, further preferably 3,000, and particularly preferably 5,000. The upper limit of Mw is preferably 50,000, more preferably 30,000, further preferably 20,000, and particularly preferably 15,000.

The lower limit of the Mw/Mn of the high fluorine-containing resin is typically 1, and more preferably 1.1. The upper limit of the Mw/Mn is typically 5, preferably 3, more preferably 2.5, and further preferably 2.2.

The lower limit of the content of the high fluorine-containing resin is preferably 1 part by mass, more preferably 2 parts by mass, further preferably 3 parts by mass based on 100 parts by mass of total base resins. The upper limit of the content is preferably 20 parts by mass, more preferably 15 parts by mass, further preferably 8 parts by mass, and particularly preferably 10 parts by mass. When the content of the high fluorine-containing resin is set to fall within the above range, the high fluorine-containing resin can more effectively be localized in the surface layer of a resist film, which as a result makes it possible to prevent elution of the upper portion of a pattern during development to enhance the rectangularity of the pattern. The radiation-sensitive resin composition may contain one kind of high fluorine-containing resin or two or more kinds of high fluorine-containing resin.

(Method for Synthesizing High Fluorine-Containing Resin)

The high fluorine-containing resin can be synthesized by a method similar to the above-described method for synthesizing a base resin.

### <Solvent>

The radiation-sensitive resin composition according to the present embodiment contains a solvent. The solvent contains at least propylene glycol monomethyl ether and alkyl lactate, and the content of propylene glycol monomethyl ether acetate in the solvent is 5% by mass or less. The content of the propylene glycol monomethyl ether acetate in the solvent is preferably 3% by mass or less, and more preferably 1% by mass or less. The solvent more preferably contains no propylene glycol monomethyl ether acetate. The solvent in the radiation-sensitive resin composition has a predetermined composition, whereby the pattern defect-suppression performance can be improved.

Examples of the alkyl lactate include an ester compound of lactic acid and a linear or branched aliphatic alcohol having 1 to 10 carbon atoms such as methyl lactate, ethyl lactate, n-propyl lactate, i-propyl lactate, n-butyl lactate, i-butyl lactate, or t-butyl lactate. Among them, an ester compound of lactic acid and a linear or branched aliphatic alcohol having 1 to 4 carbon atoms is preferable, and ethyl lactate is more preferable.

The lower limit of the total content of the propylene glycol monomethyl ether and alkyl lactate is preferably 50% by mass, more preferably 70% by mass, and still more preferably 90% by mass in the entire solvent. The upper limit of the total content may be 100% by mass. The total content of the propylene glycol monomethyl ether and alkyl lactate is set within the above range, whereby the pattern defect-suppression performance can be further enhanced.

The lower limit of the content of the propylene glycol monomethyl ether in the total mass of the propylene glycol monomethyl ether and alkyl lactate is preferably 5% by mass, more preferably 10% by mass, and still more preferably 15% by mass. The upper limit of the content is preferably 99% by mass, more preferably 95% by mass, and still more preferably 90% by mass. The content of the propylene glycol monomethyl ether is set within the above range, whereby the pattern defect-suppression performance can be further enhanced.

Examples of the solvent other than the propylene glycol monomethyl ether and the alkyl lactate include an alcohol-based solvent, an ether-based solvent (excluding propylene glycol monomethylether), a ketone-based solvent, an amide-based solvent, an ester-based solvent (excluding alkyl lactate), and a hydrocarbon-based solvent. The radiation-sensitive resin composition may contain two or more solvents.

Examples of the alcohol-based solvent include:
a monoalcohol-based solvent having a carbon number of 1 to 18, includingiso-propanol, 4-methyl-2-pentanol, 3-methoxybutanol, n-hexanol, 2-ethylhexanol, furfuryl alcohol, cyclohexanol, 3,3,5-trimethylcyclohexanol, and diacetone alcohol;
a polyhydric alcohol having a carbon number of 2 to 18, including ethylene glycol, 1,2-propylene glycol, 2-methyl-2,4-pentanediol, 2,5-hexanediol, diethylene glycol, dipropylene glycol, triethylene glycol, and tripropylene glycol; and
a partially etherized polyhydric alcohol-based solvent in which a part of hydroxy groups in the polyhydric alcohol-based solvent is etherized (excluding propylene glycol monomethyl ether).

Examples of the ether-based solvent include:
a dialkyl ether-based solvent, including diethyl ether, dipropyl ether, and dibutyl ether;
a cyclic ether-based solvent, including tetrahydrofuran and tetrahydropyran;
an ether-based solvent having an aromatic ring, including diphenylether and anisole (methyl phenyl ether); and
an etherized polyhydric alcohol-based solvent in which a hydroxy group in the polyhydric alcohol-based solvent is etherized.

Examples of the ketone-based solvent include:
a chain ketone-based solvent, including acetone, butanone, and methyl-iso-butyl ketone;
a cyclic ketone-based solvent, including cyclopentanone, cyclohexanone, and methylcyclohexanone; and
2,4-pentanedione, acetonylacetone, and acetophenone.

Examples of the amide-based solvent include:
a cyclic amide-based solvent, including N,N′-dimethyl imidazolidinone and N-methylpyrrolidone; and
a chain amide-based solvent, including N-methylformamide, N,N-dimethylformamide, N,N-diethylformamide, acetamide, N-methylacetamide, N,N-dimethylacetamide, and N-methylpropionamide.

Examples of the ester-based solvent include:
a monocarboxylate ester-based solvent, including n-butyl acetate (excluding alkyl lactate);
a partially etherized polyhydric alcohol acetate-based solvent, including diethylene glycol mono-n-butyl ether acetate, propylene glycol monomethyl ether acetate, and dipropylene glycol monomethyl ether acetate (provided that the content of propylene glycol monomethyl ether acetate is 5% by mass or less);
a lactone-based solvent, including γ-butyrolactone and valerolactone;
a carbonate-based solvent, including diethyl carbonate, ethylene carbonate, and propylene carbonate; and
a polyhydric carboxylic acid diester-based solvent, including propylene glycol diacetate, methoxy triglycol acetate, diethyl oxalate, ethyl acetoacetate, ethyl lactate, and diethyl phthalate.

Examples of the hydrocarbon-based solvent include:
an aliphatic hydrocarbon-based solvent, including n-hexane, cyclohexane, and methylcyclohexane;
an aromatic hydrocarbon-based solvent, including benzene, toluene, di-iso-propylbenzene, and n-amylnaphthalene.

<Another Optional Component>

The radiation-sensitive resin composition may contain another optional component other than the above-descried components. Examples of another optional component include a cross-linking agent, a localization enhancing agent, a surfactant, an alicyclic backbone-containing compound, and a sensitizer. These other optional components may be used singly or in combination of two or more of them.

<Method for Preparing Radiation-Sensitive Resin Composition>

The radiation-sensitive resin composition can be prepared by, for example, mixing the base resin, the solvent, and another optional component added if necessary in a predetermined ratio. The radiation-sensitive resin composition is preferably filtered through, for example, a filter having a pore diameter of about 0.05 μm to about 0.2 μm after mixing. The solid matter concentration of the radiation-sensitive resin composition is usually 0.1 mass % to 50 mass %, preferably 0.5 mass % to 30 mass %, more preferably 1 mass % to 20 mass %.

### Second Embodiment

### <<Radiation-Sensitive Resin Composition>>

A radiation-sensitive resin composition according to a second embodiment contains a radiation-sensitive acid generating resin and a solvent. The radiation-sensitive acid generating resin corresponds to a form in which a radiation-sensitive acid generator is incorporated as a part of a polymer. Therefore, the radiation-sensitive resin composition according to the present embodiment may or may not contain a radiation-sensitive strong acid generator as a radiation-sensitive acid generator, but preferably contains an acid diffusion controlling agent. The radiation-sensitive resin composition according to the second embodiment is the same as the radiation-sensitive resin composition according to the first embodiment except that the radiation-sensitive resin composition contains a radiation-sensitive acid generating resin in place of the resin of the radiation-sensitive resin composition according to the first embodiment and optionally contains a radiation-sensitive acid generator. Hereinafter, the radiation-sensitive acid generating resin different from that of the first embodiment will be described.

### <Radiation-Sensitive Acid Generating Resin>

The radiation-sensitive acid generating resin contains a structural unit having a radiation-sensitive acid generating structure (hereinafter, also referred to as “structural unit G”) and a structural unit represented by the following formula (1). As the structural unit represented by the following formula (1), the structural unit A contained in the resin in the first embodiment can be suitably employed. The radiation-sensitive acid generating resin as the base resin may contain structural units B, C, and D and the like contained in the resin in the first embodiment in addition to the structural units A and G.

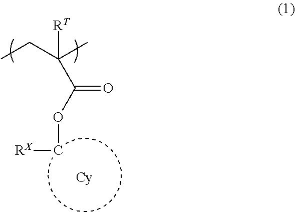

In the formula (1), R^{T} is a hydrogen atom, a fluorine atom, a methyl group, or a trifluoromethyl group.

R^{X} is a monovalent hydrocarbon group having 1 to 20 carbon atoms.

Cy represents an alicyclic structure having 3 to 20 ring members formed together with a carbon atom to which Cy is bonded.

### (Structural Unit G)

The structural unit G has a radiation-sensitive acid generating structure. As the radiation-sensitive acid generating structure, the structure of the radiation-sensitive acid generator according to the first embodiment can be suitably employed, and it is particularly preferable to have the structure of the radiation-sensitive strong acid generator.

The radiation-sensitive acid generating structure preferably contains one or two or more onium salts containing an organic acid anion moiety and an onium cation moiety. The organic acid anion moiety preferably has at least one selected from the group consisting of a sulfonate anion, a carboxylate anion and a sulfonimide anion. The onium cation moiety is preferably at least one selected from the group consisting of a sulfonium cation and an iodonium cation.

The radiation-sensitive acid generating resin preferably contains a structural unit represented by the following formula (g1) (hereinafter, also referred to as “structural unit G1”) or a structural unit represented by the following formula (g2) (hereinafter, also referred to as “structural unit G2”).

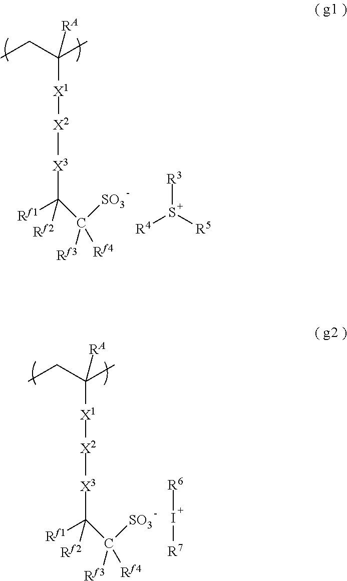

In the formula, R^{A} is a hydrogen atom or a methyl group. X¹ is a single bond or an ester group. X² is a linear, branched or cyclic alkylene group having 1 to 12 carbon atoms or an arylene group having 6 to 10 carbon atoms. Some of methylene groups constituting the alkylene group may be substituted with an ether group, an ester group or a lactone ring-containing group. At least one hydrogen atom contained in X² may be substituted with an iodine atom. X³ is a single bond, an ether group, an ester group, or a linear, branched or cyclic alkylene group having 1 to 12 carbon atoms. Some of methylene groups constituting the alkylene group may be substituted with an ether group or an ester group. Rf¹ to Rf⁴ are each independently a hydrogen atom, a fluorine atom, or a trifluoromethyl group, and at least one of Rf¹ to Rf⁴ is a fluorine atom or a fluorinated hydrocarbon group. R³ to R⁷ are each independently a monovalent hydrocarbon group having 1 to 20 carbon atoms which may contain a hetero atom, and R³ and R⁴ may be bonded to each other to form a ring together with a sulfur atom to which R³ and R⁴ are bonded.

As the monovalent hydrocarbon group having 1 to 20 carbon atoms which may contain a hetero atom in R³ to R⁷, an alkyl group having 1 to 12 carbon atoms, a cycloalkyl group having 3 to 12 carbon atoms, or an aryl group having 6 to 20 carbon atoms is preferable. Some or all of hydrogen atoms of these groups may be substituted with a hydroxy group, a carboxy group, a halogen atom, an oxo group, a cyano group, an amide group, a nitro group, a sultone group, a sulfone group, or a sulfonium salt-containing group. Some of methylene groups constituting these groups may be substituted with an ether group, an ester group, a carbonyl group, a carbonate group, or a sulfonic acid ester group.

The structural unit G1 and the structural unit G2 are preferably represented by the following formulae (g1-1) and (g2-1), respectively.

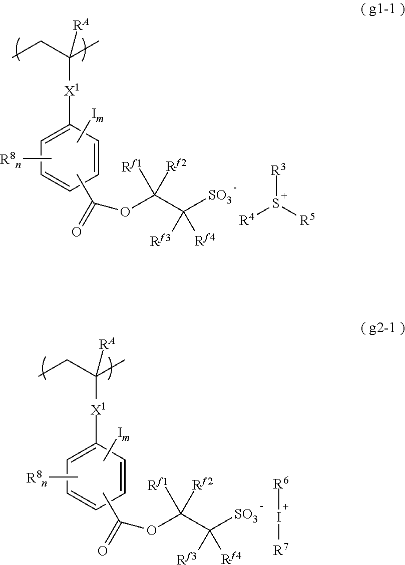

In the formula, R^{A}, R³ to R⁷, Rf¹ to Rf⁴, and X¹ have the same meanings as those in the formula (g1) or (g2). R⁸ is a linear, branched or cyclic alkyl group having 1 to 4 carbon atoms, a halogen atom other than iodine, a hydroxy group, a linear, branched or cyclic alkoxy group having 1 to 4 carbon atoms, or a linear, branched or cyclic alkoxycarbonyl group having 2 to 5 carbon atoms. m is an integer of 0 to 4. n is an integer of 0 to 3.

Examples of the organic acid anion moiety of the monomer that gives the structural unit G1 or the structural unit G2 include, but are not limited to, those shown below. All of those shown below are organic acid anion moieties having an iodine-substituted aromatic ring structure, but as the organic acid anion moieties having no iodine-substituted aromatic ring structure, a structure in which an iodine atom in the following formula is substituted with an atom or group other than an iodine atom such as a hydrogen atom or another substituent can be suitably employed.

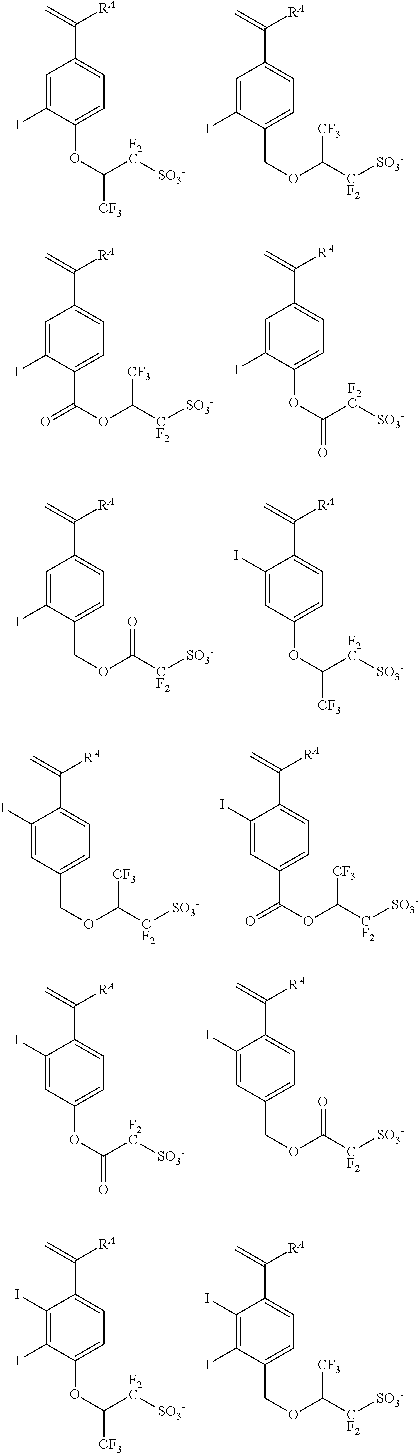

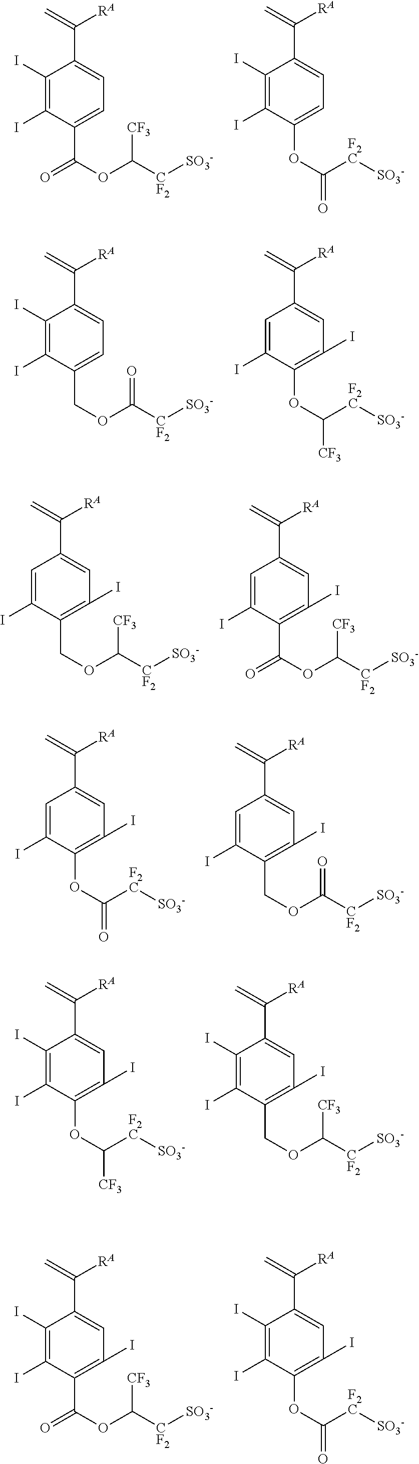

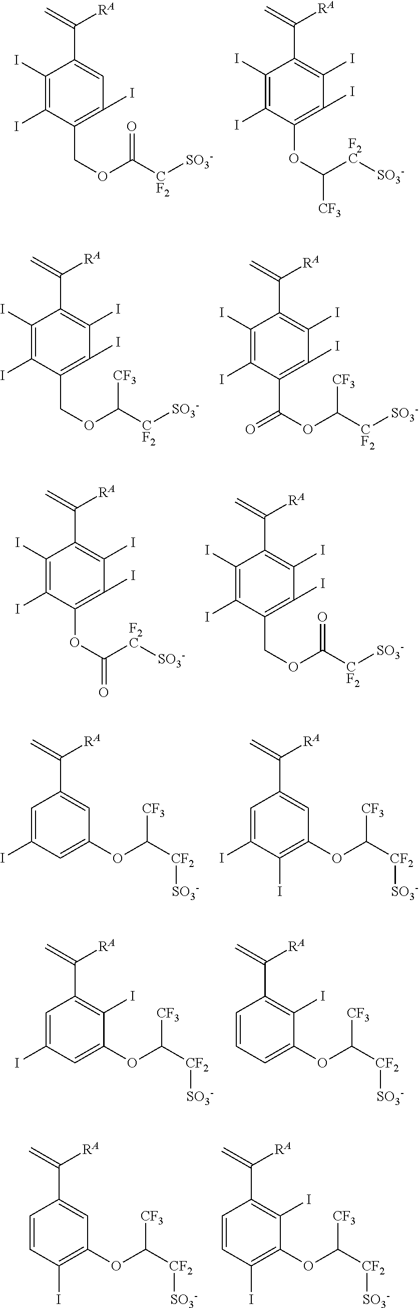

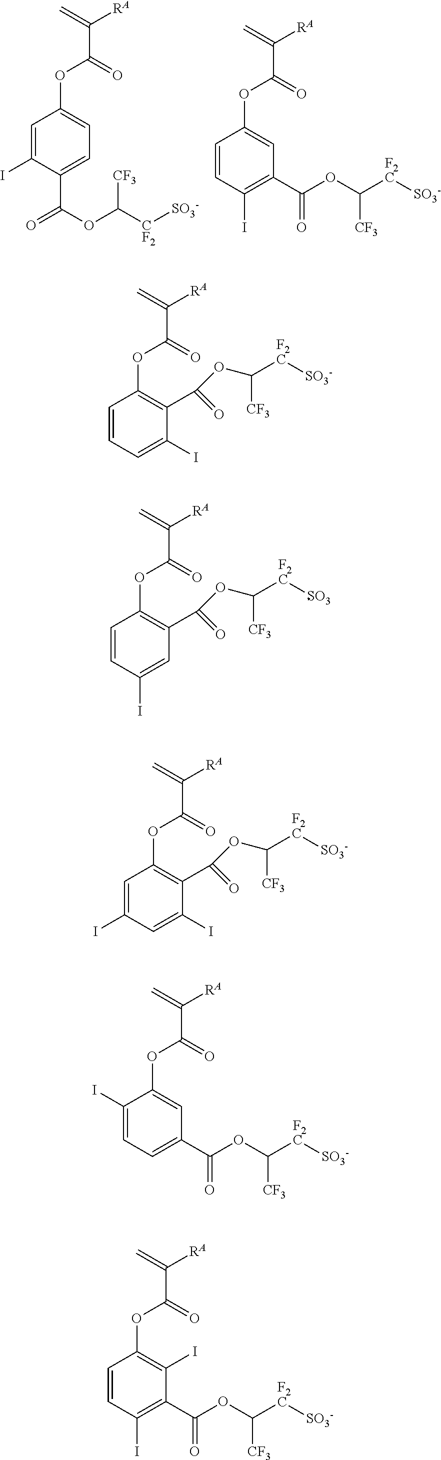

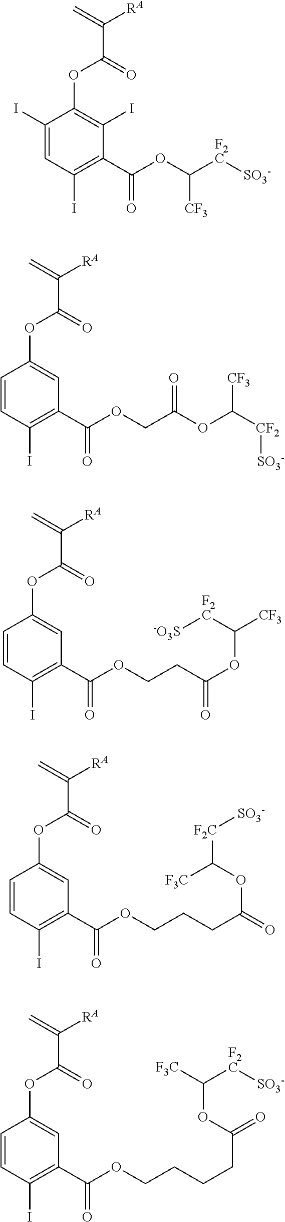

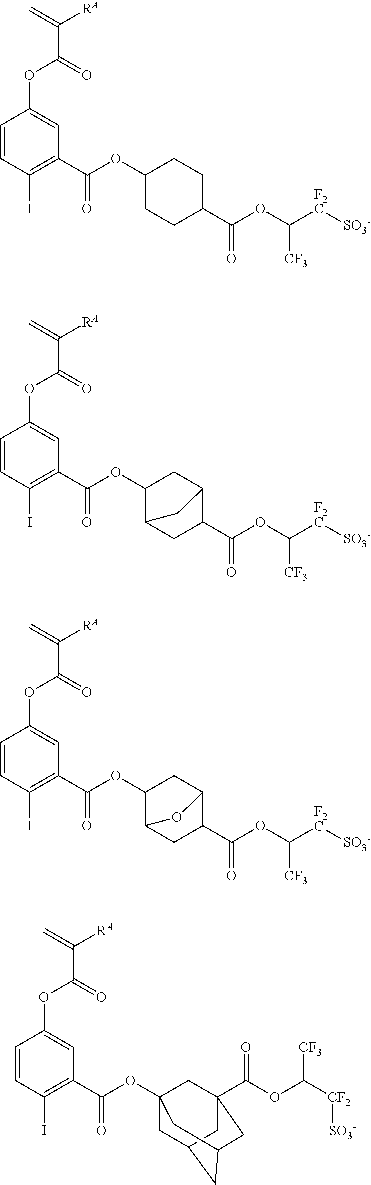

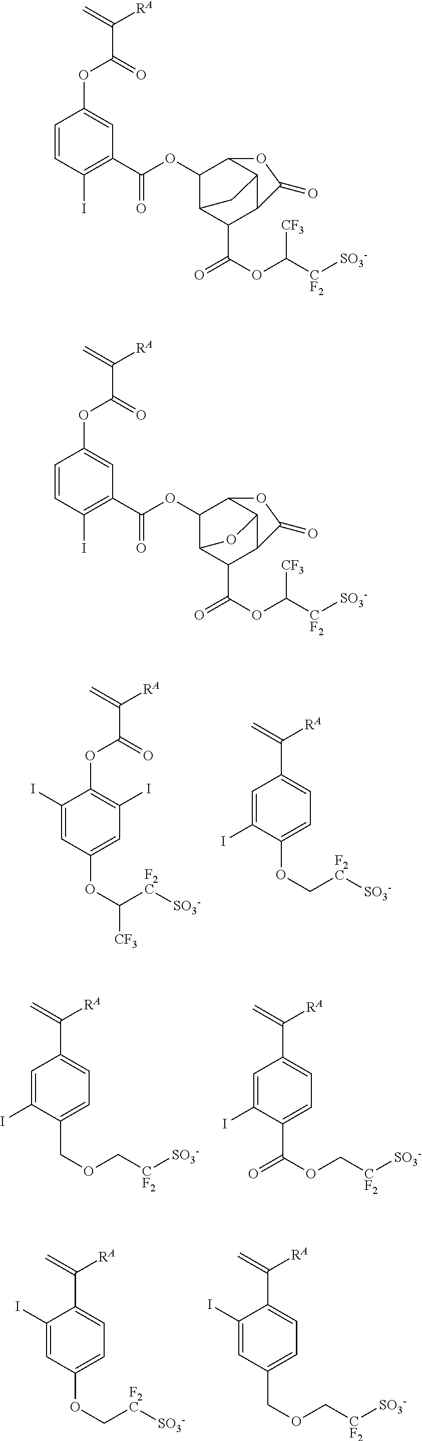

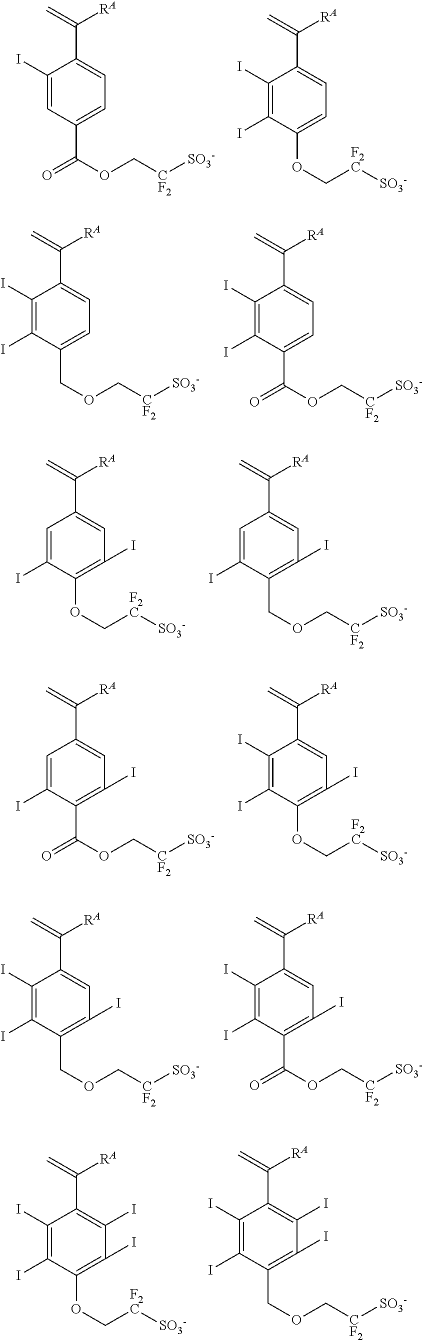

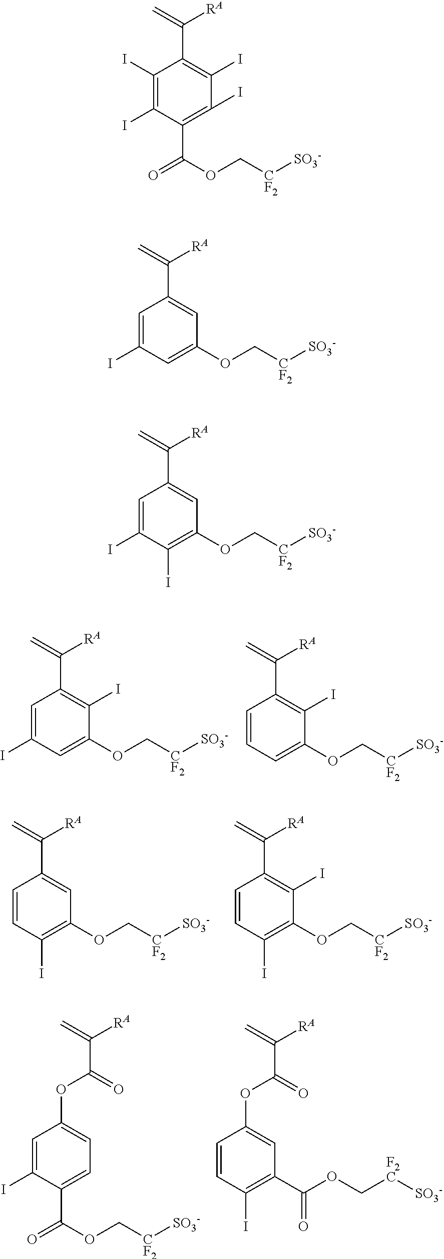

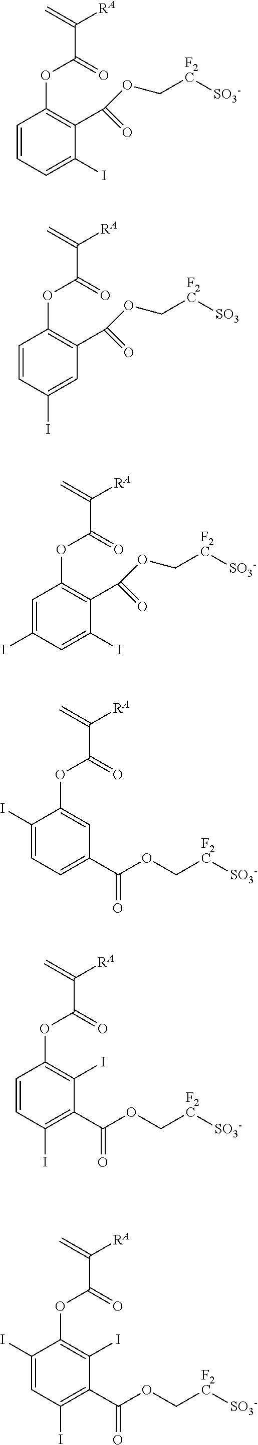

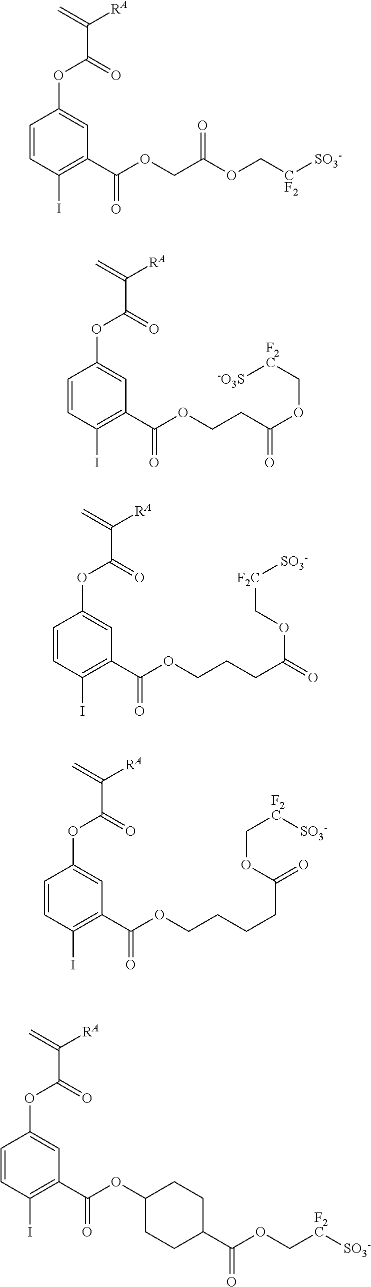

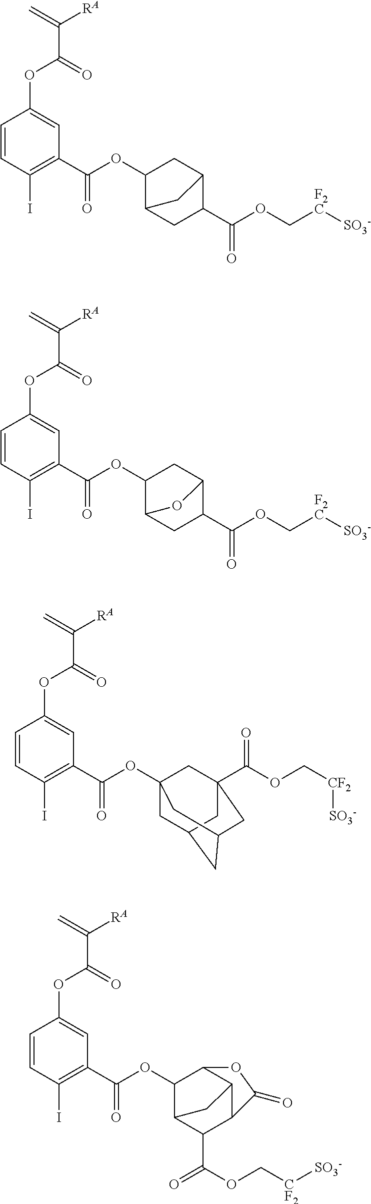

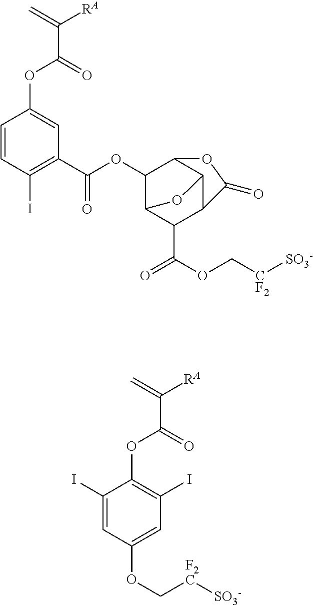

The onium cation moiety of the structural unit G1 is preferably represented by the following formula (Q-1).

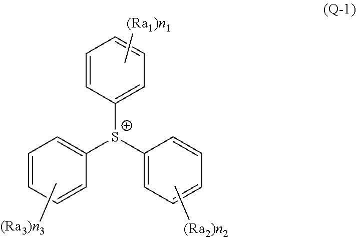

In the formula (Q-1), Ra1 and Ra2 each independently represent a substituent. n1 represents an integer of 0 to 5, and when n1 is 2 or more, a plurality of Ra1 may be the same or different. n2 represents an integer of 0 to 5, and when n2 is 2 or more, a plurality of Ra2 may be the same or different. n3 represents an integer of 0 to 5, and when n3 is 2 or more, a plurality of Ra3 may be the same or different. Ra3 represents a fluorine atom or a group having one or more fluorine atoms. Ra1 and Ra2 may be linked to each other to form a ring. When n1 is 2 or more, a plurality of Ra1 may be linkedto each other to forma ring. When n2 is 2 ormore, aplurality of Ra2 may be linked to each other to form a ring.

The substituent represented by Ra1 and Ra2 is preferably an alkyl group, a cycloalkyl group, an alkoxy group, a cycloalkyloxy group, an alkoxycarbonyl group, an alkylsulfonyl group, a hydroxyl group, a halogen atom, or a halogenated hydrocarbon group.

The alkyl group of Ra1 and Ra2 may be a linear alkyl group or a branched alkyl group. The alkyl group preferably has 1 to 10 carbon atoms, and examples thereof include a methyl group, an ethyl group, an n-propyl group, an i-propyl group, an n-butyl group, a 2-methylpropyl group, a 1-methylpropyl group, a t-butyl group, an n-pentyl group, a neopentyl group, an n-hexyl group, an n-heptyl group, an n-octyl group, a 2-ethylhexyl group, an n-nonyl group, and an n-decyl group. Among them, a methyl group, an ethyl group, an n-butyl group, and a t-butyl group are particularly preferable.

Examples of the cycloalkyl group of Ra1 and Ra2 include a monocyclic or polycyclic cycloalkyl group (preferably a cycloalkyl group having 3 to 20 carbon atoms), and examples thereof include cyclopropyl, cyclobutyl, cyclopentyl, cyclohexyl, cycloheptyl, cyclooctyl, cyclododecanyl, cyclopentenyl, cyclohexenyl, and cyclooctadienyl groups. Among these, cyclopropyl, cyclopentyl, cyclohexyl, cyclohexyl, cycloheptyl, and cyclooctyl groups are particularly preferable.

Examples of the alkyl group moiety of the alkoxy group of Ra1 and Ra2 include those listed above as the alkyl group of Ra1 and Ra2. As the alkoxy group, a methoxy group, an ethoxy group, an n-propoxy group, and an n-butoxy group are particularly preferable.

Examples of the cycloalkyl group moiety of the cycloalkyloxy group of Ra1 and Ra2 include those listed above as the cycloalkyl group of Ra1 and Ra2. As the cycloalkyloxy group, a cyclopentyloxy group and a cyclohexyloxy group are particularly preferable.

Examples of the alkoxy group moiety of the alkoxycarbonyl group of Ra1 and Ra2 include those listed above as the alkoxy group of Ra1 and Ra2. As the alkoxycarbonyl group, a methoxycarbonyl group, an ethoxycarbonyl group, and an n-butoxycarbonyl group are particularly preferable.

Examples of the alkyl group moiety of the alkylsulfonyl group of Ra1 and Ra2 include those listed above as the alkyl group of Ra1 and Ra2. Examples of the cycloalkyl group moiety of the cycloalkylsulfonyl group of Ra1 and Ra2 include those listed above as the cycloalkyl group of Ra1 and Ra2. As the alkylsulfonyl group or the cycloalkylsulfonyl group, a methanesulfonyl group, an ethanesulfonyl group, an n-propanesulfonyl group, an n-butanesulfonyl group, a cyclopentanesulfonyl group, and a cyclohexanesulfonyl group are particularly preferable.

Each of the groups Ra1 and Ra2 may further have a substituent.

Examples of the halogen atom of Ra1 and Ra2 include a fluorine atom, a chlorine atom, a bromine atom, and an iodine atom, and a fluorine atom is preferable.

The halogenated hydrocarbon group of Ra1 and Ra2 is preferably a halogenated alkyl group. Examples of the alkyl group and the halogen atom constituting the halogenated alkyl group include the same as the above. Among them, a fluorinated alkyl group is preferable, and CF₃ is more preferable.

As described above, Ra1 and Ra2 may be linked to each other to form a ring (that is, a heterocyclic ring containing a sulfur atom). In this case, Ra1 and Ra2 preferably form a single bond or a divalent linking group. Examples of the divalent linking group include —COO—, —OCO—, —CO—, —O—, —S—, —SO—, —SO₂—, an alkylene group, a cycloalkylene group, an alkenylene group, or a combination of two or more thereof, and those having total carbon atoms of 20 or less are preferable. When Ra1 and Ra2 are linked to each other to form a ring, Ra1 and Ra2 preferably form —COO—, —OCO—, —CO—, —O—, —S—, —SO—SO₂—, or a single bond, more preferably form —O—, —S—, or a single bond, and particularly preferably form a single bond. When n1 is 2 or more, a plurality of Ra1 may be linked to each other to form a ring, and when n2 is 2 or more, a plurality of Ra2 may be linked to each other to form a ring. Examples thereof include an aspect in which two Ra1 are linked to each other to form a naphthalene ring together with a benzene ring to which these are bonded.

Ra3 is a fluorine atom or a group having a fluorine atom. Examples of the group having a fluorine atom include groups in which an alkyl group, a cycloalkyl group, an alkoxy group, a cycloalkyloxy group, an alkoxycarbonyl group, and an alkylsulfonyl group as Ra1 and Ra2 are substituted with a fluorine atom. Among them, a fluorinated alkyl group can be suitably exemplified. CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉ can be more suitably exemplified. CF₃ can be particularly suitably exemplified.

Ra3 is preferably a fluorine atom or CF₃, and more preferably a fluorine atom.

n1 and n2 are each independently preferably an integer of 0 to 3, and preferably an integer of 0 to 2.

n3 is preferably an integer of 1 to 3, and more preferably 1 or 2.

(n1+n2+n3) is preferably an integer of 1 to 15, more preferably an integer of 1 to 9, still more preferably an integer of 2 to 6, and particularly preferably an integer of 3 to 6. When (n1+n2+n3) is 1, it is preferable that n3=1 is set and Ra3 is a fluorine atom or CF₃. When (n1+n2+n3) is 2, a combination in which n1=n3=1 is set and Ra1 and Ra3 are each independently a fluorine atom or CF₃ and a combination in which n3=2 is set and Ra3 is a fluorine atom or CF₃ are preferable. When (n1+n2+n3) is 3, a combination in which n1=n2=n3=1 is set and Ra1 to Ra3 are each independently a fluorine atom or CF₃ is preferable. When (n1+n2+n3) is 4, a combination in which n1=n3=2 is set and Ra1 to Ra3 are each independently a fluorine atom or CF₃ is preferable. When (n1+n2+n3) is 5, a combination in which n1=n2=1 and n3=3 are set and Ra1 to Ra3 are each independently a fluorine atom or CF₃, a combination in which n1=n2=2 and n3=1 are set and Ra1 to Ra3 are each independently a fluorine atom or CF₃, and a combination in which n3=5 is set and Ra3 are each independently a fluorine atom or CF₃ are preferable. When (n1+n2+n3) is 6, a combination in which n1=n2=n3=2 is set and Ra1 to Ra3 are each independently a fluorine atom or CF₃ is preferable.

As a specific example of such an onium cation moiety represented by the formula (Q-1), the structures exemplified as the sulfonium cation moiety in the radiation-sensitive strong acid generator according to the first embodiment can be suitably employed. All of the above are sulfonium cation moieties having a fluorine-substituted aromatic ring structure, but as an onium cation moiety having no fluorine-substituted aromatic ring structure, a structure in which a fluorine atom or CF₃ in the above formula is substituted with an atom or group other than a fluorine atom such as a hydrogen atom or another substituent can be suitably employed.

When the onium cation moiety of the structural unit G2 contains a fluorine-substituted aromatic ring structure, the onium cation moiety is preferably a diaryliodonium cation having one or more fluorine atoms. Among them, the onium cation moiety is preferably represented by the following formula (Q-2).

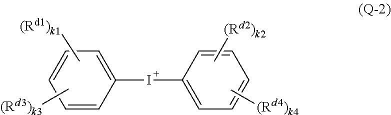

In the formula, R^{d1} and R^{d2} are each independently a substituted or unsubstituted linear or branched alkyl group having 1 to 12 carbon atoms, an alkoxy group or an alkoxycarbonyl group, a substituted or unsubstituted aromatic hydrocarbon group having 6 to 12 carbon atoms, or a nitro group. R^{d3} and R^{d4} are each independently a fluorine atom or a group having a fluorine atom. k1 and k2 are each independently an integer of 0 to 5. k3 and k4 are each independently an integer of 0 to 5. (k1+k3) and (k2+k4) are each 5 or less, and (k3+k4) is an integer of 1 to 10. When there are a plurality of R^{d1} to R^{d4}, the plurality of R^{d1} to R^{d4} may be the same or different.

Examples of the alkyl group, the alkoxy group, and the alkoxycarbonyl group represented by R^{d1} and R^{d2}, and the group having a fluorine atom represented by R^{d3} and R^{d4} include the same as those represented by the above formula (Q-1).

Examples of the monovalent aromatic hydrocarbon group having 6 to 12 carbon atoms include aryl groups such as a phenyl group, a tolyl group, a xylyl group, and a naphthyl group; and aralkyl groups such as a benzyl group and a phenethyl group.

Examples of the substituent of each group include halogen atoms such as a fluorine atom, a chlorine atom, a bromine atom, and an iodine atom; a hydroxy group; a carboxy group; a cyano group; a nitro group; an alkyl group, an alkoxy group, an alkoxycarbonyl group, an alkoxycarbonyloxy group, an acyl group, an acyloxy group, or a group in which a hydrogen atom of these groups is substituted with a halogen atom; and an oxo group (═O).

k1 and k2 are each preferably 0 to 2, and more preferably 0 or 1. k3 and k4 are each preferably 1 to 3, and more preferably 1 or 2. (k3+k4) is an integer of 1 to 10, preferably an integer of 1 to 6, more preferably an integer of 1 to 4, and still more preferably 1 or 2.

As a specific example of such an onium cation moiety represented by the formula (Q-2), the structures exemplified as the iodonium cation moiety in the radiation-sensitive strong acid generator according to the first embodiment can be suitably employed. All of the above are iodonium cation moieties having a fluorine-substituted aromatic ring structure, but as an onium cation moiety having no fluorine-substituted aromatic ring structure, a structure in which a fluorine atom or CF₃ in the above formula is substituted with an atom or group other than a fluorine atom such as a hydrogen atom or another substituent can be suitably employed.

The lower limit of the content ratio of the structural unit G1 or the structural unit G2 (the total content ratio in the case of containing two or more types) is preferably 5 mol %, more preferably 10 mol %, and still more preferably 15 mol %, with respect to the total structural units constituting the radiation-sensitive acid generating resin. The upper limit of the content ratio is preferably 50 mol %, more preferably 40 mol %, and still more preferably 30 mol %. The content ratio of the structural unit G1 or the structural unit G2 is within the above range, whereby the function as an acid generator can be sufficiently exhibited.

The monomer that gives the structural unit G1 or the structural unit G2 can be synthesized, for example, by the same method as that of a sulfonium salt having a polymerizable anion described in Japanese Patent No. 5201363.

### Third Embodiment

### <<Method for Forming Pattern>>

A method for forming a pattern according to the present embodiment includes:
applying the radiation-sensitive resin composition directly or indirectly onto a substrate to form a resist film (hereinafter, also referred to as a “resist film-forming step”);
exposing the resist film (hereinafter, also referred to as an “exposure step”); and
developing the exposed resist film (hereinafter, also referred to as a “development step”).

The method for forming a pattern may further include, before the resist film forming step, a step of forming a resist underlayer film by directly or indirectly applying a composition for forming a resist underlayer film onto the substrate (hereinafter, also referred to as “resist underlayer film forming step”).

According to the method for forming a pattern, the radiation-sensitive resin composition having excellent pattern defect-suppression performance, sensitivity, and CDU performance is used, whereby a high-quality resist pattern can be formed. Hereinafter, steps including the resist underlayer film forming step which is an optional step will be described.

### [Resist Underlayer Film Forming Step]

This step is performed before the resist film forming step. The resist underlayer film can be formed by directly or indirectly applying a composition for forming a resist underlayer film onto a substrate. The composition for forming a resist underlayer film typically contains a novolac-based polymer obtained by polycondensation of an aromatic ring and an aldehyde, and a solvent. The polymer may have an acidic group or a basic group.

In addition to or instead of the resist underlayer film, an organic or inorganic antireflection film disclosed in, for example, JP-A-59-93448 and the like may be formed on the substrate before the resist forming step.

[Resist Film Forming Step]

In this step, a resist film is formed with the radiation-sensitive resin composition. Examples of the substrate on which the resist film is formed include one traditionally known in the art, including a silicon wafer, silicon dioxide, and a wafer coated with aluminum. A film of a dielectric material such as SiO₂, SiC, SiN, SiOC, SiNO, SiCNO, and SiCN may be formed on the substrate. Examples of the applicating method of the radiation-sensitive resin composition include a rotary coating (spin coating), flow casting, and roll coating. After applicating, a prebake (PB) may be carried out in order to evaporate the solvent in the film, if needed. The temperature of PB is typically from 60° C. to 140° C., and preferably from 80° C. to 120° C. The duration of PB is typically from 5 seconds to 600 seconds, and preferably from 10 seconds to 300 seconds. The thickness of the resist film formed is preferably from 10 nm to 1,000 nm, and more preferably from 10 nm to 500 nm.

When the immersion exposure is carried out, irrespective of presence of a water repellent polymer additive such as the high fluorine-containing resin in the radiation-sensitive resin composition, the formed resist film may have a protective film for the immersion which is not soluble into the immersion liquid on the film in order to prevent a direct contact between the immersion liquid and the resist film. As the protective film for the immersion, a solvent-removable protective film that is removed with a solvent before the developing step (for example, see JP-A-2006-227632); or a developer-removable protective film that is removed during the development of the developing step (for example, see WO2005-069076 and WO02006-035790) may be used. In terms of the throughput, the developer-removable protective film is preferably used.

Further, when the next exposure step is performed using a radioactive ray having a wavelength of 50 nm or less, a resin having the structural units A and B, and if necessary, the structural unit C is preferably used as the base resin in the composition.

[Exposing Step]

In this step, the resist film formed in the resist film forming step as the step (1) is exposed by irradiating with a radioactive ray through a photomask (optionally through an immersion medium such as water). Examples of the radioactive ray used for the exposure include visible ray, ultraviolet ray, far ultraviolet ray, extreme ultraviolet ray (EUV); an electromagnetic wave including X ray and γ ray; an electron beam; and a charged particle radiation such as α ray. Among them, far ultraviolet ray, an electron beam, or EUV is preferred. ArF excimer laser light (wavelength is 193 nm), KrF excimer laser light (wavelength is 248 nm), an electron beam, or EUV is more preferred. An electron beam or EUV having a wavelength of 50 nm or less which is identified as the next generation exposing technology is further preferred.

When the exposure is carried out by immersion exposure, examples of the immersion liquid include water and fluorine-based inert liquid.

After the exposure, post exposure bake (PEB) is preferably carried out to promote the dissociation of the acid-dissociable group in the resin by the acid generated from the radiation-sensitive acid generator with the exposure in the exposed part of the resist film. The difference of solubility into the developer between the exposed part and the non-exposed part is generated by the PEB. The temperature of PEB is typically from 50° C. to 180° C., and preferably from 80° C. to 130° C. The duration of PEB is typically from 5 seconds to 600 seconds, and preferably from 10 seconds to 300 seconds.

[Developing Step]

In this step, the resist film exposed in the exposing step as the step (2) is developed. By this step, the predetermined resist pattern can be formed. After the development, the resist pattern is washed with a rinse solution such as water or alcohol, and the dried, in general.

Examples of the developer used for the development include, in the alkaline development, an alkaline aqueous solution obtained by dissolving at least one alkaline compound such as sodium hydroxide, potassium hydroxide, sodium carbonate, sodiumsilicate, sodium metasilicate, ammonia water, ethylamine, n-propylamine, diethylamine, di-n-propylamine, triethylamine, methyldiethylamine, ethyldimethylamine, triethanolamine, tetramethyl ammonium hydroxide (TMAH), pyrrole, piperidine, choline, 1,8-diazabicyclo-[5.4.0]-7-undecene, 1,5-diazabicyclo-[4.3.0]-5-nonene. Among them, an aqueous TMAH solution is preferred, and 2.38% by mass of aqueous TMAH solution is more preferred.

In the case of the development with organic solvent, examples of the solvent include an organic solvent, including a hydrocarbon-based solvent, an ether-based solvent, an ester-based solvent, a ketone-based solvent, and an alcohol-based solvent; and a solvent containing an organic solvent. Examples of the organic solvent include one, two or more solvents listed as the solvent for the radiation-sensitive resin composition. Among them, an ester-based solvent or a ketone-based solvent is preferred. The ester-based solvent is preferably an acetate ester-based solvent, and more preferably n-butyl acetate or amyl acetate. The ketone-based solvent is preferably a chain ketone, and more preferably 2-heptanone. The content of the organic solvent in the developer is preferably not less than 80% by mass, more preferably not less than 90% by mass, further preferably not less than 95% by mass, and particularly preferably not less than 99% by mass. Examples of the ingredient other than the organic solvent in the developer include water and silicone oil.

Examples of the developing method include a method of dipping the substrate in a tank filled with the developer for a given time (dip method); a method of developing by putting and leaving the developer on the surface of the substrate with the surface tension for a given time (paddle method); a method of spraying the developer on the surface of the substrate (spray method); and a method of injecting the developer while scanning an injection nozzle for the developer at a constant rate on the substrate rolling at a constant rate (dynamic dispense method).

### EXAMPLES

Hereinafter, the present invention will be specifically described with reference to Examples, but the present invention is not limited to these Examples. Methods for measuring various physical property values will be described below.

The structures of onium salts (hereinafter, each also referred to as “PAG1” and the like) as a radiation-sensitive acid generator (PAG) used in a radiation-sensitive resin composition will be shown below.

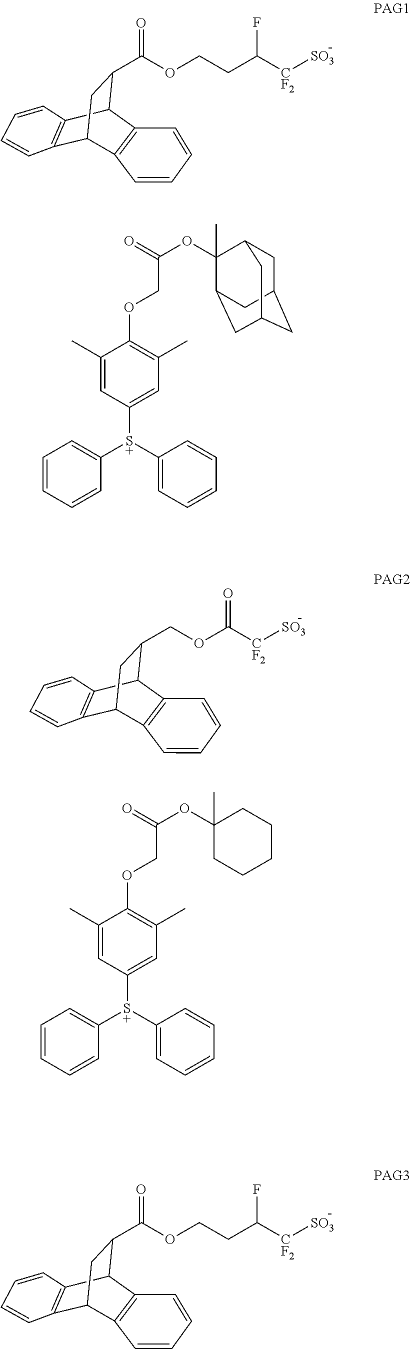

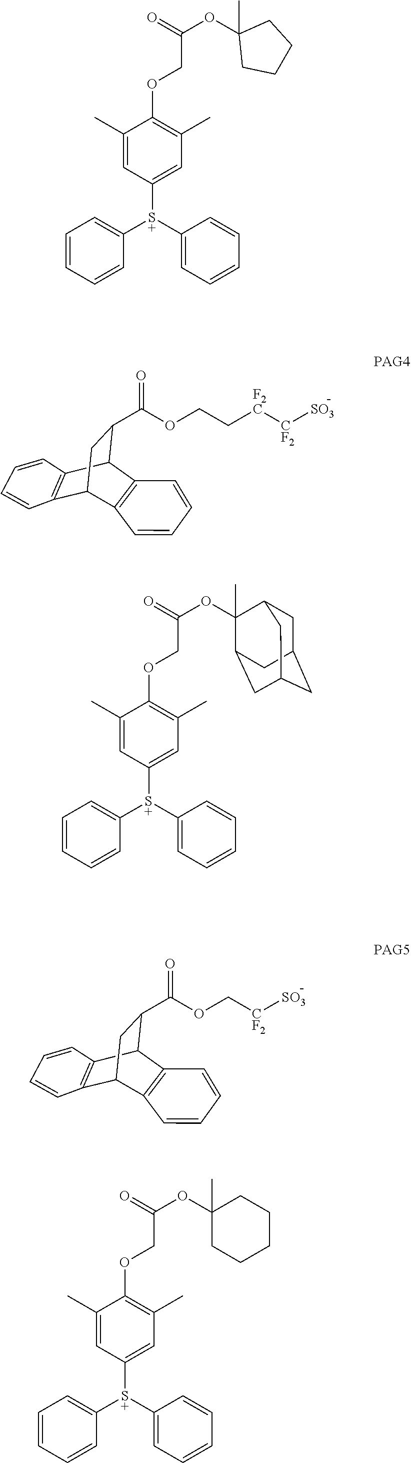

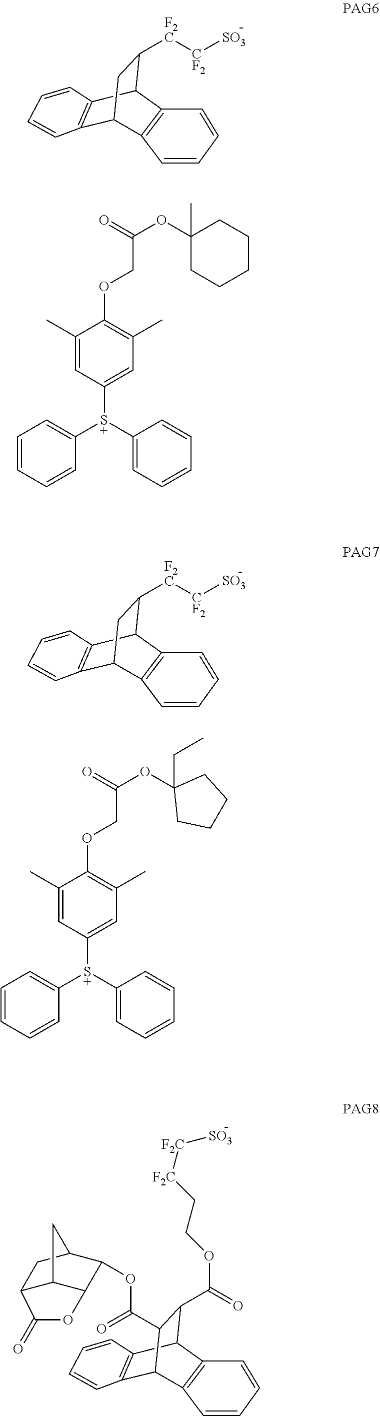

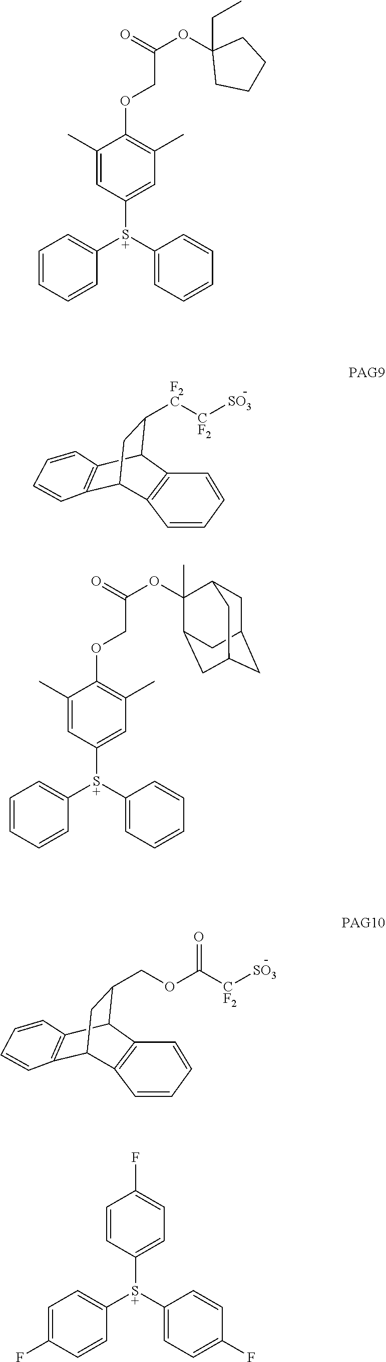

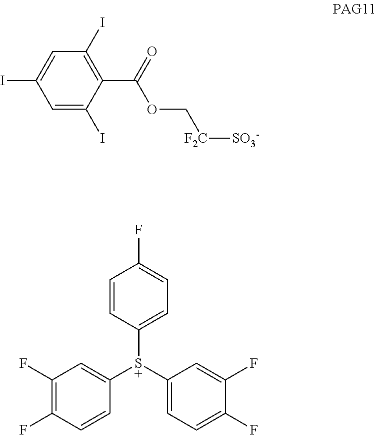

### [Synthesis Examples] Synthesis of Base Resin

Respective monomers were combined, and subjected to a copolymerization reaction under a tetrahydrofuran (THF) solvent, followed by crystallization in methanol. Furthermore, the copolymerized product was repeatedly washed with hexane, and then isolated and dried to obtain base resins P-1 to P-7 having the following compositions. The composition of the obtained base resin was confirmed by 1H-NMR. The Mw and dispersion degree (Mw/Mn) of the resin were measured by gel permeation chromatography (GPC) using GPC columns (two “G2000HXL”, one “G3000HXL”, one “G4000HXL”) manufactured by Tosoh Corporation under the following conditions.

Eluent: tetrahydrofuran (manufactured by Wako Pure Chemical Industries, Ltd.)

Flow rate: 1.0 mL/min

Sample concentration: 1.0% by mass

Sample injection volume: 100 μL

Column temperature: 40° C.

Detector: differential refractometer

Standard substance: monodisperse polystyrene

P-1: Mw=8,600, Mw/Mn=1.88

P-2: Mw=6,900, Mw/Mn=1.72

P-3: Mw=7,000, Mw/Mn=1.76

P-4: Mw=7,200, Mw/Mn=1.69

P-5: Mw=7,300, Mw/Mn=1.65

P-6: Mw=6,900, Mw/Mn=1.76

P-7: Mw=8,600, Mw/Mn=1.88

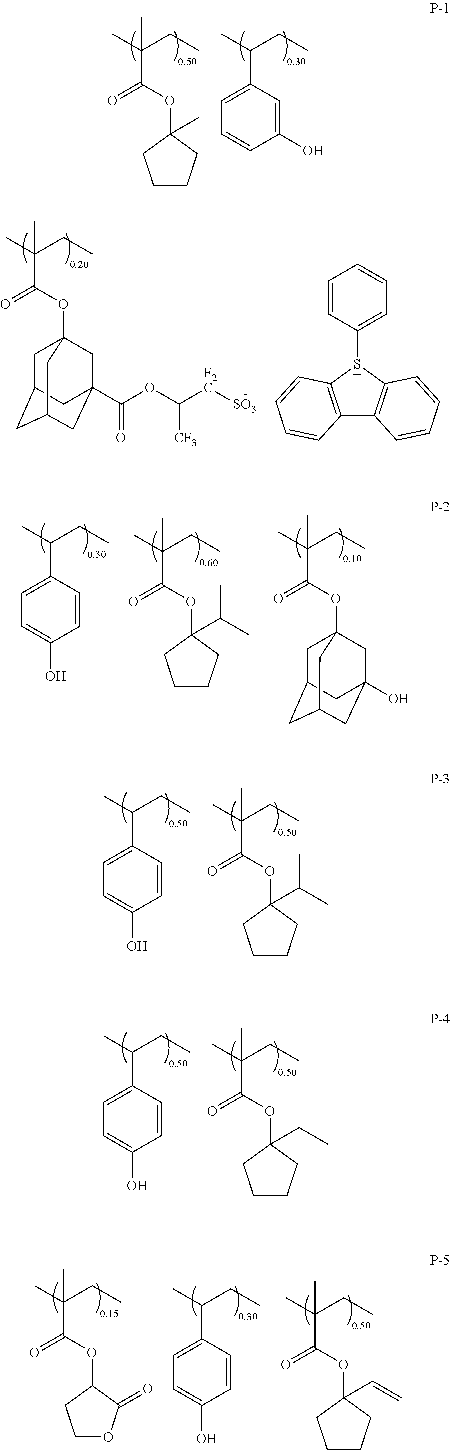

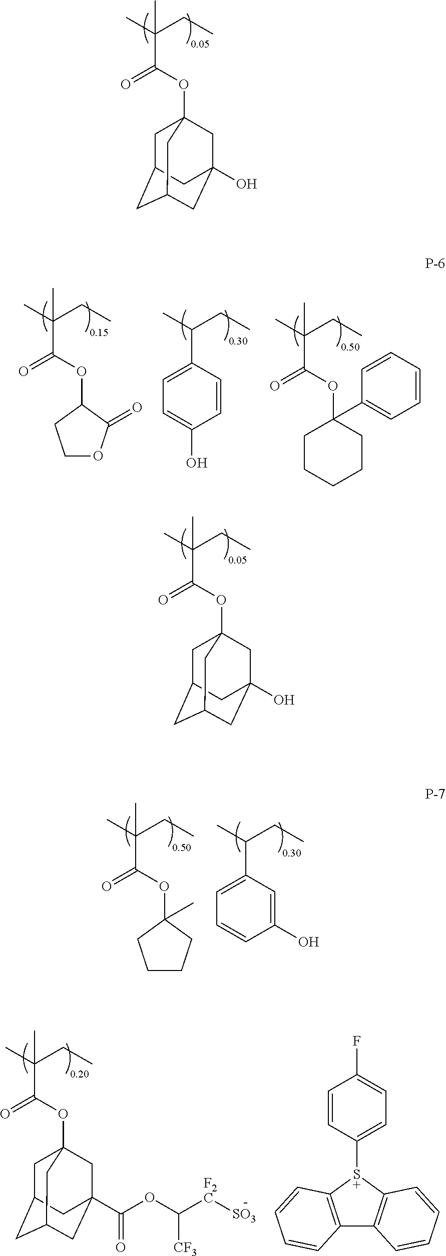

### Examples 1 to 25 and Comparative Examples 1 to 21

Components shown in Tables 1 to 5 was dissolved in a solvent in which 100 ppm of FC-4430 manufactured by 3M as a surfactant was dissolved, and the solution were then filtered through a 0.2 μm-sized filter to prepare a radiation-sensitive resin composition.

Solvent:

PGMEA (propylene glycol monomethyl ether acetate)

CHN (cyclohexanone)

PGME (propylene glycol monomethyl ether)

EL (ethyl lactate)

Acid diffusion controlling agent: Q-1 to Q-15 (see the following structural formulae)

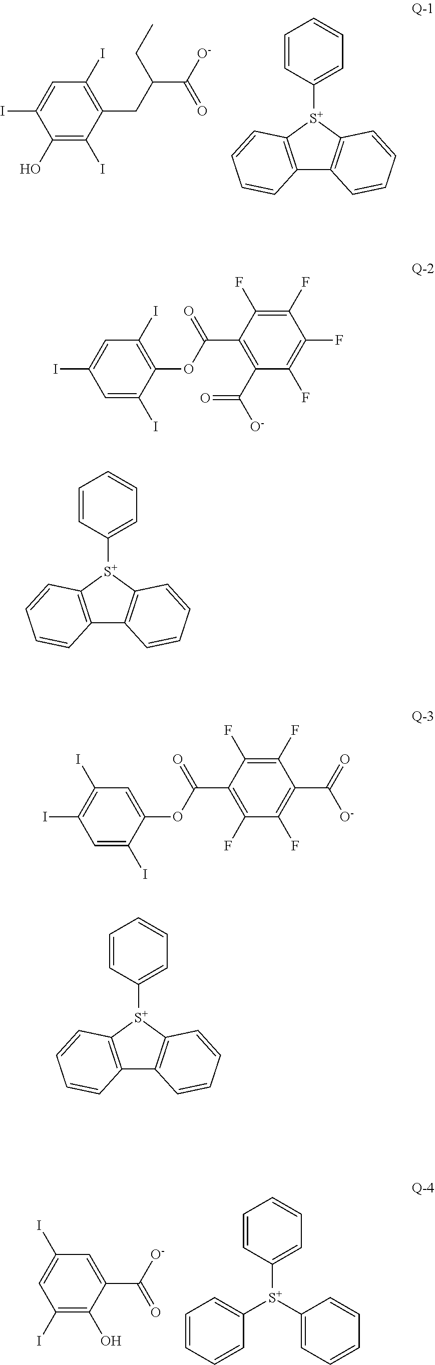

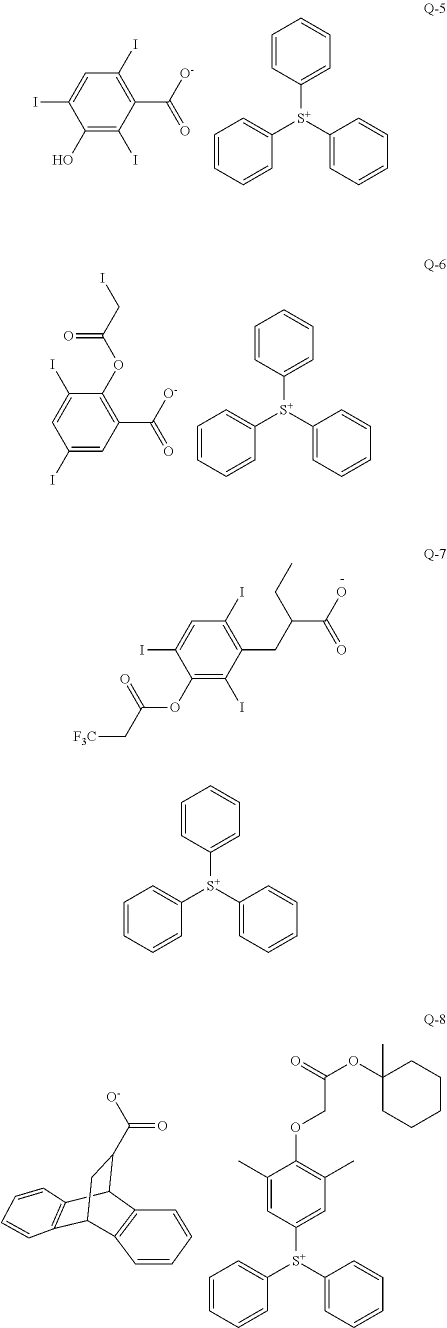

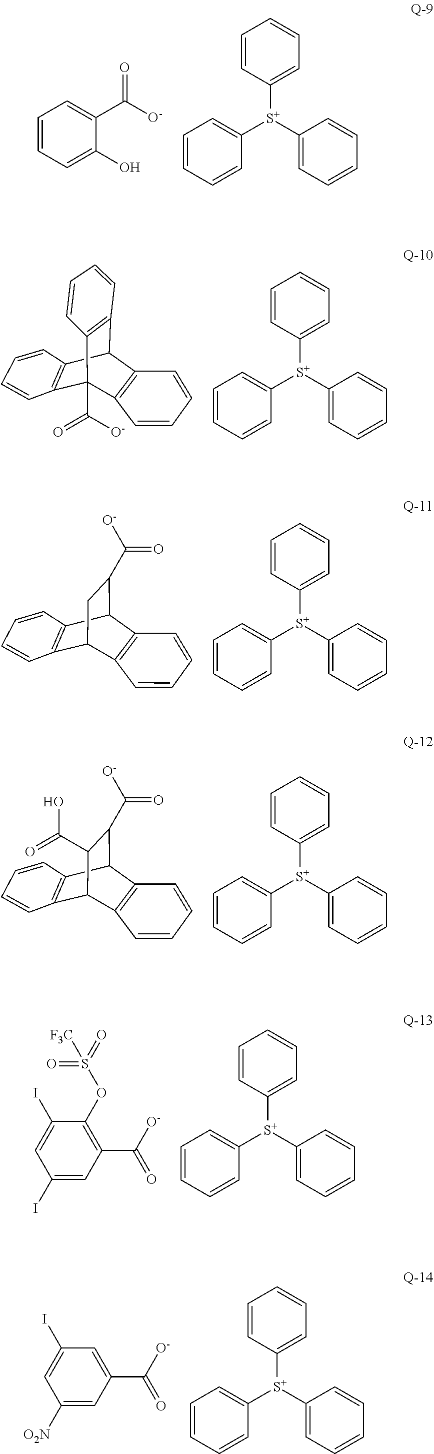

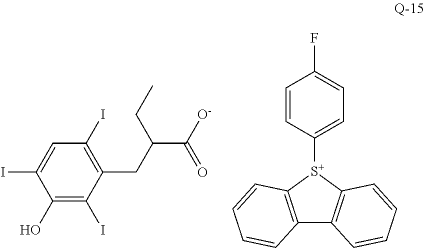 [SMILES: CCC(Cc1c(I)cc(I)c(O)c1I)C(=O)[O-] ; Fc1ccc(-[s+]2c3ccccc3c3ccccc32)cc1]

### <Evaluation>

The defect-suppression performance, sensitivity, and CDU performance of the radiation-sensitive resin composition were evaluated by the following methods. For measuring the length of a resist pattern in sensitivity and CDU performance, a high-resolution FEB length measuring apparatus (“CG5000” manufactured by Hitachi High-Technologies Corporation) was used. The results are shown in Tables 1 to 5.

### <Formation of Line and Space Pattern (EUV Exposure, Alkaline Development)>

Using a spin coater (“CLEAN TRACK ACT 8” available from Tokyo Electron Limited), the radiation-sensitive resin composition prepared above was applied onto the surface of a 12 inch silicon wafer on which SiC was deposited, subjected to PB at 130° C. for 60 seconds, and then cooled at 23° C. for 30 seconds to form a resist film having a film thickness of 55 nm. Then, the resist film was irradiated with EUV light using an EUV scanner (type “NXE3300”, manufactured by ASML, NA=0.33, lighting condition: Conventional, s=0.89, Mask imecDEFECT32FFR02). The resist film was then subjected to PEB at 110° C. for 60 seconds, and then cooled at 23° C. for 30 seconds. Using a 2.38% by mass aqueous tetramethylammonium hydroxide (TMAH) solution, the resist film was developed at 23° C. for 30 seconds to form a positive 32 nm line and space pattern.

### [Defect-Suppression Performance]

The number of defects (number/cm²) of the formed line and space pattern was measured with a defect inspection apparatus (“KLA2925” manufactured by KLA-Tencor Corporation). The defect-suppression performance can be evaluated as “good” when the number of defects is 20/cm² or less and as “poor” when the number of defects exceeds 20/cm².

### [Sensitivity]

An exposure amount at which the 32 nm line and space pattern was formed in the formation of the resist pattern was defined as an optimum exposure amount, and the optimum exposure amount was defined as sensitivity (mJ/cm²).

### <Formation of Hole Pattern (EUV Exposure, Alkaline Development)>

Each of the radiation-sensitive resin compositions was spin-coated on a Si substrate formed with a silicon-containing spin-on hardmask SHB-A940 (silicon content: 43% by mass) having an average thickness of 20 nm, and prebaked at 105° C. for 60 seconds using a hot plate to prepare a resist film having an average thickness of 60 nm. This was exposed using an EUV scanner “NXE3300” (NA: 0.33, σ: 0.9/0.6, quadrupole illumination, a mask having a hole pattern having a pitch size of 46 nm on a wafer and +20% bias) manufactured by ASML, subjected to PEB at 110° C. for 60 seconds on a hot plate, and developed with a 2.38% by mass aqueous TMAH solution for 30 seconds to obtain a hole pattern having a size of 23 nm.

### <Evaluation>

The obtained resist pattern was evaluated as follows.

### [CDU Performance]

Using a length-measuring SEM (CG 5000) manufactured by Hitachi High-Technologies Corporation, an exposure amount when a hole having a size of 23 nm was formed was determined and defined as sensitivity. The sizes of 50 holes at this time were measured to determine CDU (size variation: 3σ) (nm). The smaller the value of the CDU performance is, the smaller the variation in the hole diameter over long period is, which is better.

TABLE 1

| | | | Acid | | | | |
|---|---|---|---|---|---|---|---|
| | | | diffusion | | | | |
| | | | controlling | | | | |
| | Resin | Radiation-sensitive | agent | Solvent | | | |
| | (parts by | acid generator | (parts by | (parts by | | Sensitivity | CDU |
| | mass) | (parts by mass) | mass) | mass) | Defect | (mJ/cm²) | (nm) |
| Example 1 | P-1 | — | Q-1 | PGMEA (100) | 10 | 24 | 2.4 |
| | (100) | | (3.5) | EL (1,800) | | | |
| | | | | PGME (600) | | | |
| Example 2 | P-1 | — | Q-2 | PGMEA (100) | 11 | 20 | 2.3 |
| | (100) | | (3.5) | EL (1,800) | | | |
| | | | | PGME (600) | | | |
| Example 3 | P-1 | — | Q-3 | PGMEA (100) | 12 | 22 | 2.3 |
| | (100) | | (3.5) | EL (1,800) | | | |
| | | | | PGME (600) | | | |
| Example 4 | P-1 | — | Q-4 | PGMEA (100) | 10 | 20 | 2.3 |
| | (100) | | (3.5) | EL (1,800) | | | |
| | | | | PGME (600) | | | |
| Example 5 | P-1 | — | Q-5 | PGMEA (100) | 13 | 18 | 2.3 |
| | (100) | | (3.5) | EL (1,800) | | | |
| | | | | PGME (600) | | | |
| Example 6 | P-1 | — | Q-6 | PGMEA (100) | 13 | 17 | 2.3 |
| | (100) | | (3.5) | EL (600) | | | |
| | | | | PGME (1,800) | | | |
| Example 7 | P-1 | — | Q-7 | PGMEA (100) | 12 | 18 | 2.2 |
| | (100) | | (3.5) | EL (600) | | | |
| | | | | PGME (1,800) | | | |
| Example 8 | P-1 | — | Q-13 | PGMEA (100) | 13 | 19 | 2.3 |
| | (100) | | (3.5) | EL (1,800) | | | |
| | | | | PGME (600) | | | |
| Example 9 | P-1 | — | Q-14 | PGMEA (100) | 10 | 22 | 2.4 |
| | (100) | | (3.5) | EL (600) | | | |
| | | | | PGME (1,800) | | | |
| Comparative | P-1 | — | Q-1 | PGMEA (400) | 21 | 22 | 2.4 |
| Example 1 | (100) | | (3.5) | CHN (2,000) | | | |
| | | | | PGME (100) | | | |
| Comparative | P-1 | — | Q-2 | PGMEA (400) | 25 | 21 | 2.3 |
| Example 2 | (100) | | (3.5) | CHN (2,000) | | | |
| | | | | PGME (100) | | | |
| Comparative | P-1 | — | Q-3 | PGMEA (400) | 25 | 20 | 2.3 |
| Example 3 | (100) | | (3.5) | CHN (2,000) | | | |
| | | | | PGME (100) | | | |
| Comparative | P-1 | — | Q-4 | PGMEA (400) | 23 | 21 | 2.4 |
| Example 4 | (100) | | (3.5) | CHN (2,000) | | | |
| | | | | PGME (100) | | | |
| Comparative | P-1 | — | Q-5 | PGMEA (400) | 22 | 19 | 2.2 |
| Example 5 | (100) | | (3.5) | CHN (2,000) | | | |
| | | | | PGME (100) | | | |
| Comparative | P-1 | — | Q-6 | PGMEA (400) | 24 | 15 | 2.2 |
| Example 6 | (100) | | (3.5) | CHN (2,000) | | | |
| | | | | PGME (100) | | | |
| Comparative | P-1 | — | Q-7 | PGMEA (400) | 21 | 16 | 2.1 |
| Example V | (100) | | (3.5) | CHN (2,000) | | | |
| | | | | PGME (100) | | | |
| Comparative | P-1 | — | Q-13 | PGMEA (400) | 23 | 18 | 2.3 |
| Example 8 | (100) | | (3.5) | CHN (2,000) | | | |
| | | | | PGME (100) | | | |
| Comparative | P-1 | — | Q-14 | PGMEA (400) | 25 | 21 | 2.4 |
| Example 9 | (100) | | (3.5) | CHN (2,000) | | | |
| | | | | PGME (100) | | | |

TABLE 2

| | | Radiation-sensitive | Acid diffusion | | | | |
|---|---|---|---|---|---|---|---|
| | Resin | acid generator | controlling agent | Solvent | | Sensitivity | CDU |
| | (parts by mass) | (parts by mass) | (parts by mass) | (parts by mass) | Defect | (mJ/cm²) | (nm) |
| Example 10 | P-2 | PAG1 | Q-9 | PGME (5,120) | 12 | 21 | 2.3 |
| | (100) | (27.1) | (3.8) | EL (1,280) | | | |
| Example 11 | P-2 | PAG2 | Q-9 | PGME (5,120) | 13 | 24 | 2.2 |
| | (100) | (24.7) | (3.8) | EL (1,280) | | | |
| Example 12 | P-2 | PAG3 | Q-9 | EL (5,120) | 15 | 22 | 2.1 |
| | (100) | (26.2) | (3.8) | PGME (1,280) | | | |
| Comparative | P-2 | PAG1 | Q-9 | PGMEA (5,120) | 24 | 22 | 2.2 |
| Example 10 | (100) | (27.1) | (3.8) | PGME (1,280) | | | |
| Comparative | P-2 | PAG2 | Q-9 | PGMEA (5,120) | 22 | 24 | 2.3 |
| Example 11 | (100) | (24.7) | (3.8) | PGME (1,280) | | | |
| Comparative | P-2 | PAG3 | Q-9 | PGMEA (5,120) | 23 | 22 | 2.2 |
| Example 12 | (100) | (26.2) | (3.8) | PGME (1,280) | | | |

TABLE 3

| | | Radiation-sensitive | Acid diffusion | | | | |
|---|---|---|---|---|---|---|---|
| | Resin | acid generator | controlling agent | Solvent | | Sensitivity | CDU |
| | (parts by mass) | (parts by mass) | (parts by mass) | (parts by mass) | Defect | (mJ/cm²) | (nm) |
| Example 13 | P-3 | PAG4 | Q-10 | EL (5,120) | 14 | 30 | 2.3 |
| | (100) | (27.6) | (5.3) | PGME (1,280) | | | |
| Example 14 | P-3 | PAG5 | Q-11 | EL (5,120) | 15 | 33 | 2.2 |
| | (100) | (24.7) | (4.8) | PGME (1,280) | | | |
| Example 15 | P-3 | PAG6 | Q-12 | EL (5,120) | 13 | 32 | 2.3 |
| | (100) | (24.5) | (5.3) | PGME (1,280) | | | |
| Example 16 | P-3 | PAG7 | Q-1 | EL (5,120) | 12 | 31 | 2.4 |
| | (100) | (24.1) | (7.2) | PGME (1,280) | | | |
| Example 17 | P-3 | PAG8 | Q-2 | PGME (5,120) | 12 | 28 | 2.5 |
| | (100) | (31.3) | (7.2) | EL (1,280) | | | |
| Comparative | P-3 | PAG4 | Q-10 | PGMEA (5,120) | 22 | 29 | 2.2 |
| Example 13 | (100) | (27.6) | (5.3) | PGME (1,280) | | | |
| Comparative | P-3 | PAG5 | Q-11 | PGMEA (5,120) | 23 | 28 | 2.1 |
| Example 14 | (100) | (24.7) | (4.8) | PGME (1,280) | | | |
| Comparative | P-3 | PAG6 | Q-12 | PGMEA (5,120) | 24 | 26 | 2.4 |
| Example 15 | (100) | (24.5) | (5.3) | PGME (1,280) | | | |
| Comparative | P-3 | PAG7 | Q-1 | PGMEA (5,120) | 26 | 30 | 2.5 |
| Example 16 | (100) | (24.1) | (7.2) | PGME (1,280) | | | |
| Comparative | P-3 | PAG8 | Q-2 | PGMEA (5,120) | 22 | 27 | 2.5 |
| Example 17 | (100) | (31.3) | (7.2) | PGME (1,280) | | | |

TABLE 4

| | | Radiation-sensitive | Acid diffusion | | | | |
|---|---|---|---|---|---|---|---|
| | Resin | acid generator | controlling agent | Solvent | | Sensitivity | CDU |
| | (parts by mass) | (parts by mass) | (parts by mass) | (parts by mass) | Defect | (mJ/cm²) | (nm) |
| Example 18 | P-4 | PAG6 | Q-9 | EL (5,120) | 13 | 21 | 2.5 |
| | (100) | (24.5) | (3.8) | PGME (1,180) | | | |
| | | | | PGMEA (100) | | | |
| Example 19 | P-4 | PAG6 | Q-11 | EL (5,120) | 11 | 24 | 2.3 |
| | (100) | (24.5) | (4.8) | PGME (1,180) | | | |
| | | | | PGMEA (100) | | | |
| Example 20 | P-4 | PAG6 | Q-8 | PGME (5,120) | 17 | 22 | 2.2 |
| | (100) | (24.5) | (6.7) | EL (1,180) | | | |
| | | | | PGMEA (100) | | | |
| Example 21 | P-5 | PAG4 | Q-9 | PGME (5,120) | 15 | 24 | 2.5 |
| | (100) | (27.6) | (3.8) | EL (1,180) | | | |
| | | | | PGMEA (100) | | | |
| Example 22 | P-6 | PAG9 | Q-9 | PGME (5,120) | 15 | 25 | 2.3 |
| | (100) | (25.6) | (3.8) | EL (1,180) | | | |
| | | | | PGMEA (100) | | | |
| Comparative | P-4 | PAG6 | Q-9 | PGMEA (5,120) | 22 | 21 | 2.6 |
| Example 18 | (100) | (24.5) | (3.8) | PGME (1,280) | | | |
| Comparative | P-4 | PAG6 | Q-11 | PGMEA (5,120) | 21 | 22 | 2.2 |
| Example 19 | (100) | (24.5) | (4.8) | PGME (1,280) | | | |
| Comparative | P-4 | PAG6 | Q-8 | PGMEA (5,120) | 21 | 21 | 2.1 |
| Example 20 | (100) | (24.5) | (6.7) | PGME (1,280) | | | |
| Comparative | P-5 | PAG4 | Q-9 | PGMEA (5,120) | 25 | 24 | 2.5 |
| Example 21 | (100) | (27.6) | (3.8) | EL (1,280) | | | |

TABLE 5

| | | Radiation-sensitive | Acid diffusion | | | | |
|---|---|---|---|---|---|---|---|
| | Resin | acid generator | controlling agent | Solvent | | Sensitivity | CDU |
| | (parts by mass) | (parts by mass) | (parts by mass) | (parts by mass) | Defect | (mJ/cm²) | (nm) |
| Example 23 | P-7 | — | Q-15 | PGMEA (100) | 10 | 23 | 2.4 |
| | (100) | | (35) | EL (1,800) | | | |
| | | | | PGME (600) | | | |
| Example 24 | P-2 | PAG10 | Q-9 | PGME (5,120) | 13 | 22 | 2.2 |
| | (100) | (24.7) | (3.8) | EL (1,280) | | | |
| Example 25 | P-2 | PAG11 | Q-15 | PGME (5,120) | 13 | 21 | 2.0 |
| | (100) | (24.7) | (3.8) | EL (1,280) | | | |

### Example 26

The same operation as in Example 25 was performed except that the composition for forming a resist underlayer film of Example 1 in JP-A-2012-215842 was spin-coated so as to have an average thickness of 300 nm to form the resist underlayer film before spin-coating the radiation-sensitive resin composition in Example 25. Defect-suppression performance, sensitivity, and CDU performance were evaluated. As a result, the same results as in Example 25 were obtained. The composition for forming an underlayer film contained 10 parts by mass of a polymer which was a condensate of 1-naphthol and formaldehyde and 90 parts by mass of propylene glycol monomethyl ether acetate.

From the results shown in Tables 1 to 5 and Example 26, it can be confirmed that the resist compositions of Examples to which the present invention is applied provide a resist pattern having few defects and good CDU performance with high sensitivity.

According to the radiation-sensitive resin composition and the method for forming a resist pattern described above, a resist pattern having few defects and good CDU performance can be formed with high sensitivity. Therefore, these can be suitably used for a machining process and the like of a semiconductor device in which micronization is expected to further progress in the future.

Obviously, numerous modifications and variations of the present invention are possible in light of the above teachings. It is therefore to be understood that within the scope of the appended claims, the invention may be practiced otherwise than as specifically described herein.

What is claimed is:

1. A radiation-sensitive resin composition comprising:
a resin comprising a structural unit represented by formula (1); and
a solvent comprising propylene glycol monomethyl ether and alkyl lactate,
wherein the solvent does not comprise propylene glycol monomethyl ether acetate or comprises propylene glycol monomethyl ether acetate in a content of 5% by mass or less in the solvent, and
the radiation-sensitive resin composition further comprises a radiation-sensitive acid generator, or the resin further comprises a structural unit having a radiation-sensitive acid generating structure: 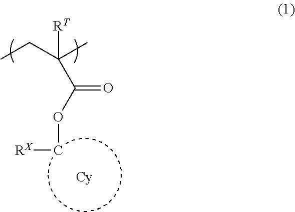
wherein R^{T} is a hydrogen atom, a fluorine atom, a methyl group, or a trifluoromethyl group,
R^{X} is a monovalent hydrocarbon group having 1 to 20 carbon atoms, and
Cy represents an alicyclic structure having 3 to 20 ring members formed together with the carbon atom to which Cy is bonded.

2. The radiation-sensitive resin composition according to claim 1, wherein the solvent does not comprise the propylene glycol monomethyl ether acetate or comprises the propylene glycol monomethyl ether acetate in the content of 1% by mass or less in the solvent.

3. The radiation-sensitive resin composition according to claim 1, wherein the solvent does not comprise the propylene glycol monomethyl ether acetate.

4. The radiation-sensitive resin composition according to claim 1, wherein:
when the radiation-sensitive resin composition further comprises the radiation-sensitive acid generator, the radiation-sensitive acid generator comprises an onium salt comprising: an organic acid anion moiety; and an onium cation moiety; and
when the resin further comprises the structural unit having the radiation-sensitive acid generating structure, the radiation-sensitive acid generating structure comprises an organic acid anion moiety and an onium cation moiety.

5. The radiation-sensitive resin composition according to claim 4, wherein the organic acid anion moiety comprises an iodine-substituted aromatic ring structure.

6. The radiation-sensitive resin composition according to claim 4, wherein the onium cation moiety comprises a fluorine-substituted aromatic ring structure.

7. The radiation-sensitive resin composition according to claim 1, wherein
the radiation-sensitive resin composition further comprises the radiation-sensitive acid generator, and the radiation-sensitive acid generator comprises an onium salt comprising: an organic acid anion moiety; and an onium cation moiety,
the onium salt is at least one selected from the group consisting of:
a radiation-sensitive strong acid generator comprising the organic acid anion moiety and the onium cation moiety; and
an acid diffusion controlling agent comprising the organic acid anion moiety and the onium cation moiety and generating an acid having a pKa higher than a pKa of an acid generated from the radiation-sensitive strong acid generator by irradiation with radiation.

8. The radiation-sensitive resin composition according to claim 1, wherein the resin further comprises a structural unit having a phenolic hydroxyl group.

9. The radiation-sensitive resin composition according to claim 4, wherein the organic acid anion moiety has at least one selected from the group consisting of a sulfonate anion, a carboxylate anion, and a sulfonimide anion.

10. The radiation-sensitive resin composition according to claim 4, wherein the onium cation moiety is at least one selected from the group consisting of a sulfonium cation and an iodonium cation.

11. The radiation-sensitive resin composition according to claim 1, wherein the structural unit represented by the formula (1) is represented by formula (A-1): 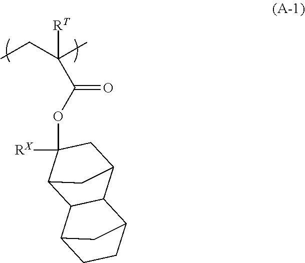
wherein each of R^{T} and R^{X} is as defined in the formula (1).

12. The radiation-sensitive resin composition according to claim 4, wherein the organic acid anion moiety contains a partial structure represented by formula (b1) or (b2): 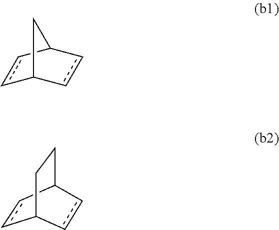
wherein [symbol]
represents a single bond or a double bond.

13. A method for forming a pattern, the method comprising:
forming a resist film by applying the radiation-sensitive resin composition according to claim 1 directly or indirectly onto a substrate;
exposing the resist film; and
developing the exposed resist film with a developer.

14. The method according to claim 13, wherein in the exposing of the resist film, the resist film is exposed to an extreme ultraviolet ray or an electron beam.

15. The method according to claim 13, further comprising, before forming the resist film, forming a resist underlayer film by applying a composition for forming a resist underlayer film directly or indirectly to the substrate.
